(19) United States
(12) Patent Application Publication
(10) Pub. No.: US 2025/0011616 A1
(43) Pub. Date: Jan. 9, 2025

(54) METHOD FOR PRODUCING STRUCTURE BODY INCLUDING PHASE-SEPARATED STRUCTURE, AND COMPOSITION

(71) Applicants: TOKYO OHKA KOGYO CO., LTD., Kawasaki-shi (JP); TOKYO INSTITUTE OF TECHNOLOGY, Tokyo (JP)

(72) Inventors: Takuya Uehara, Kawasaki-shi (JP); Takahiro Dazai, Kawasaki-shi (JP); Teruaki Hayakawa, Tokyo (JP); Shinsuke Maekawa, Tokyo (JP); Riku Mizusaki, Tokyo (JP)

(21) Appl. No.: 18/437,759

(22) Filed: Feb. 9, 2024

(30) Foreign Application Priority Data
Jun. 22, 2023 (JP) 2023-102849

(51) Int. Cl. C09D 153/00; C08J 7/04; C08L 53/00

(52) U.S. Cl. CPC C09D 153/00; C08J 7/042; C08L 53/00; C08J 2353/00

(57) ABSTRACT

A method for producing a structure body including a phase-separated, the method including (i) applying a composition containing a block copolymer represented by Formula (n1) onto a substrate to form an undercoat agent layer, (ii) applying the composition containing the block copolymer onto the undercoat agent layer to form a self-organization layer, and (iii) subjecting the self-organization layer to phase separation. In General Formula (n1), A represents a first polymer block, B represents a second polymer block, R^{1c} and R^{1d} represent a substrate adsorptive group-containing group, R^{2c} and R^{2d} represent a substituent other than the substrate adsorptive group-containing group, m1 and n1 represent an integer of 0 to 5, m2 and n2 represent an integer of 0 to 5, m1+n1 >1, m1+m2<5, and n1+n2<5

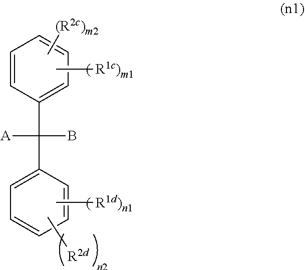

### BACKGROUND OF THE INVENTION

### Field of the Invention

The present invention relates to a method for producing a structure body including a phase-separated structure, and a composition.

Priority is claimed on Japanese Patent Application No. 2023-102849, filed on Jun. 22, 2023, the content of which is incorporated herein by reference.

### Description of the Related Art

In recent years, along with further miniaturization of large-scale integrated circuits (LSI), a technology for processing finer structure bodies has been demanded. In response to such a demand, a technology has been developed for forming a finer structure body by utilizing a phase-separated structure formed by self-organization of a block copolymer in which blocks incompatible to each other are bonded together.

In order to utilize the phase-separated structure of the block copolymer, it is considered essential to form self-organized nanostructures, which are formed by micro-phase separation, only in a specific region and arrange the nanostructures in a desired direction. In order to realize the position control and orientation control of these nanostructures, processes have been proposed such as graphoepitaxy for controlling the phase separation pattern by a guide pattern, and chemical epitaxy for controlling the phase separation pattern by the difference in the chemical state of the substrate (for example, see Proceedings of SPI, Vol. 7637, No. 76370G-1 (2010)).

As a method for forming a fine pattern by subjecting the block copolymer to phase separation, for example, a method of forming an undercoat agent layer on a substrate has been disclosed. For example, Japanese Patent No. 6475963 discloses an undercoat agent including a constitutional unit derived from styrene and a constitutional unit derived from hydroxyethyl acrylate.

### SUMMARY OF THE INVENTION

In the method disclosed in Patent Document 1, as an undercoat agent and a resin composition for forming a phase-separated structure, compositions containing different block copolymers are used. In a case where the same composition can be used for the undercoat agent and the resin composition for forming a phase-separated structure, it is possible to save effort of changing the composition. In addition, since an undercoat agent layer and a self-organization layer can be formed with a single composition, management of raw materials is also facilitated.

The present invention has been made in consideration of the above circumstances, and an object of the present invention is to provide a method for producing a structure body including a phase-separated structure, in which an undercoat agent layer and a self-organization layer are formed of the same composition containing a block copolymer, and provide a composition containing a block copolymer, which is used in the method.

That is, a first aspect of the present invention is a method for producing a structure body including a phase-separated structure, the method including (i) applying a composition containing a block copolymer represented by General Formula (n1) onto a substrate to form an undercoat agent layer, (ii) applying the composition containing the block copolymer onto the undercoat agent layer to form a self-organization layer, and (iii) subjecting the self-organization layer to phase separation.

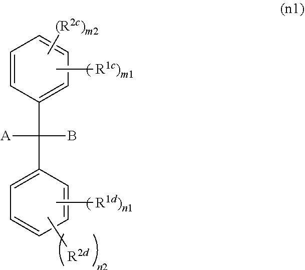

[in the formula, A represents a first polymer block; B represents a second polymer block; R^{1c} and R^{1d} each independently represents a substrate adsorptive group-containing group; R^{2c} and R^{2d} each independently represents a substituent other than the substrate adsorptive group-containing group; m1 and n1 each independently represents an integer of 0 to 5; m2 and n2 each independently represents an integer of 0 to 5; m1+n1>1; m1+m2<5; and n1+n2<5; provided that, in a case where m1 is an integer of 2 or more, a plurality of R^{1c}'s may be the same as or different from each other, in a case where m2 is an integer of 2 or more, a plurality of R^{2c}'s may be the same as or different from each other, in a case where n1 is an integer of 2 or more, a plurality of Rid's may be the same as or different from each other, and in a case where n2 is an integer of 2 or more, a plurality of R^{2d}'s may be the same as or different from each other].

A second aspect of the present invention is a composition used in the method for producing a structure body including a phase-separated structure according to the first aspect, the composition containing the block copolymer represented by General Formula (n1).

According to the present invention, it is possible to provide a method for producing a structure body including a phase-separated structure, in which an undercoat agent layer and a self-organization layer are formed of the same composition containing a block copolymer, and provide a composition containing a block copolymer, which is used in the method.

### BRIEF DESCRIPTION OF THE DRAWINGS

FIG. 1 is a schematic process diagram explaining an exemplary embodiment of a method for producing a structure body including a phase-separated structure.

FIG. 2 is a diagram explaining an exemplary embodiment of an optional step.

### DETAILED DESCRIPTION OF THE PREFERRED EMBODIMENT

In the present specification and the scope of the present claims, the term “aliphatic” is a relative concept used with respect to “aromatic” and defines a group or compound that has no aromaticity.

The term “alkyl group” includes linear, branched, or cyclic monovalent saturated hydrocarbon groups unless otherwise specified. The same applies to an alkyl group in an alkoxy group.

The term “alkylene group” includes linear, branched, or cyclic divalent saturated hydrocarbon groups unless otherwise specified.

A “halogenated alkyl group” is a group in which a part of or all of hydrogen atoms in an alkyl group are substituted with halogen atoms. As the halogen atom, a fluorine atom, a chlorine atom, a bromine atom, and an iodine atom are exemplary examples.

A “fluorinated alkyl group” or “fluorinated alkylene group” is a group obtained by substituting part or all of hydrogen atoms of an alkyl group or an alkylene group with a fluorine atom.

The term “constitutional unit” indicates a monomer unit constituting a polymer compound (a resin, a polymer, or a copolymer).

The expression “may have a substituent” includes a case where a hydrogen atom (—H) is substituted with a monovalent group and a case where a methylene group (—CH₂—) is substituted with a divalent group.

The term “exposure” is used as a general concept for irradiation with radiation.

The term “α-position (carbon atom at α-position)” means a carbon atom to which a side chain of a block copolymer is bonded, unless otherwise specified. The “carbon atom at the α-position” of a methyl methacrylate unit means a carbon atom to which a carbonyl group of methacrylic acid is bonded. The “carbon atom at the α-position” of a styrene unit means a carbon atom to which a benzene ring is bonded.

The term “number-average molecular weight” (Mn) is a number-average molecular weight in terms of standard polystyrene measured by size-exclusion chromatography, unless otherwise specified. The term “weight-average molecular weight” (Mw) is a weight-average molecular weight in terms of standard polystyrene measured by size-exclusion chromatography, unless otherwise specified. A value obtained by adding a unit (g mol⁻¹) to the value of Mn or Mw represents a molar mass.

In the detailed description of the specification and claims of the present invention, some structures represented by a chemical formula have an asymmetric carbon, and there may be enantiomers and diastereomers. Those isomers are collectively represented by one formula. These isomers may be used alone or in the form of a mixture.

### Method for Producing Structure Body Including Phase-Separated Structure

The method for producing a structure body including a phase-separated structure according to the first aspect of the present invention includes a step (i) of applying a composition containing a block copolymer represented by General Formula (n1) onto a substrate to form an undercoat agent layer, a step (ii) of applying the composition containing the block copolymer onto the undercoat agent layer to form a self-organization layer, and a step (iii) of subjecting the self-organization layer to phase separation.

### Composition Containing Block Copolymer: BCP Composition

In the step (i) and the step (ii) of the production method according to the present embodiment, the same composition containing a block copolymer (hereinafter, also referred to as “BCP composition”) is used.

### Block Copolymer (P1)

The composition containing a block copolymer contains a block copolymer represented by General Formula (n1) (hereinafter, also referred to as “block copolymer (P1)”).

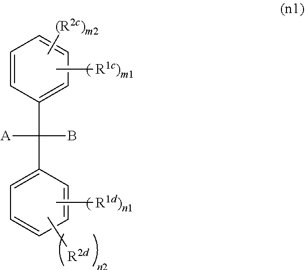

[in the formula, A represents a first polymer block; B represents a second polymer block; R^{1c} and R^{1d} each independently represents a substrate adsorptive group-containing group; R^{2c} and R^{2d} each independently represents a substituent other than the substrate adsorptive group-containing group; m1 and n1 each independently represents an integer of 0 to 5; m2 and n2 each independently represents an integer of 0 to 5; m1+n1>1; m1+m2<5; and n1+n2<5; provided that, in a case where m1 is an integer of 2 or more, a plurality of R^{1c}'s may be the same as or different from each other, in a case where m2 is an integer of 2 or more, a plurality of R^{2c}'s may be the same as or different from each other, in a case where n1 is an integer of 2 or more, a plurality of R^{1d}'s may be the same as or different from each other, and in a case where n2 is an integer of 2 or more, a plurality of R^{2d}'s may be the same as or different from each other].

In Formula (n1), the substrate adsorptive group-containing group in R^{1c} and R^{1d} is a group containing a substrate adsorptive group. The substrate adsorptive group-containing group may be composed of only a substrate adsorptive group, or may contain a group other than the substrate adsorptive group. The substrate adsorptive group-containing group is preferably a substrate adsorptive group or an organic group containing a substrate adsorptive group.

The substrate adsorptive group can be appropriately selected depending on the type of the substrate. As the substrate adsorptive group, specifically, a hydroxy group, a carboxy group, a thiol group, a vinyl group, a bromine atom, an iodine atom, an amino group, an azide group, a formyl group, an epoxy group, and a cyano group are exemplary examples. As the substrate adsorptive group, a hydroxy group, a carboxy group, a thiol group, a vinyl group, a bromine atom, an iodine atom, or a cyano group is preferable, and a hydroxy group is more preferable.

The substrate adsorptive group-containing group in R^{1c} and R^{1d} may contain only one of the substrate adsorptive group or two or more thereof. In a case where the substrate adsorptive group-containing group has two or more substrate adsorptive groups, the substrate adsorptive group may be one kind or two or more kinds. The number of substrate adsorptive groups contained in the substrate adsorptive group-containing group in R^{1c} and R^{1d} is preferably 1 to 3 and more preferably 1 or 2. The number of kinds of substrate adsorptive groups contained in the substrate adsorptive group-containing group in R^{1c} and R^{1d} is preferably 1 to 3, more preferably 1 or 2, and still more preferably 1.

R^{1c} and R^{1d} in Formula (n1) are preferably each a group represented by General Formula (r1).

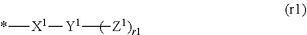

[in the formula, X¹ represents a single bond, a methylene group, —COO—, or —O—; Y¹ represents a single bond or a divalent linking group; Z¹ represents the substrate adsorptive group-containing group; r1 represents an integer of 1 or more within a limit of valence; provided that, in a case where X¹ is —COO— or —O—, Y¹ is not a single bond; and * represents a bonding site bonded with a benzene ring in General Formula (n1)].

In Formula (r1), as the divalent linking group in Y¹, a divalent hydrocarbon group which may have a substituent or a divalent linking group containing a hetero atom is an exemplary example.

Divalent Hydrocarbon Group which May have Substituent:

The divalent hydrocarbon group which may have a substituent may be an aliphatic hydrocarbon group or an aromatic hydrocarbon group.

### Aliphatic Hydrocarbon Group

The aliphatic hydrocarbon group indicates a hydrocarbon group with no aromaticity. The aliphatic hydrocarbon group may be saturated or unsaturated. In general, it is preferable that the aliphatic hydrocarbon group be saturated.

As the aliphatic hydrocarbon group, a linear or branched aliphatic hydrocarbon group or an aliphatic hydrocarbon group including a ring in the structure thereof is an exemplary example.

### Linear or Branched Aliphatic Hydrocarbon Group

The linear aliphatic hydrocarbon group preferably has 1 to 10 carbon atoms, more preferably has 1 to 6 carbon atoms, still more preferably has 1 to 4 carbon atoms, and most preferably has 1 to 3 carbon atoms.

As the linear aliphatic hydrocarbon group, a linear alkylene group is preferable. Specifically, a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—] are exemplary examples.

The branched aliphatic hydrocarbon group preferably has 2 to 10 carbon atoms, more preferably has 3 to 6 carbon atoms, still more preferably has 3 or 4 carbon atoms, and most preferably has 3 carbon atoms.

As the branched aliphatic hydrocarbon group, a branched alkylene group is preferable. Specifically, alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂— and —CH₂CH(CH₃)CH₂CH₂— are exemplary examples. As an alkyl group in the alkylalkylene group, a linear alkyl group having 1 to 5 carbon atoms is preferable.

The above-described linear or branched aliphatic hydrocarbon group may or may not have a substituent. The substituent may be a monovalent substituent which substitutes a hydrogen atom of an aliphatic hydrocarbon chain or a divalent substituent which substitutes a methylene group of an aliphatic hydrocarbon chain.

### Aliphatic Hydrocarbon Group Including Ring in Structure Thereof

As the aliphatic hydrocarbon group including a ring in the structure thereof, a cyclic aliphatic hydrocarbon group which contains a hetero atom in a ring structure and may have a substituent (group obtained by removing two hydrogen atoms from an aliphatic hydrocarbon ring), a group in which the cyclic aliphatic hydrocarbon group is bonded to a terminal of a linear or branched aliphatic hydrocarbon group, a group in which the cyclic aliphatic hydrocarbon group is interposed in a linear or branched aliphatic hydrocarbon group, and the like are exemplary examples. As the linear or branched aliphatic hydrocarbon group, the same ones as those described above are exemplary examples.

The cyclic aliphatic hydrocarbon group preferably has 3 to 20 carbon atoms and more preferably has 3 to 12 carbon atoms.

The cyclic aliphatic hydrocarbon group may be a polycyclic group or a monocyclic group. As the monocyclic alicyclic hydrocarbon group, a group formed by removing two hydrogen atoms from a monocycloalkane is preferable. The number of carbon atoms in the monocycloalkane is preferably 3 to 6, and specifically, cyclopentane and cyclohexane are exemplary examples. As the polycyclic alicyclic hydrocarbon group, a group formed by removing two hydrogen atoms from a polycycloalkane is preferable. The number of carbon atoms in the polycycloalkane is preferably 7 to 12, and specifically, adamantane, norbornane, isobornane, tricyclo[5.2.1.0^{2,6}]decane, and tetracyclododecane are exemplary examples.

The cyclic aliphatic hydrocarbon group may or may not have a substituent. As the substituent, an alkyl group, an alkoxy group, a fluorine atom, a fluorinated alkyl group, a hydroxyl group, and a carbonyl group are exemplary examples.

As the alkyl group as the above-described substituent, an alkyl group having 1 to 5 carbon atoms is preferable, and a methyl group, an ethyl group, a propyl group, an n-butyl group, or a tert-butyl group is more preferable.

As the alkoxy group as the above-described substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is still more preferable.

As the fluorinated alkyl group as the above-described substituent, a group in which a part of or all of hydrogen atoms in the alkyl group are substituted with the fluorine atoms is an exemplary example.

In the cyclic aliphatic hydrocarbon group, a part of carbon atoms constituting the ring structure thereof may be substituted with substituents having a hetero atom. As the substituent having a hetero atom, —O—, —C(═O)—O—, —S—, —S(═O)₂—, or —S(═O)₂—O— is preferable.

### Aromatic Hydrocarbon Group

The aromatic hydrocarbon group is a hydrocarbon group having at least one aromatic ring.

The aromatic ring is not particularly limited as long as the aromatic ring has a cyclic conjugated system having (4n+2)π electrons, and may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms. Here, the number of carbon atoms does not include the number of carbon atoms in a substituent.

Specifically, as the aromatic ring, aromatic hydrocarbon rings such as benzene, naphthalene, anthracene, and phenanthrene; an aromatic heterocyclic ring obtained by substituting a part of carbon atoms constituting the above-described aromatic hydrocarbon ring with a hetero atom; and the like are exemplary examples. As the hetero atom in the aromatic heterocyclic ring, an oxygen atom, a sulfur atom, and a nitrogen atom are exemplary examples. Specifically, as the aromatic heterocyclic ring, a pyridine ring and a thiophene ring are exemplary examples.

Specifically, as the aromatic hydrocarbon group, a group (an arylene group or a heteroarylene group) formed by removing two hydrogen atoms from the aromatic hydrocarbon ring or the aromatic heterocyclic ring; a group formed by removing two hydrogen atoms from an aromatic compound (for example, biphenyl, fluorene, or the like) having two or more aromatic rings; and a group (for example, a group in which one hydrogen atom is further removed from an aryl group in an arylalkyl group such as a benzyl group, a phenethyl group, a 1-naphthylmethyl group, a 2-naphthylmethyl group, a 1-naphthylethyl group, and a 2-naphthylethyl group) in which one hydrogen atom of a group (an aryl group or a heteroaryl group) formed by removing one hydrogen atom from the aromatic hydrocarbon ring or the aromatic heterocyclic ring is substituted with an alkylene group are exemplary examples. The number of carbon atoms in the alkylene group which is bonded to the above-described aryl group or heteroaryl group is preferably 1 to 4, more preferably 1 or 2, and particularly preferably 1.

In the above-described aromatic hydrocarbon group, a hydrogen atom in the aromatic hydrocarbon group may be substituted with a substituent. For example, the hydrogen atom bonded to the aromatic ring in the aromatic hydrocarbon group may be substituted with a substituent. As the substituent, for example, an alkyl group, an alkoxy group, a fluorine atom, a fluorinated alkyl group, and a hydroxyl group are exemplary examples.

As the alkyl group as the above-described substituent, an alkyl group having 1 to 5 carbon atoms is preferable, and a methyl group, an ethyl group, a propyl group, an n-butyl group, or a tert-butyl group is more preferable.

As the alkoxy group, the fluorine atom, and the fluorinated alkyl group as the above-described substituent, the same exemplary examples of the substituent which substitutes the hydrogen atom in the cyclic aliphatic hydrocarbon group described above are preferable.

Divalent linking group containing hetero atom:

As the divalent linking group containing a hetero atom, —O—, —C(═O)—O—, —O—C(═O)—, —C(═O)—O—, —O—C(═O)—O—, —C(═O)—NH—, —NH—, —NH—C(═NH)— (H may be substituted with a substituent such as an alkyl group and an acyl group), —S—, —S(═O)₂—, —S(═O)₂—O—, and a group represented by General Formulae —Y²¹—O—Y²²—, —Y²¹—O—, —Y²¹—C(═O)—O—, —C(═O)—O—Y²¹—, —[Y²¹—C(═O)—O]ₘ, —Y²²—, —Y²¹—O—C(═O)—Y²²—, or —Y²¹—S(═O)₂—O—Y²²— [in the formulae, Y²¹ and Y²² each independently represents a divalent hydrocarbon group which may have a substituent, O represents an oxygen atom, and m” represents an integer of 0 to 3] are exemplary examples.

In a case where the above-described divalent linking group containing a hetero atom is —C(═O)—NH—, —C(═O)—NH—C(═O)—, —NH—, or —NH—C(═NH)—, H may be substituted with a substituent such as an alkyl group and an acyl group. The substituent (alkyl group, acyl group, and the like) preferably has 1 to 10 carbon atoms, more preferably has 1 to 8 carbon atoms, and particularly preferably has 1 to 5 carbon atoms.

In General Formulae —Y²¹—O—Y²²—, —Y²¹—O—, —Y²¹—C(═O)—O—, —C(═O)—O—Y²¹——[Y²¹—C(═O)—O]ₘ—Y²²—, —Y²¹—O—C(═O)—Y²²—, or —Y²¹—S(═O)₂—O—Y²²—, Y²¹ and Y²² each independently represents a divalent hydrocarbon group which may have a substituent. As the divalent hydrocarbon group, the same ones as those described above are exemplary examples.

As Y²¹, a linear aliphatic hydrocarbon group is preferable, a linear alkylene group is more preferable, a linear alkylene group having 1 to 5 carbon atoms is still more preferable, and a methylene group or an ethylene group is particularly preferable.

As Y²², a linear or branched aliphatic hydrocarbon group is preferable, and a methylene group, an ethylene group, or an alkylmethylene group is more preferable. The alkyl group in the alkylmethylene group is preferably a linear alkyl group having 1 to 5 carbon atoms, more preferably a linear alkyl group having 1 to 3 carbon atoms, and most preferably a methyl group.

In the group represented by the formula —[Y²¹—C(═O)—O]ₘ—Y²²—, m” is an integer of 0 to 3, preferably an integer of 0 to 2, more preferably 0 or 1, and particularly preferably 1. That is, it is particularly preferable that the group represented by Formula —[Y²¹—C(═O)—O]ₘ—Y²²— be a group represented by Formula —Y²¹—C(═O)—O—Y²²—. Among these, a group represented by Formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As Y₁, a single bond, an ester bond [—C(═O)—O— or —O—C(═O)—], an ether bond (—O—), a linear or branched alkylene group, or a combination thereof is preferable; a single bond, a linear or branched alkylene group, or a combination of an ester bond [—C(═O)—O— or —O—C(═O)—] or an ether bond (—O—) with a linear or branched alkylene group is more preferable; and a linear or branched alkylene group or a combination of an ether bond and an alkylene group is still more preferable. As a group of the combination of an ether bond and an alkylene group, a group represented by —[(CH₂)ₖ₁—O—]ₖ₂— (k1 and k2 are integers of 1 to 6) is an exemplary example.

As the above-described alkylene group, an alkylene group having 1 to 10 carbon atoms is an exemplary example, and an alkylene group having 1 to 8 carbon atoms is preferable and an alkylene group having 1 to 6 carbon atoms is more preferable. k1 is preferably 2 or 3 and more preferably 2. k2 is preferably an integer of 1 to 4, more preferably an integer of 1 to 3, and still more preferably 1 or 2.

In Formula (r1), as the substrate adsorptive group contained in the substrate adsorptive group-containing group in Z¹, specifically, the same ones as those described above are exemplary examples. As the substrate adsorptive group, a hydroxy group, a carboxy group, a thiol group, a vinyl group, a bromine atom, an iodine atom, or a cyano group is preferable, and a hydroxy group is more preferable. As the substrate adsorptive group-containing group in Z¹, the substrate adsorptive group or a group in which one or more hydrogen atoms of a linear or branched alkylene group are substituted with substrate adsorptive groups is preferable. The above-described linear alkylene group preferably has 1 to 5 carbon atoms, more preferably has 1 to 3 carbon atoms, and still more preferably 1 or 2 carbon atoms. The above-described branched alkylene group preferably has 2 to 5 carbon atoms, more preferably has 2 or 3 carbon atoms, and still more preferably 2 carbon atoms. The number of substrate adsorptive groups contained in the substrate adsorptive group-containing group in Z¹ is preferably 1 to 3 and more preferably 1 or 2.

In Formula (r1), r1 is preferably 1 to 3, more preferably 1 or 2, and still more preferably 1.

R^{1c} and R^{1d} in Formula (n1) are preferably each a group represented by General Formula (r1-1) or General Formula (r1-2).

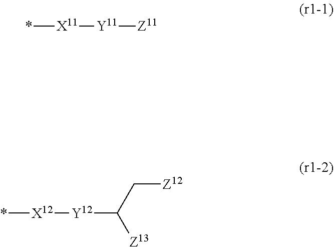

[in the formulae, X¹¹ and X¹² each independently represents a single bond, a methylene group, —COO—, or —O—; Y¹¹ and Y¹² each independently represents a single bond or a divalent linking group; Z¹¹ to Z¹³ each independently represents the substrate adsorptive group; provided that, in a case where X¹¹ is —COO— or —O—, Y¹¹ is not a single bond, and in a case where X¹² is —COO— or —O, Y¹² is not a single bond; and * represents a bonding site bonded with a benzene ring in General Formula (n1) described above].

In Formula (r1-1) or Formula (r1-2), as the divalent linking group in Y¹¹ and Y¹², the same ones as those for Y¹ in Formula (r1) described above are exemplary examples. As the divalent linking group in Y¹¹ and Y¹², a linear aliphatic hydrocarbon group which may have a substituent is preferable, and a linear alkylene group which may have a substituent is more preferable. As the above-described substituent, a divalent group which substitutes a methylene group is an exemplary example, in which as the divalent group, an ester bond or an ether bond is an exemplary example, and an ether bond is preferable.

As the divalent linking group in Y¹¹ and Y¹², a linear alkylene group having 1 to 10 carbon atoms or a group represented by —[(CH₂)ₖ₁—O—]ₖ₂—(CH₂)ₖ₃— (k1, k2, and k3 are integers of 1 to 6) is preferable. The above-described alkylene group preferably has 1 to 8 carbon atoms and more preferably has 1 to 6 carbon atoms. k1 is preferably 2 or 3 and more preferably 2. k2 is preferably an integer of 1 to 4, more preferably an integer of 1 to 3, and still more preferably 1 or 2. k3 is preferably 2 or 3 and more preferably 2.

In Formula (r1-1) or Formula (r1-2), as the substrate adsorptive group in Z¹¹ to Z¹³, the same ones as those described above are exemplary examples. As the substrate adsorptive group, a hydroxy group, a carboxy group, a thiol group, a vinyl group, a bromine atom, an iodine atom, or a cyano group is preferable, and a hydroxy group is more preferable.

Specific examples of R¹¹ and R^{1d} in Formula (n1) are shown below, but the present invention is not limited thereto. * represents a bonding site bonded to the benzene ring in Formula (n1) described above.

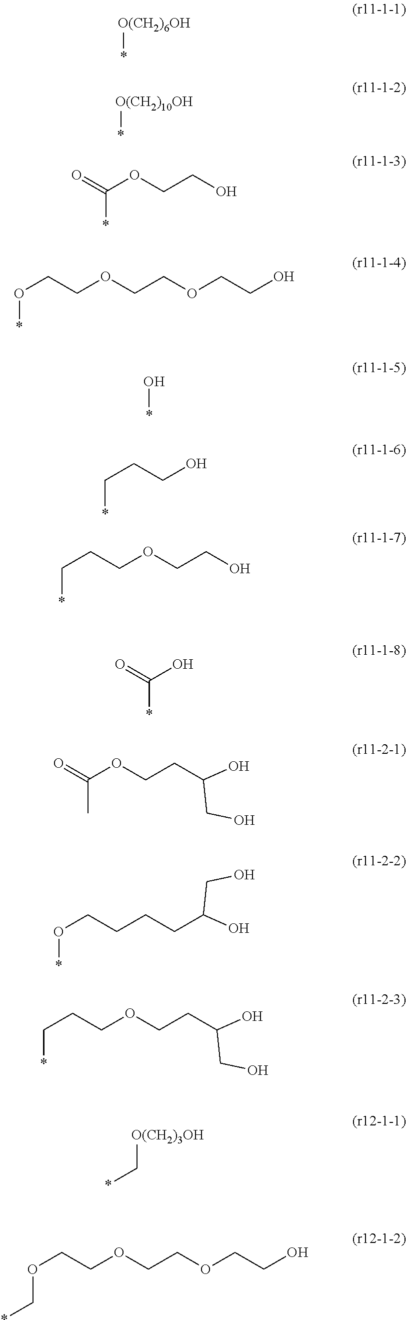

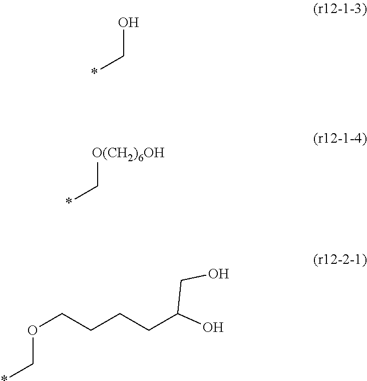

In Formula (n1), the substituent other than the substrate adsorptive group-containing group in R^{2c} and R^{2d} is not particularly limited. As the substituent other than the substrate adsorptive group-containing group, an alkyl group is an exemplary example. The above-described alkyl group may be linear or branched, but is preferably linear.

As the linear alkyl group, a linear alkyl group having 1 to 6 carbon atoms is an exemplary example, and the number of carbon atoms is preferably 1 to 5, more preferably 1 to 3, and still more preferably 1 or 2.

As the branched alkyl group, a branched alkyl group having 3 to 6 carbon atoms an exemplary example, and the number of carbon atoms is preferably 1 to 5, more preferably 1 to 3, and still more preferably 1 or 2.

In Formula (n1), m1 and n1 are each independently preferably an integer of 0 to 4, more preferably an integer of 0 to 3, still more preferably an integer of 0 to 2, and particularly preferably 0 or 1, on condition that m1+n1>1. It is preferable that both m1 and n1 be 1, m1 be 1 and n1 be 0, or m1 be 0 and n1 be 1.

In Formula (n1), m2 and n2 are each independently preferably an integer of 0 to 4, more preferably an integer of 0 to 3, still more preferably an integer of 0 to 2, and particularly preferably 0 or 1.

The block copolymer (P1) is preferably a block copolymer represented by General Formula (n1-1) or General Formula (n1-2).

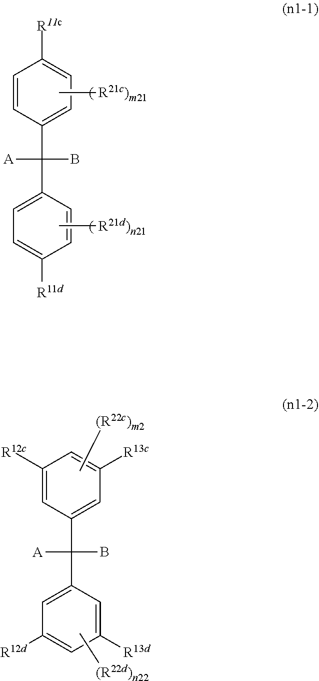

[in the formulae, A represents a first polymer block, B represents a second polymer block, R^{11c} and R^{11d} each independently represents a hydrogen atom or a group represented by General Formula (r11), where both R^{11c} and R^{11d} do not simultaneously represent a hydrogen atom, R^{12c}, R^{13c}, R^{12d}, and R^{13d} each independently represents a hydrogen atom or a group represented by General Formula (r12), where all of R^{12c}, R^{13c}, R^{12d}, and R^{13d} do not simultaneously represent a hydrogen atom, R^{21c}, R^{21d}, R^{22c}, and R^{22d} each independently represents a substituent other than the substrate adsorptive group-containing group, m21 and n21 each independently represents an integer of 0 to 4, m22 and n22 each independently represents an integer of 0 to 3, in a case where m21 is an integer of 2 or more, a plurality of R^{21c}'s may be the same as or different from each other, in a case where n21 is an integer of 2 or more, a plurality of R^{21d}'s may be the same as or different from each other, in a case where m22 is an integer of 2 or more, a plurality of R^{22c}'s may be the same as or different from each other, and in a case where n22 is an integer of 2 or more, a plurality of R^{22d}'s may be the same as or different from each other].

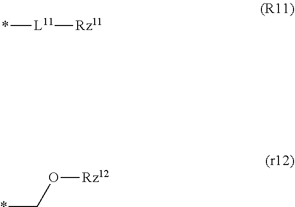

[in the formulae, L¹¹ represents a single bond, —COO—, or —O—, Rz¹¹ represents the substrate adsorptive group-containing group; and R²¹² represents the substrate adsorptive group-containing group or a hydrogen atom].

In Formula (n1-1), as the substituent other than the substrate adsorptive group-containing group in R^{21c} and R^{21d}, the same ones as those in R^{2c} and R^{2d} in Formula (n1) described above are exemplary examples. As the substituent in R^{21c} and R^{21d}, a linear or branched alkyl group is an exemplary example, the number of carbon atoms therein is preferably 1 to 6, more preferably 1 to 5, still more preferably 1 to 3, and even more preferably 1 or 2.

In Formula (n1-1), m21 and n21 are preferably an integer of 0 to 3, more preferably an integer of 0 to 2, still more preferably 0 or 1, and particularly preferably 0.

In Formula (n1-2), as the substituent other than the substrate adsorptive group-containing group in R^{22c} and R^{22d}, the same ones as those in R^{2C} and R^{2d} in Formula (n1) described above are exemplary examples. As the substituent in R^{22C} and R^{22d}, a linear or branched alkyl group is an exemplary example, the number of carbon atoms therein is preferably 1 to 6, more preferably 1 to 5, still more preferably 1 to 3, and even more preferably 1 or 2.

In Formula (n1-2), m22 and n22 are preferably an integer of 0 to 3, more preferably an integer of 0 to 2, still more preferably 0 or 1, and particularly preferably 0.

In Formula (n1-1), R^{11c} and R^{11d} each independently represents a hydrogen atom or the group represented by General Formula (r11).

In Formula (n1-2), R^{12c}, R^{13c}, R^{12d}, and R^{13d} each independently represents a hydrogen atom or the group represented by General Formula (r12).

As the substrate adsorptive group-containing group in Rz¹¹ and Rz¹² in Formulae (r11) and (r12), the same ones as those in R^{1c} and R^{1d} in Formula (n1) described above are exemplary examples.

Rz¹¹ and Rz¹² are each preferably represented by General Formula (r1-1-1) or General Formula (r1-2-1).

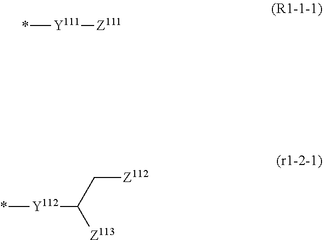

[in the formulae, Y¹¹¹ and Y¹¹² each independently represents a single bond or a divalent linking group; Z¹¹¹ to Z¹¹³ each independently represents a substrate adsorptive group; provided that, in a case where L¹¹ in General Formula (r11) described above is —COO— or —O—, Y¹¹¹ is not a single bond; and * represents a bonding site].

In Formula (r1-1-1) or Formula (r1-2-1), as the divalent linking group in Y¹¹¹ and Y¹¹², the same ones as the divalent linking groups in Y¹¹ and Y¹² in Formula (r1-1) or Formula (r1-2) described above are exemplary examples. As the divalent linking group in Y¹¹¹ and Y¹¹², a linear alkylene group having 1 to 10 carbon atoms or a group represented by —[(CH₂)ₖ₁—O—]ₖ₂—(CH₂)ₖ₃— (k1, k2, and k3 are integers of 1 to 6) is preferable. The above-described alkylene group preferably has 1 to 8 carbon atoms and more preferably has 1 to 6 carbon atoms. k1 is preferably 2 or 3 and more preferably 2. k2 is preferably an integer of 1 to 4, more preferably an integer of 1 to 3, and still more preferably 1 or 2. k3 is preferably 2 or 3 and more preferably 2.

In Formula (r1-1-1) or Formula (r1-2-1), as the substrate adsorptive group in Z¹¹¹ to Z¹¹³, the same ones as those described above are exemplary examples. As the substrate adsorptive group, a hydroxy group, a carboxy group, a thiol group, a vinyl group, a bromine atom, an iodine atom, or a cyano group is preferable, and a hydroxy group is more preferable.

As R^{11c} and R^{11d} in Formula (n1-1), specifically, a group represented by any one of Formulae (r11-1-1) to (r11-1-8) and (r11-2-1) to (r11-2-3) is exemplary.

As R^{21c}, R^{21d}, R^{22c}, and R^{22d} in Formula (n1-2), specifically, a group represented by any one of Formulae (r12-1-1) to (r12-1-4-), and (r12-2-1) is exemplary.

Specific examples of the block copolymer (P1) are shown below, but the present invention is not limited thereto. In the following formulae, A and B are the same as those in Formula (n1) described above.

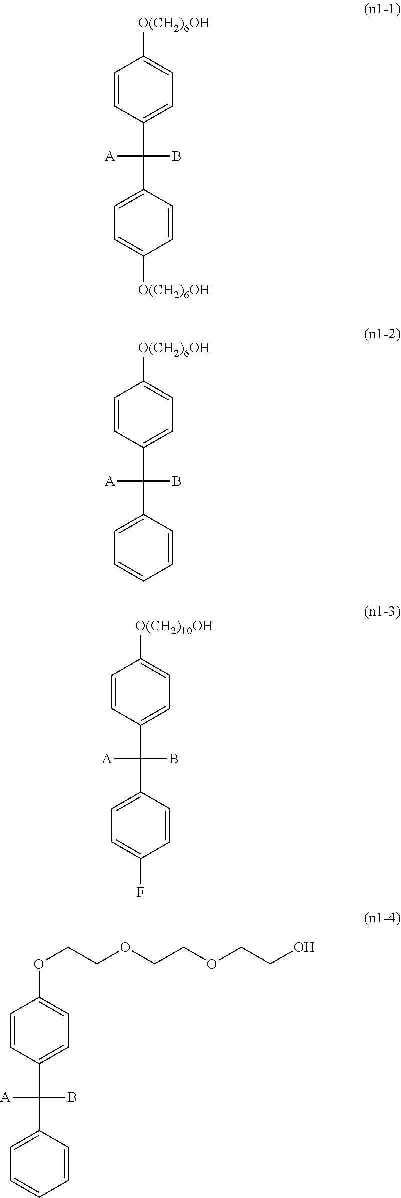

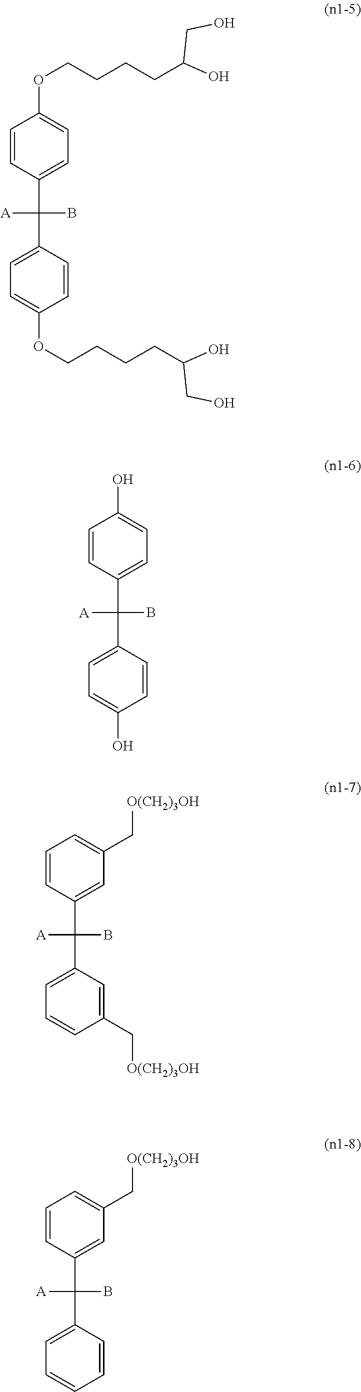

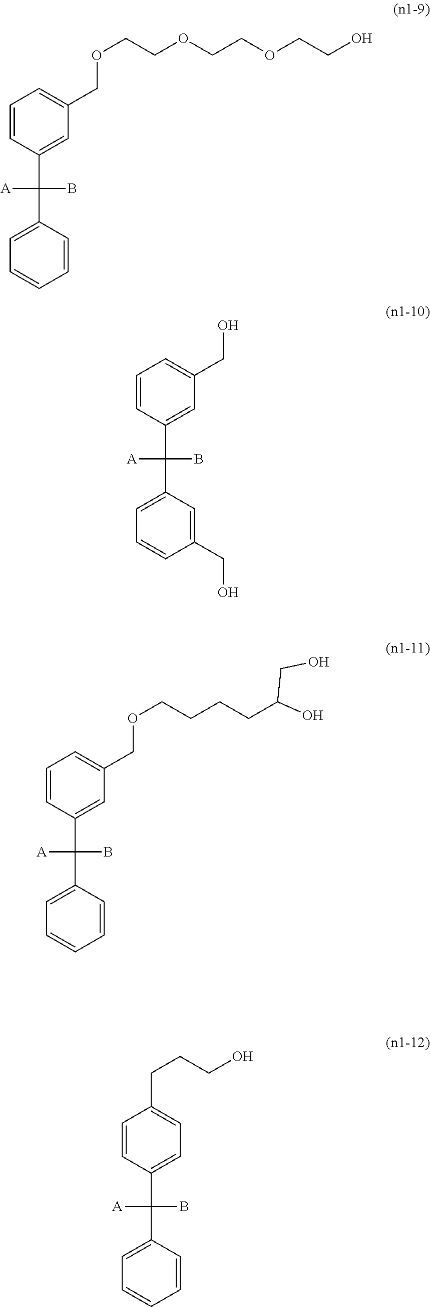

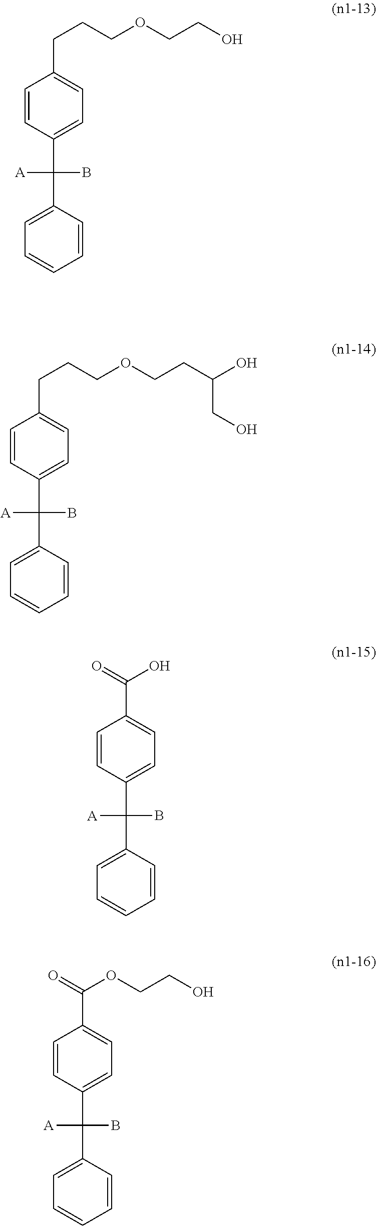

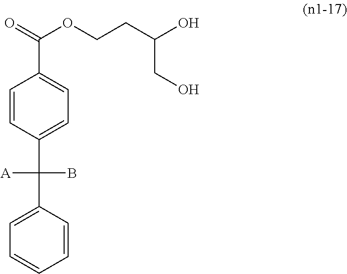

### First Polymer Block (A)

In Formula (n1), the first polymer block in A (hereinafter, also referred to as “first polymer block (A)”) is preferably a hydrophobic polymer block (hereinafter, also referred to as “block (b12)”).

The hydrophobic polymer block (b12) is a block consisting of a polymer (hydrophobic polymer) obtained by polymerizing a monomer having a relatively low affinity for water, as compared with a monomer providing a constitutional unit for other polymer blocks constituting the block copolymer.

It is preferable that the block (b12) have a hydrophobic constitutional unit (Na). As the constitutional unit (Na), for example, a block in which constitutional units derived from styrene or a styrene derivative are repeatedly bonded is an exemplary example.

As the styrene derivative, for example, a compound in which a hydrogen atom at an α-position of styrene is substituted with a substituent such as an alkyl group and a halogenated alkyl group, and a derivative thereof are exemplary examples. As the above-described derivative thereof, a compound in which a substituent is bonded to a benzene ring of the styrene which may be substituted in the hydrogen atom at the α-position is an exemplary example. As the above-described substituent, for example, an alkyl group having 1 to 5 carbon atoms, a halogenated alkyl group having 1 to 5 carbon atoms, a hydroxyalkyl group, and the like are exemplary examples.

As the styrene derivative, specifically, α-methylstyrene, 2-methylstyrene, 3-methylstyrene, 4-methylstyrene, 4-t-butylstyrene, 4-n-octylstyrene, and 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, 4-vinylbenzyl chloride, and the like are exemplary examples.

As the constitutional unit (Na), from the viewpoint that the surface of the undercoat agent layer is more likely to be stabilized, a constitutional unit derived from styrene or the styrene derivative is preferable. That is, a constitutional unit (u1) including a styrene skeleton which may have a substituent is more preferable.

### Regarding Constitutional Unit (u1)

The constitutional unit (u1) is a constitutional unit including a styrene skeleton which may have a substituent.

The styrene skeleton having a substituent refers to a styrene skeleton in which an α-position of styrene or a part or all of hydrogen atoms in a benzene ring are substituted with a substituent.

As the substituent in the constitutional unit (u1), a halogen atom or a linear, branched, cyclic, or combined hydrocarbon group having 1 to 20 carbon atoms, which may contain an oxygen atom, a halogen atom, or a silicon atom is an exemplary example.

As the halogen atom as the substituent in the constitutional unit (u1), a fluorine atom, a bromine atom, a chlorine atom, and an iodine atom are exemplary examples, and a fluorine atom, a chlorine atom, or a bromine atom is preferable and a fluorine atom is more preferable.

In the substituent in the constitutional unit (u1), the hydrocarbon group has 1 to 20 carbon atoms. In addition, such a hydrocarbon group is a linear, branched, cyclic, or combined hydrocarbon group, and may contain an oxygen atom, a halogen atom, or a silicon atom.

As such a hydrocarbon group, for example, a linear, branched, or cyclic alkyl group, and a linear, branched, or cyclic aryl group are exemplary examples.

The alkyl group as the hydrocarbon group preferably has 1 to 10 carbon atoms, more preferably has 1 to 8 carbon atoms, and still more preferably has 1 to 6 carbon atoms.

The alkyl group herein may be a partially or completely halogenated alkyl group (halogenated alkyl group), an alkylsilyl group in which a carbon atom constituting the alkyl group is substituted with a silicon atom or an oxygen atom, an alkylsilyloxy group, or an alkoxy group.

The partially halogenated alkyl group means an alkyl group in which a part of the hydrogen atoms bonded to the alkyl group are substituted with halogen atoms, and the completely halogenated alkyl group means an alkyl group in which all of the hydrogen atoms bonded to the alkyl group are substituted with halogen atoms. As the halogen atom, a fluorine atom, a bromine atom, a chlorine atom, and an iodine atom are exemplary examples, and a fluorine atom, a chlorine atom, or a bromine atom is preferable and a fluorine atom is more preferable (that is, a fluorinated alkyl group is preferable).

As the above-described alkylsilyl group, a trialkylsilyl group or a trialkylsilyl alkyl group is preferable, and for example, a trimethylsilyl group, a trimethylsilylmethyl group, a trimethylsilyl ethyl group, and a trimethylsilyl-n-propyl group are suitable exemplary examples.

As the above-described alkylsilyloxy group, a trialkylsilyloxy group or a trialkylsilyloxy alkyl group is preferable, and for example, a trimethylsilyloxy group, a trimethylsilylmethyloxy group, a trimethylsilyloxy ethyl group, and a trimethylsilyloxy-n-propyl group are suitable exemplary examples.

The above-described alkoxy group preferably has 1 to 10 carbon atoms, more preferably has 1 to 8 carbon atoms, and still more preferably has 1 to 6 carbon atoms.

The aryl group as the hydrocarbon group has 4 to 20 carbon atoms, preferably has 4 to 10 carbon atoms and more preferably has 6 to 10 carbon atoms.

As a preferred aspect of the constitutional unit (u1), for example, a constitutional unit represented by General Formula (u1-1) or General Formula (u1-2) is an exemplary example. In the present invention, the constitutional unit (u1) is preferably a constitutional unit represented by General Formula (u1-1).

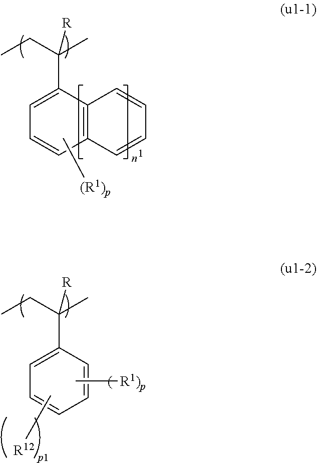

[in the formulae, R is a hydrogen atom, an alkyl group having 1 to 5 carbon atoms, or a fluorinated alkyl group having 1 to 5 carbon atoms; R¹ is a fluorine atom or a linear, branched, cyclic, or combined hydrocarbon group having 1 to 20 carbon atoms, which may contain an oxygen atom, a fluorine atom, or a silicon atom; p is an integer of 0 to 5, n1 is 0 or 1; and R¹² is an aromatic hydrocarbon ring which may have a substituent; and p1 is an integer of 1 to 5].

In Formula (u1-1) or Formula (u1-2), R is a hydrogen atom, an alkyl group having 1 to 5 carbon atoms, or a fluorinated alkyl group having 1 to 5 carbon atoms.

The alkyl group having 1 to 5 carbon atoms in R is preferably a linear or branched alkyl group having 1 to 5 carbon atoms, and specifically, a methyl group, an ethyl group, an n-propyl group, an isopropyl group, an n-butyl group, an isobutyl group, a tert-butyl group, a pentyl group, an isopentyl group, a neopentyl group, and the like are exemplary examples.

The fluorinated alkyl group having 1 to 5 carbon atoms in R is a group obtained by substituting a part or all of the hydrogen atoms of the above-described alkyl group having 1 to 5 carbon atoms with a fluorine atom.

As R, a hydrogen atom, an alkyl group having 1 to 5 carbon atoms, or a fluorinated alkyl group having 1 to 5 carbon atoms is preferable, a hydrogen atom or an alkyl group having 1 to 5 carbon atoms is more preferable, a hydrogen atom or a methyl group is still more preferable, and a hydrogen atom is particularly preferable.

In Formula (u1-1) or Formula (u1-2), R¹ is a fluorine atom or a linear, branched, cyclic, or combined hydrocarbon group having 1 to 20 carbon atoms, which may contain an oxygen atom, a fluorine atom, or a silicon atom.

In the constitutional unit (u1), free energy of the surface of the undercoat agent layer is regulated by the benzene ring to which R¹ is bonded as a substituent, and the layer containing the block copolymer, formed on the undercoat agent layer, can be favorably phase-separated into a vertical cylinder pattern or the like.

R¹ in Formula (u1-1) or Formula (u1-2) is the same as in the description for the substituent in the constitutional unit (u1) above (a fluorine atom, an oxygen atom, or a linear, branched, cyclic, or combined hydrocarbon group having 1 to 20 carbon atoms, which may contain a fluorine atom or a silicon atom).

Among these, as R¹, since the layer containing the block copolymer, formed on the undercoat agent layer, can be favorably phase-separated, a linear, branched, cyclic, or combined hydrocarbon group having 1 to 20 carbon atoms, which may contain an oxygen atom, a fluorine atom, or a silicon atom, is preferable.

Among these, an alkyl group having 1 to 20 carbon atoms, which may contain an oxygen atom or a fluorine atom, is more preferable, an alkyl group having 1 to 6 carbon atoms, a fluorinated alkyl group having 1 to 6 carbon atoms, or an alkoxy group having 1 to 6 carbon atoms is still more preferable, and an alkyl group having 1 to 6 carbon atoms is particularly preferable.

The alkyl group in R¹ preferably has 1 to 6 carbon atoms, more preferably has 3 to 6 carbon atoms, still more preferably has 3 or 4 carbon atoms, and particularly preferably has 4 carbon atoms. As the alkyl group in R¹, a linear alkyl group or a branched alkyl group is preferable, and for example, a methyl group, an ethyl group, an n-propyl group, an isopropyl group, an n-butyl group, an isobutyl group, and a tert-butyl group are suitable exemplary examples. Among these, an n-propyl group, an isopropyl group, an n-butyl group, an isobutyl group, or a tert-butyl group is more preferable, an n-butyl group, an isobutyl group, or a tert-butyl group is still more preferable, and a tert-butyl group is particularly preferable.

As the fluorinated alkyl group in R¹, a group in which a part or all of the hydrogen atoms in the above-described alkyl group in R¹ are substituted with a fluorine atom is an exemplary example. The fluorinated alkyl group in R¹ preferably has 1 to 6 carbon atoms, more preferably has 3 to 6 carbon atoms, and still more preferably has 3 or 4 carbon atoms.

The alkoxy group in R¹ preferably has 1 to 6 carbon atoms, more preferably has 1 to 4 carbon atoms, and still more preferably has 2 carbon atoms. As the alkoxy group in R¹, a linear alkoxy group or a branched alkoxy group is preferable, for example, a methoxy group, an ethoxy group, an isopropoxy group, and a t-butoxy group are suitable exemplary examples, and an ethoxy group is particularly preferable.

In Formula (u1-1) or Formula (u1-2), p is an integer of 0 to 5, preferably an integer of 0 to 3, more preferably an integer of 0 to 2, still more preferably 0 or 1, and particularly preferably 1.

In Formula (u1-2), p1 is 0 or 1, preferably 0.

In Formula (u1-2), R¹² is an aromatic hydrocarbon ring which may have a substituent. As the aromatic hydrocarbon ring of R¹², aromatic hydrocarbon rings such as benzene, naphthalene, anthracene, and phenanthrene are exemplary examples. In addition, as the substituent which may be included in R¹², an alkyl group having 1 to 5 carbon atoms, an alkoxy group having 1 to 5 carbon atoms, a fluorinated alkyl group having 1 to 5 carbon atoms, a fluorine atom, a trialkylsilyl group, an alkoxysilyl group, and the like are exemplary examples.

In Formula (u1-2), p1 is an integer of 1 to 5.

Specific examples of the constitutional unit of the block (b12) are shown below. In the formulae, R¹¹ is a hydrogen atom or a methyl group.

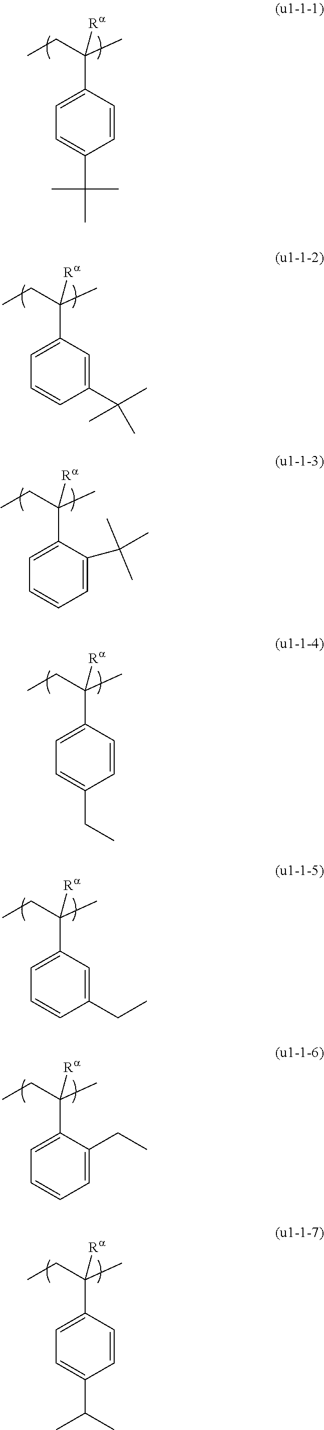

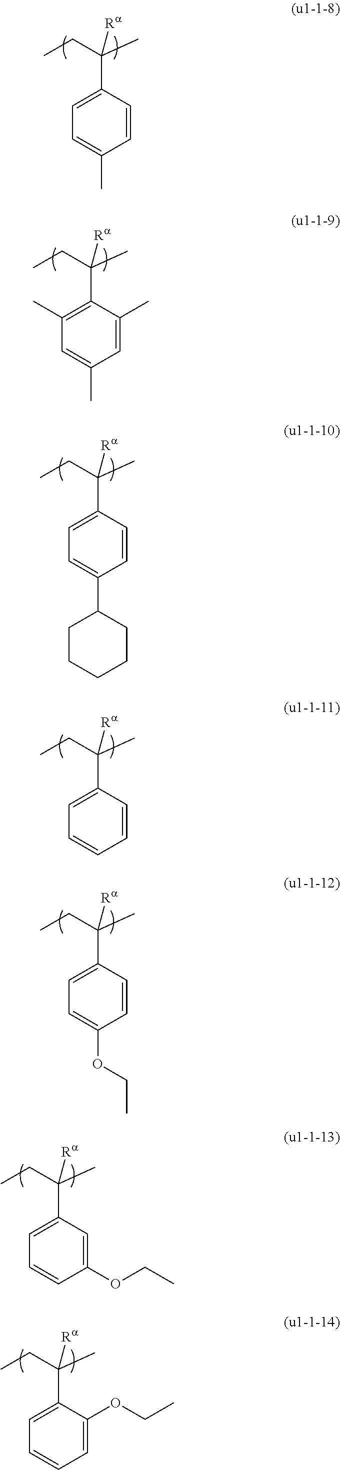

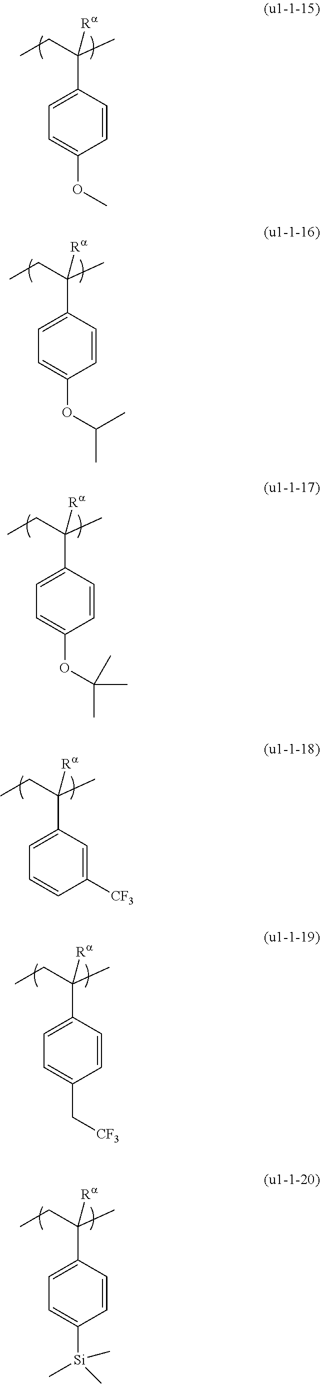

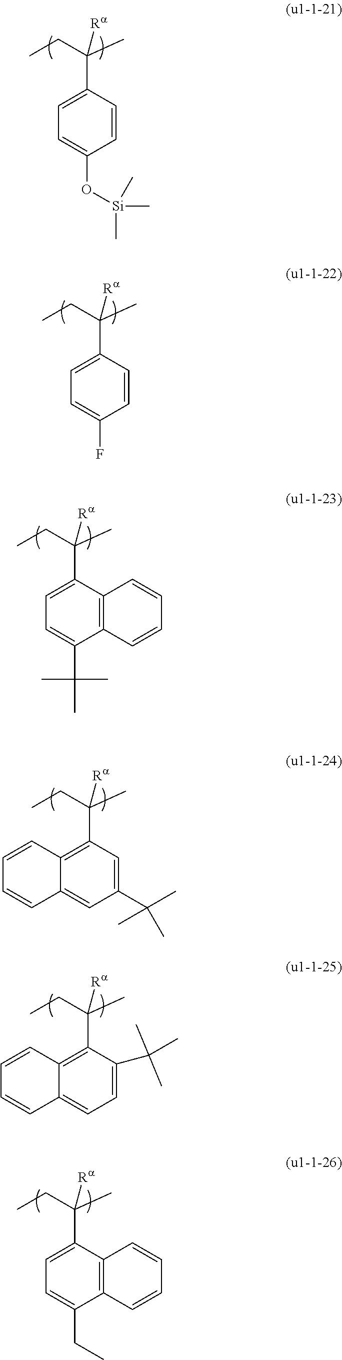

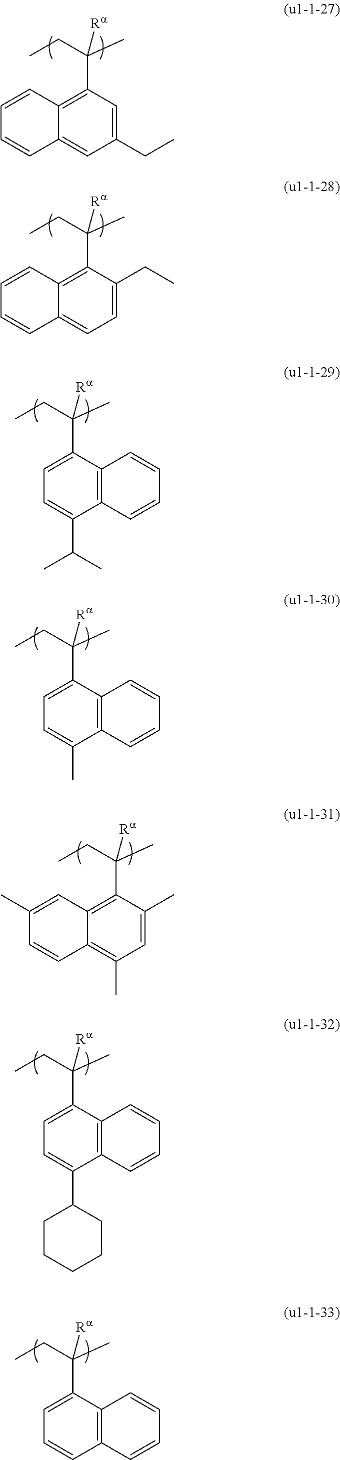

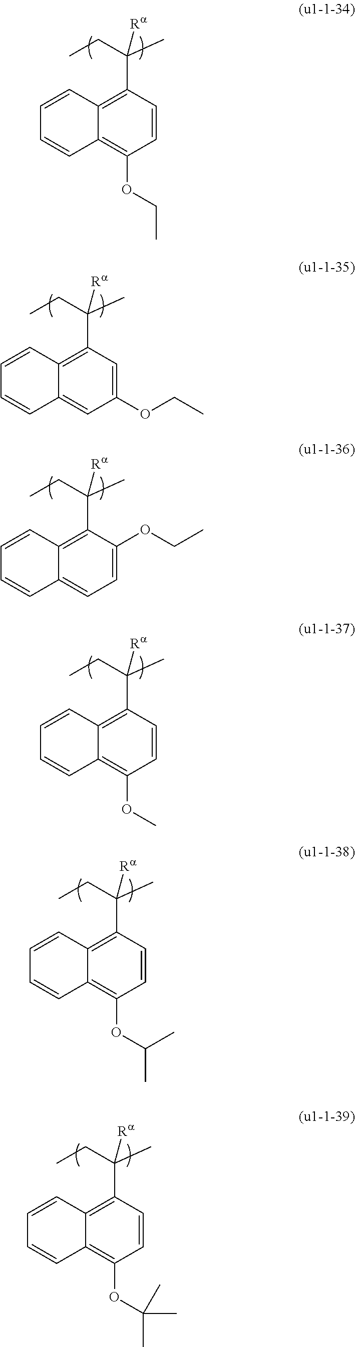

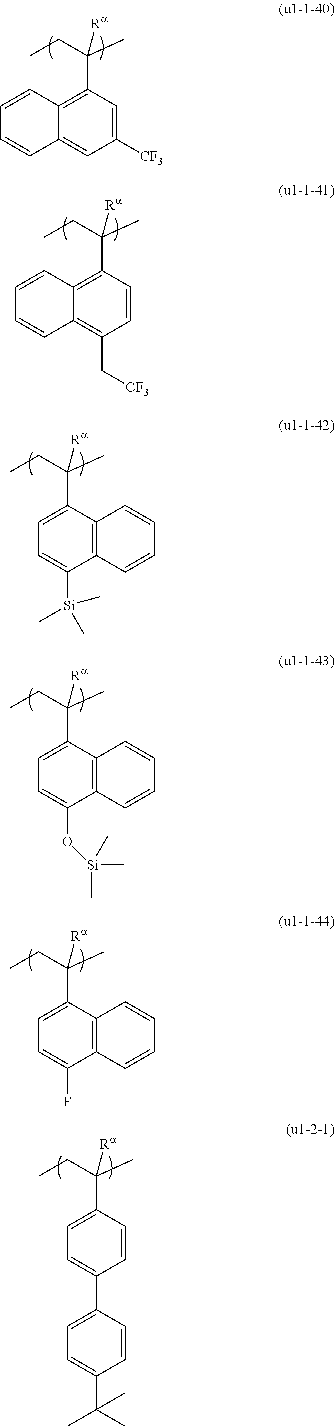

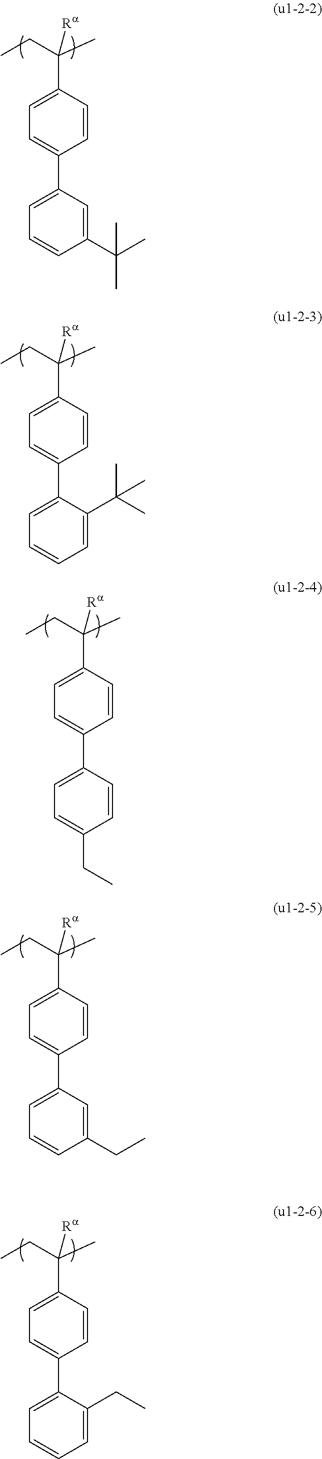

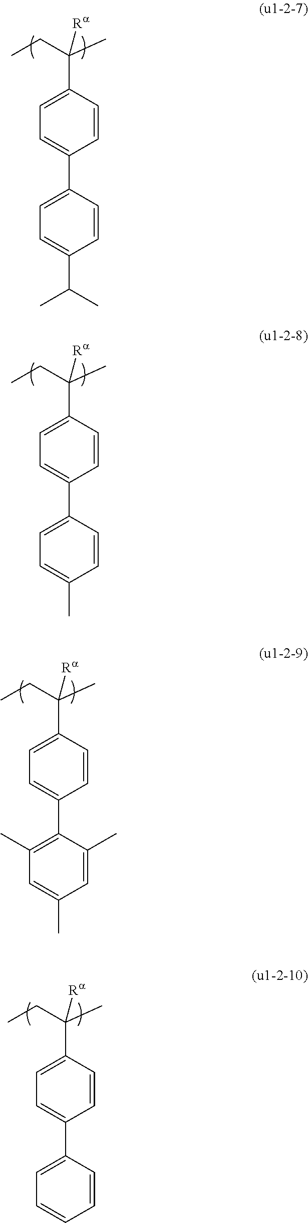

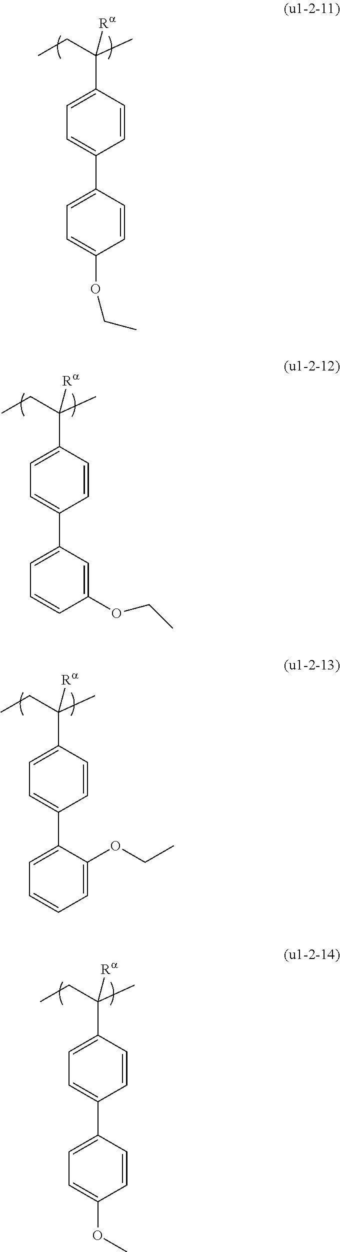

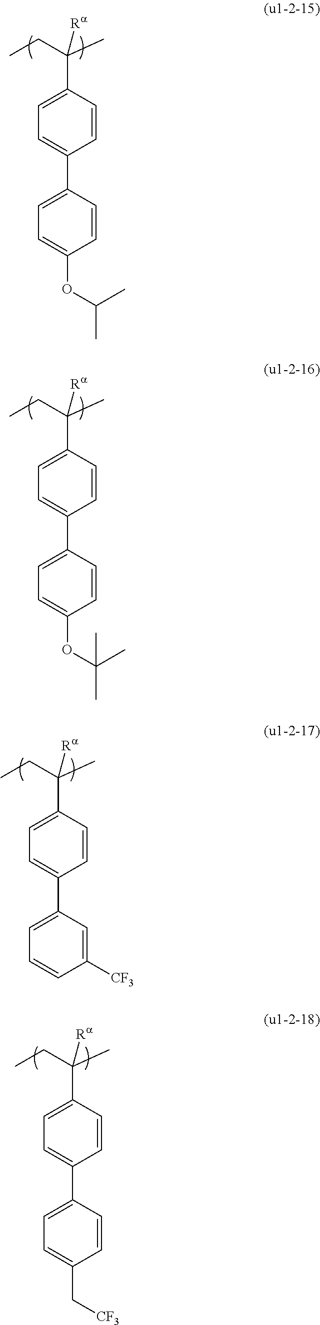

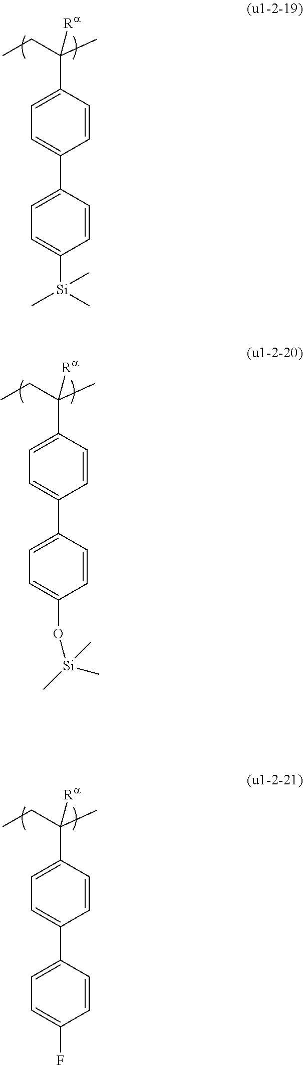

As the constitutional unit of the block (b12), one kind may be used alone, or two or more kinds may be used in combination.

It is preferable that the block (b12) contain the constitutional unit (u1) as the constitutional unit (Na). As the constitutional unit (u1), at least one kind selected from the group consisting of constitutional units each represented by Chemical Formulae (u1-1-1) to (u1-1-22) is preferable, at least one kind selected from the group consisting of constitutional units each represented by Chemical Formulae (u1-1-1) to (u1-1-14) is more preferable, at least one kind selected from the group consisting of constitutional units each represented by Chemical Formulae (u1-1-1) to (u1-1-11) is still more preferable, at least one kind selected from the group consisting of constitutional units each represented by Chemical Formulae (u1-1-1) to (u1-1-6), and (u1-1-11) is particularly preferable, and at least one kind selected from the group consisting of constitutional units each represented by Chemical Formulae (u1-1-1) to (u1-1-3), and (u1-1-11) is most preferable.

A proportion of the constitutional unit (u1) in the block (b12) is preferably 25 mol % or more, more preferably 50 mol % or more, and still more preferably 75 to 100 mol % with respect to the total of all constitutional units constituting the block (b12).

In a case where the proportion of the constitutional unit (u1) in the block (b12) is equal to or more than the preferred lower limit value, the surface of the undercoat agent layer is further stabilized, and the layer containing the block copolymer, formed on the undercoat agent layer, can be favorably phase-separated.

### Second Polymer Block (B)

In Formula (n1), the second polymer block in B (hereinafter, also referred to as “second polymer block (B)”) is preferably a hydrophilic polymer block (hereinafter, also referred to as “block (b22)”).

The hydrophilic polymer block (b22) is a block consisting of a polymer (hydrophilic polymer) obtained by polymerizing a monomer having a relatively high affinity for water, as compared with a monomer providing a constitutional unit for other polymer blocks constituting the block copolymer.

It is preferable that the block (b22) have a hydrophilic constitutional unit (Nb). As the constitutional unit (Nb), for example, a block in which constitutional units derived from (α-substituted) acrylic acid ester are repeatedly bonded, a block in which constitutional units derived from (α-substituted) acrylic acid are repeatedly bonded, and the like are exemplary examples.

As the (α-substituted) acrylic acid ester, for example, acrylic acid ester and acrylic acid ester in which a hydrogen atom bonded to a carbon atom at an α-position is substituted with a substituent are exemplary examples. As the above-described substituent, for example, an alkyl group having 1 to 5 carbon atoms, a fluorinated alkyl group having 1 to 5 carbon atoms, a hydroxyalkyl group, and the like are exemplary examples.

Specifically, as the (α-substituted) acrylic acid ester, acrylic acid esters such as methyl acrylate, ethyl acrylate, propyl acrylate, n-butyl acrylate, t-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, and propyltrimethoxysilane acrylate; methacrylic acid esters such as methyl methacrylate, ethyl methacrylate, propyl methacrylate, n-butyl methacrylate, t-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, and propyltrimethoxysilane methacrylate; and the like are exemplary examples.

As the (α-substituted) acrylic acid, for example, acrylic acid and acrylic acid in which a hydrogen atom bonded to a carbon atom at an α-position is substituted with a substituent are exemplary examples. As the above-described substituent, for example, an alkyl group having 1 to 5 carbon atoms, a fluorinated alkyl group having 1 to 5 carbon atoms, a hydroxyalkyl group, and the like are exemplary examples.

As the (α-substituted) acrylic acid, specifically, acrylic acid, methacrylic acid, and the like are exemplary examples.

As the constitutional unit (Nb), from the viewpoint that the surface of the undercoat agent layer is more likely to be stabilized, a constitutional unit derived from the (α-substituted) acrylic acid ester or a constitutional unit derived from the (α-substituted) acrylic acid (that is, a constitutional unit (u2) derived from acrylic acid or acrylic acid ester, which may be substituted with a substituent at a hydrogen atom bonded to a carbon atom at an α-position) is preferable.

### Regarding Constitutional Unit (u2)

The constitutional unit (u2) is a constitutional unit derived from acrylic acid or acrylic acid ester, which may be substituted with a substituent at a hydrogen atom bonded to a carbon atom at an α-position.

As a preferred aspect of the constitutional unit (u2), for example, a constitutional unit represented by General Formula (u2-1) is an exemplary example.

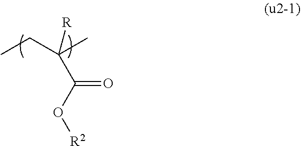

[in the formula, R is a hydrogen atom, an alkyl group having 1 to 5 carbon atoms, or a fluorinated alkyl group having 1 to 5 carbon atoms; and R² is an alkyl group which may have a linear or branched substituent having 1 to 20 carbon atoms; provided that R² does not have the substrate adsorptive group].

In Formula (u2-1), R is a hydrogen atom, an alkyl group having 1 to 5 carbon atoms, or a fluorinated alkyl group having 1 to 5 carbon atoms. R in Formula (u2-1) is the same as R in Formula (u1-1) described above.

As R, a hydrogen atom, an alkyl group having 1 to 5 carbon atoms, or a fluorinated alkyl group having 1 to 5 carbon atoms is preferable, a hydrogen atom or an alkyl group having 1 to 5 carbon atoms is more preferable, a hydrogen atom or a methyl group is still more preferable, and a hydrogen atom is particularly preferable.

In Formula (u2-1), R² is an alkyl group which may have a linear or branched substituent having 1 to 20 carbon atoms. However, R² does not have the substrate adsorptive group as a substituent.

The alkyl group in R² has 1 to 20 carbon atoms, and the number of carbon atoms is preferably 1 to 10, more preferably 1 to 8, still more preferably 1 to 6, and particularly preferably 1 to 4.

The alkyl group in R² may be linear or branched.

The alkyl group in R² is preferably a methyl group or an ethyl group, and more preferably a methyl group.

The constitutional unit (u2) may be a constitutional unit represented by General Formula (u2-2).

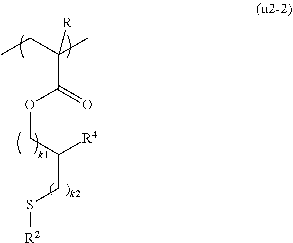

[in the formula, R is a hydrogen atom, an alkyl group having 1 to 5 carbon atoms, or a fluorinated alkyl group having 1 to 5 carbon atoms; R⁴ is a hydrogen atom or a hydroxy group; k¹ and k² are each independently an integer of 1 to 5; and R² is an alkyl group which may have a silicon atom or a fluorine atom].

In Formula (u2-2), R is a hydrogen atom, an alkyl group having 1 to 5 carbon atoms, or a fluorinated alkyl group having 1 to 5 carbon atoms. R in Formula (u2-2) is the same as R in Formula (u1-1) described above.

As R, a hydrogen atom, an alkyl group having 1 to 5 carbon atoms, or a fluorinated alkyl group having 1 to 5 carbon atoms is preferable, a hydrogen atom or an alkyl group having 1 to 5 carbon atoms is more preferable, a hydrogen atom or a methyl group is still more preferable, and a hydrogen atom is particularly preferable.

In Formula (u2-2), R² is an alkyl group which may have a silicon atom or a fluorine atom. The above-described alkyl group is preferably a linear or branched alkyl group, and more preferably a linear alkyl group. In a case where the above-described alkyl group is linear, it is sufficient that the number of carbon atoms therein be 1 or more, preferably 2 or more. The upper limit of the number of carbon atoms in the above-described linear alkyl group is not particularly limited, but from the viewpoint of phase separation performance, it is preferably 15 or less, more preferably 10 or less, still more preferably 8 or less, even more preferably 6 or less, and particularly preferably 5 or less. In a case where the above-described alkyl group is branched, it is sufficient that the number of carbon atoms therein be 3 or more. The upper limit of the number of carbon atoms in the above-described branched alkyl group is not particularly limited, but from the viewpoint of phase separation performance, it is preferably 15 or less, more preferably 10 or less, still more preferably 8 or less, even more preferably 6 or less, and particularly preferably 5 or less. The number of carbon atoms in the above-described alkyl group is preferably 2 to 15, more preferably 2 to 10, still more preferably 2 to 8, even more preferably 2 to 6, and particularly preferably 2 to 5.

The alkyl group of R² is preferably a linear alkyl group having 2 to 5 carbon atoms.

The alkyl group of R² may have a silicon atom or a fluorine atom. In a case where the alkyl group of R² has a fluorine atom or a carboxy group, the fluorine atom or carboxy group may be a substituent which substitutes a hydrogen atom of the alkyl group. The number of hydrogen atoms substituted in the above-described group is not particularly limited, but is preferably 1 to 3.

In a case where the alkyl group of R^{z} has a silicon atom, the silicon atom may be a substituent which substitutes a methylene group (—CH₂—) in the alkyl group. The number of methylene groups substituted with the silicon atom is not particularly limited, but is preferably 1.

R² is preferably an alkyl group which may be substituted with an alkylsilyl group or a fluoromethyl group. The alkyl group in the above-described alkylsilyl group preferably has 1 to 3 carbon atoms and more preferably has 1 or 2 carbon atoms. The above-described alkylsilyl group is preferably a trialkylsilyl group, more preferably a triethylsilyl group or a trimethylsilyl group, and still more preferably a trimethylsilyl group. The above-described fluoromethyl group is preferably a trifluoromethyl group.

In Formula (u2-2), k1 and k2 are preferably 1 to 3, more preferably 1 or 2, and still more preferably 1.

Specific examples of the constitutional unit of the block (b22) are shown below. In the formulae, R¹¹ is a hydrogen atom or a methyl group.

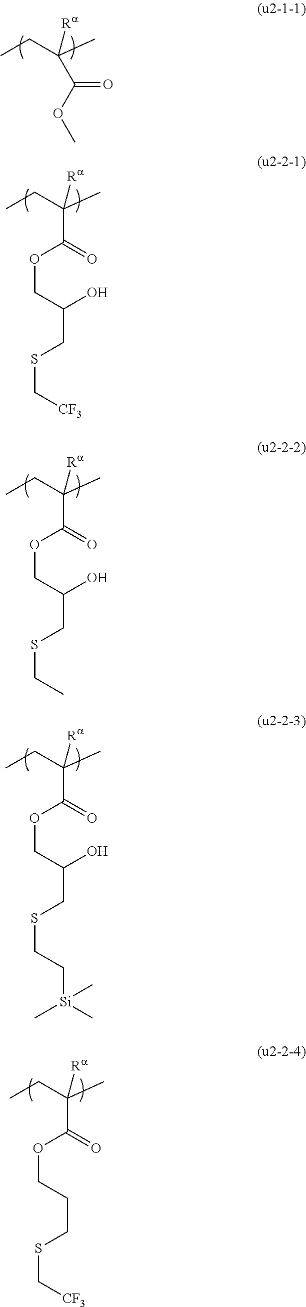

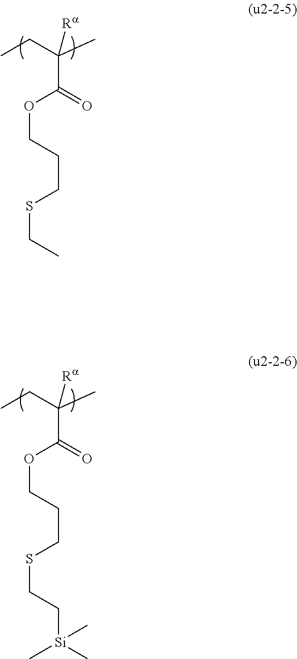

As the constitutional unit of the block (b22), one kind may be used alone, or two or more kinds may be used in combination.

The constitutional unit (Nb) preferably contains the constitutional unit (u2).

As the constitutional unit (u2), at least one kind selected from the group consisting of constitutional units each represented by Chemical Formulae (u2-1-1), and (u2-2-1) to (u2-1-6) is preferable.

A proportion of the constitutional unit (u2) in the block (b22) is preferably 25 mol % or more, more preferably 50 mol % or more, and still more preferably 75 to 100 mol % with respect to the total of all constitutional units constituting the block (b22).

In a case where the proportion of the constitutional unit (u2) in the block (b22) is equal to or more than the preferred lower limit value, the surface of the undercoat agent layer is further stabilized, and the layer containing the block copolymer, formed on the undercoat agent layer, can be favorably phase-separated.

It is preferable that the first polymer block (A) and the second polymer block (B) not have a substrate adsorptive group bonded to a primary carbon atom.

It is preferable that the first polymer block (A) and the second polymer block (B) not have a constitutional unit (u0) represented by any one of General Formulae (u0-1) to (u0-4).

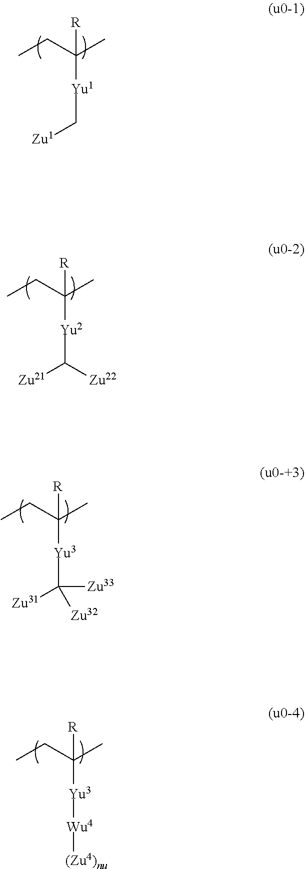

[in the formulae, R represents a hydrogen atom, an alkyl group having 1 to 5 carbon atoms, or a fluorinated alkyl group having 1 to 5 carbon atoms; Yu¹, Yu², Yu³, and Yu⁴ each independently represents a divalent linking group; Zu¹, Zu²¹, Zu²², Zu³¹, Zu³², Zu³³, and Zu⁴ each independently represents a substrate adsorptive group; Wu⁴ represents a cyclic group; and nu represents an integer of 1 or more within a limit of valence].

In Formulae (u0-1) to (u0-4), as the divalent linking group in Yu^{I}, Yu², Yu³, and Yu⁴, the same ones as the divalent linking groups in Y¹ in Formula (r1) described above are exemplary examples. As the divalent linking group in Yu¹, Yu², Yu³, and Yu⁴, a hydrocarbon group having 1 to 10 carbon atoms, which may have a substituent, is an exemplary example.

In Formulae (u0-1) to (u0-4), as the substrate adsorptive group in Zu¹, Zu²¹, Zu²², Zu³¹, Zu³², Zu³³, and Zu⁴, for example, a hydroxy group, a carboxy group, a thiol group, a vinyl group, a bromine atom, an iodine atom, an amino group, an azide group, a formyl group, an epoxy group, and a cyano group are exemplary examples. As the substrate adsorptive group in Zu¹, a hydroxy group, a carboxy group, a thiol group, a vinyl group, a bromine atom, an iodine atom, or a cyano group is preferable, and a hydroxy group is more preferable.

In Formula (u0-4), the cyclic group in Wu⁴ may be an aromatic hydrocarbon cyclic group, an aromatic heterocyclic group, or an alicyclic group. As the cyclic group, a group obtained by removing two hydrogen atoms from monocycloalkane, a group obtained by removing two hydrogen atoms from polycycloalkane, a group obtained by removing two hydrocarbon groups from an aromatic ring, and the like are exemplary examples. These groups may have a substituent which substitutes for a hydrogen atom of the cyclic group or a substituent which substitutes for a carbon atom constituting the ring skeleton.

Due to the fact that the first polymer block (A) and the second polymer block (B) do not have the constitutional unit (u0), in a case where the block copolymer (P1) is used as an undercoat agent, a substrate adsorptive group which does not contribute to the adsorption on the substrate is reduced, and uniformity of the surface of the underlayer film is maintained.

In a case where the first polymer block (A) has the constitutional unit (u0), a proportion (mol %) of the constitutional unit (u0) is preferably 40 mol % or less, more preferably 30 mol % or less, still more preferably 20 mol % or less, and particularly preferably 10 mol % or less with respect to all constitutional units (100 mol %) of the first polymer block (A).

In a case where the second polymer block (B) has the constitutional unit (u0), a proportion (mol %) of the constitutional unit (u0) is preferably 40 mol % or less, more preferably 30 mol % or less, still more preferably 20 mol % or less, and particularly preferably 10 mol % or less with respect to all constitutional units (100 mol %) of the second polymer block (B).

A number-average molecular weight (Mn) of the block copolymer (P1) (in terms of polystyrene by size exclusion chromatography) is not particularly limited, but is preferably 5,000 to 200,000, more preferably 6,000 to 100,000, still more preferably 8,000 to 80,000, and particularly preferably 10,000 to 60,000.

In a case of being equal to or less than the lower limit value of the preferred range, the block copolymer (P1) is sufficiently dissolved in an organic solvent, and thus coatability on the substrate is excellent. On the other hand, in a case of being equal to or more than the upper limit value of the preferred range, production stability of a polymer compound is excellent, and an undercoat agent composition having excellent coatability on the substrate is obtained.

A polydispersity (Mw/Mn) of the block copolymer (P1) is not particularly limited, but is preferably 1.0 to 5.0, more preferably 1.0 to 3.0, and still more preferably 1.0 to 2.5. Mw represents a mass-average molecular weight.

Specific examples of the block copolymer (P1) are shown below, but the present invention is not limited thereto. In the following formulae, a, b, x, and y represent a molar ratio of the constitutional unit. a and b represent an integer of 1 or more. As a:b, 10:90 to 90:10 are exemplary examples, and it is preferably 20:80 to 80:20, more preferably 30:70 to 70:30, and still more preferably 40:60 to 60:40. x and y are more than 0 and less than 1. x and y can be appropriately determined depending on the type of the desired phase-separated structure. x and y are, for example, 0.01 to 0.3.

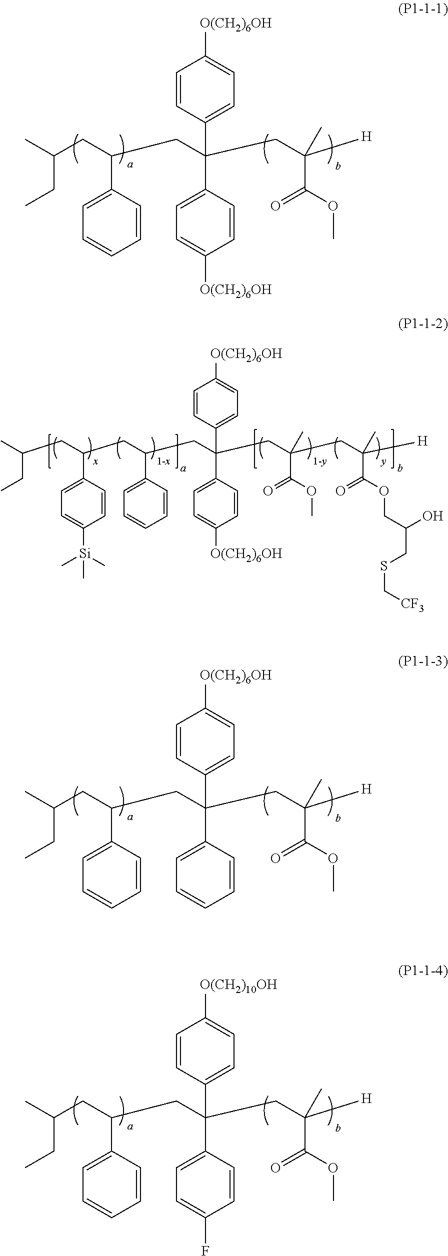

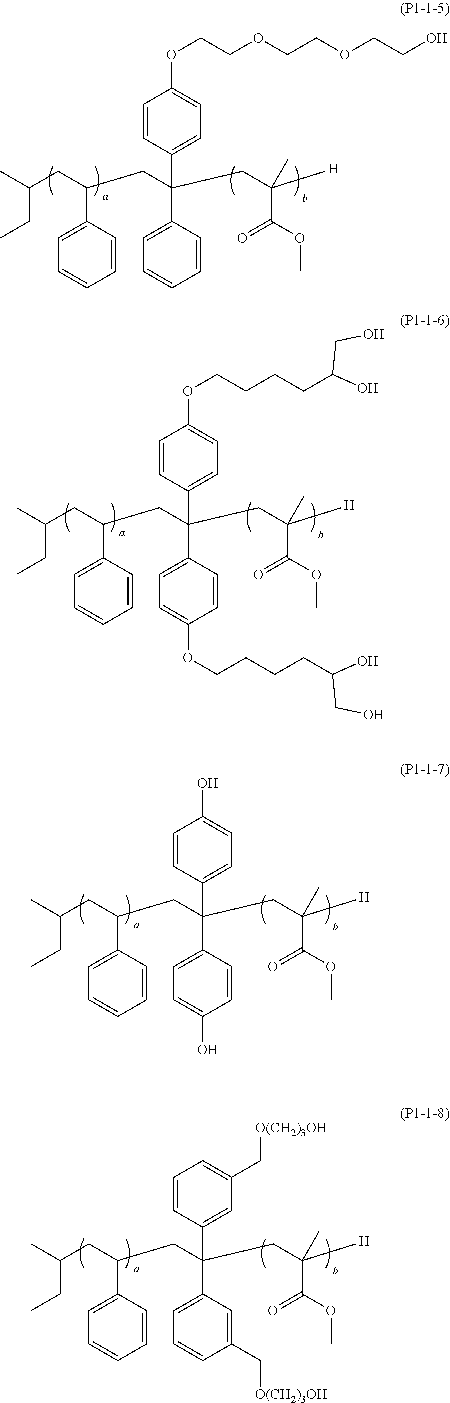

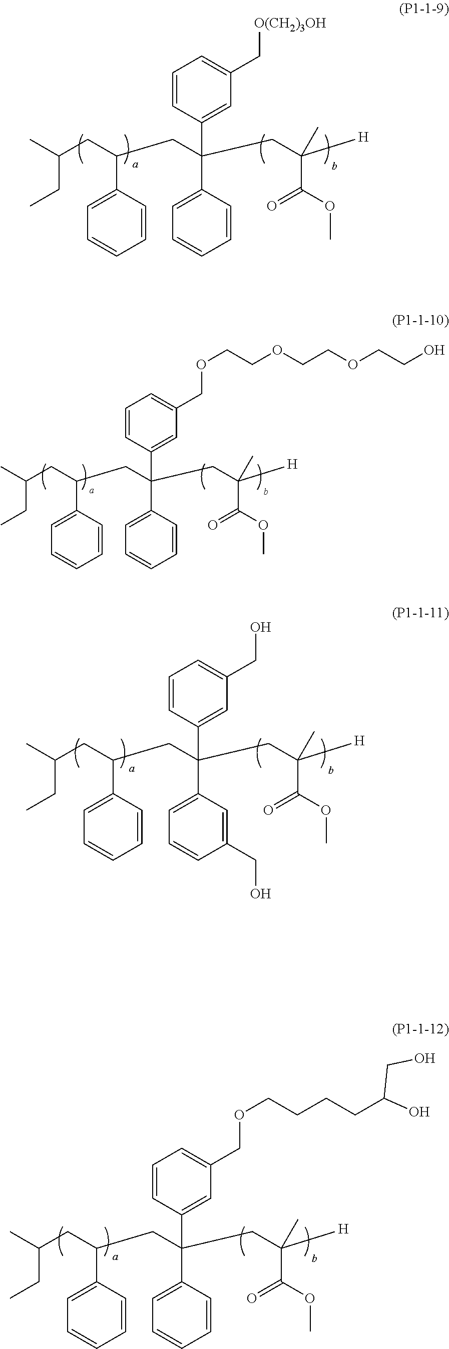

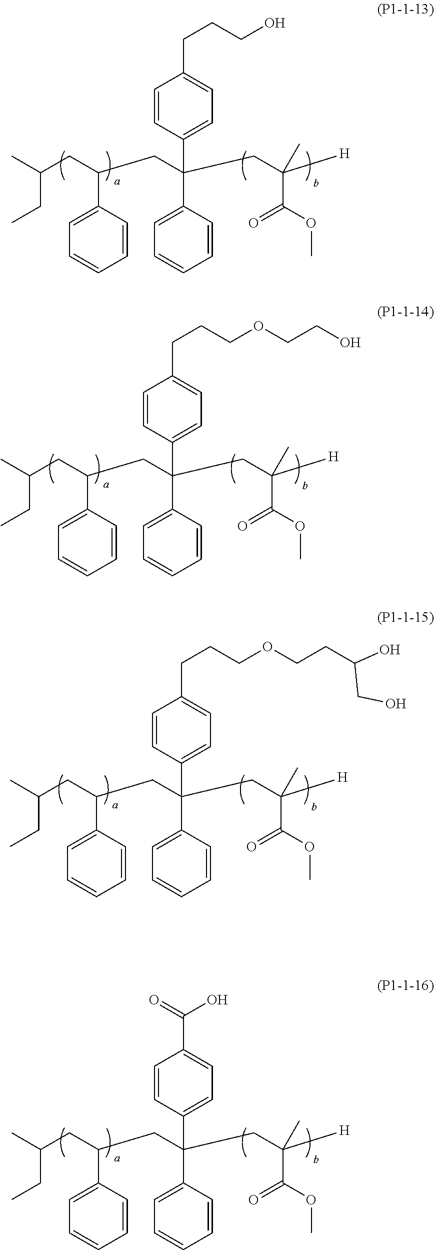

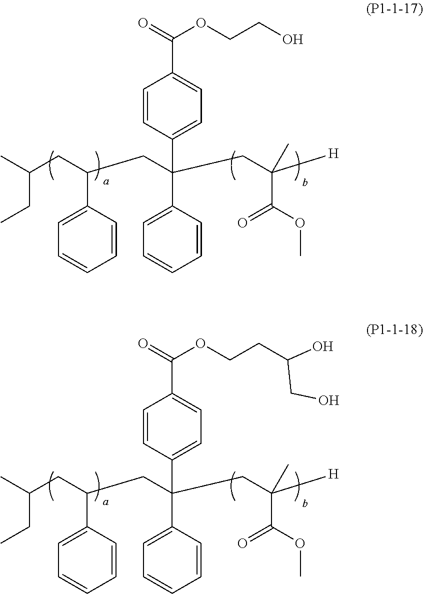

### Method for Producing Block Copolymer (P1)

The block copolymer (P1) can be produced by combining known methods as shown in Examples described later. For example, the block copolymer (P1) can be produced by a production method including the following steps.

Step (p1): step of synthesizing the first polymer block (A) by a living anionic polymerization;

Step (p2): step of reacting the first polymer block (A) with a diphenyl ethylene derivative (hereinafter, referred to as “DPE”) having a substrate adsorptive group-containing group; and

Step (p3): step of synthesizing the second polymer block (B) by a living anionic polymerization

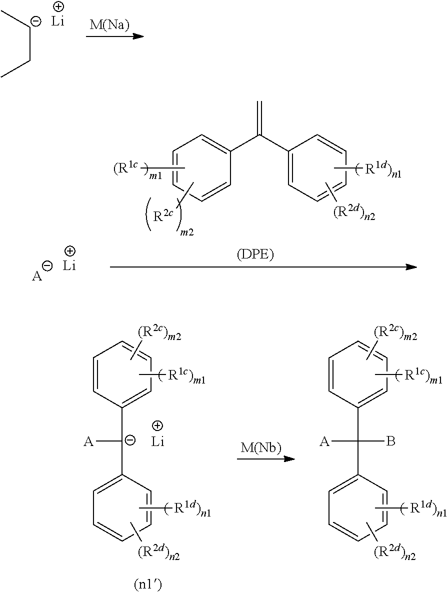

[in the formulae, A, B, R^{1c}, R^{1d}, R^{2c}, R^{2d}, m1, n1, m2, and n2 are the same as those in Formula (n1), and M (Na) and M (Nb) each represents a monomer (Na) and a monomer (Nb)].

### Step (p1):

The first polymer block (A) can be synthesized, for example, by carrying out a living anionic polymerization reaction of a monomer from which the constitutional unit (Na) (hereinafter, also referred to as “monomer (Na)”; for example, styrene and a derivative thereof) is derived. The living anionic polymerization can be carried out by a known method.

As a polymerization initiator, for example, organic alkali metals such as n-butyl lithium, sec-butyl lithium, tert-butyl lithium, ethyl lithium, ethyl sodium, 1,1-diphenylhexyl lithium, and 1,1-diphenyl-3-methylpentyl lithium can be used. In the above-described formulae, an example of use of sec-butyl lithium as the initiator is shown.

As a solvent, for example, aliphatic hydrocarbons such as hexane, heptane, and octane; ethers such as diethyl ether and tetrahydrofuran; ketones such as acetone, methyl ethyl ketone, and methyl amyl ketone; alcohols such as methanol, ethanol, and propanol; aromatic hydrocarbons such as benzene, toluene, and xylene; alkyl halides such as chloroform, bromoform, methylene chloride, methylene bromide, and carbon tetrachloride; esters such as ethyl acetate, butyl acetate, ethyl lactate, propylene glycol monomethyl ether, propylene glycol monomethyl ether acetate, and cellosolve; non-protonic polar solvents such as dimethylformamide, dimethyl sulfoxide, and hexamethylphosphoramide; and water are exemplary examples.

### Step (p2):

DPE is added to the reaction solution after the step (p1), and the reaction is carried out. As a solvent of DPE, for example, tetrahydrofuran is an exemplary example. The substrate adsorptive group contained in DPE may be protected by a protective group such as a tert-butyldimethylsilyl group.

### Step (p3):

For example, a monomer from which the constitutional unit (Nb) (hereinafter, also referred to as “monomer (Nb)”; for example, (α-substituted) acrylic acid ester and a derivative thereof) is derived is added to the reaction solution after the step (p2) for a polymerization reaction.

The reaction temperature, the reaction time, and the like of each of the above-described steps are not particularly limited, and may be appropriately determined, for example, depending on the type of the polymerization initiator.

In the step (p2), in a case where the substrate adsorptive group contained in the DPE is protected by a protective group, a deprotecting step may be performed after the step (p3). The condition for deprotection may be appropriately determined depending on the type of the protective group.

### Optional Component

The BCP composition can further contain miscible additives appropriately as desired, for example, an additive resin for ameliorating the performance of the undercoat agent layer, a surfactant for improving coatability, a dissolution inhibitor, a plasticizer, a stabilizer, a colorant, a halation preventing agent, a dye, a sensitizer, a base multiplier, and a basic compound (a nitrogen-containing compound such as imidazole, or the like), to the extent that does not impair the effects of the present invention.

### Organic Solvent (Component (S))

The BCP composition can be produced by dissolving each component such as the block copolymer (P1) in an organic solvent (hereinafter, also referred to as “component (S)”).

The component (S) may be any organic solvent which can dissolve each component to be used and form a uniform solution, and any one kind or two or more kinds can be selected as appropriate from the organic solvents which are conventionally known as a solvent for a film composition containing a resin as a main component, and used.

As the component (S), for example, lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monoethylether, monopropylether, or monobutylether or monophenylether of any of the polyhydric alcohols or the compounds having an ester bond [among these, propylene glycol monomethyl ether acetate (PGMEA), or propylene glycol monomethyl ether (PGME) is preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and the like are exemplary examples.

The component (S) may be used alone or in a form of a mixed solvent of two or more kinds thereof.

Among these, as the component (S), propylene glycol monomethyl ether acetate (PGMEA), propylene glycol monomethyl ether (PGME), cyclohexanone, or EL is preferable.

A mixed solvent obtained by mixing PGMEA with a polar solvent is also preferable. A blending ratio (mass ratio) thereof can be appropriately determined in consideration of compatibility between PGMEA and the polar solvent, and it is preferably in a range of 1:9 to 9:1 and more preferably in a range of 2:8 to 8:2. For example, in a case where EL is blended as the polar solvent, a mass ratio of PGMEA:EL is preferably 1:9 to 9:1 and more preferably 2:8 to 8:2. In addition, in a case where PGME is blended as the polar solvent, a mass ratio of PGMEA:PGME is preferably 1:9 to 9:1, more preferably 2:8 to 8:2, and still more preferably 3:7 to 7:3. In addition, in a case where PGME and cyclohexanone are blended as the polar solvent, a mass ratio of PGMEA:(PGME+cyclohexanone) is preferably 1:9 to 9:1, more preferably 2:8 to 8:2, and still more preferably 3:7 to 7:3.

As the component (S), PGMEA, EL, a mixed solvent of PGMEA and a polar solvent, or a mixed solvent with γ-butyrolactone is also preferable. In this case, as a mixing proportion, a mass ratio of the former and the latter is preferably set to 70:30 to 95:5.

An amount of the component (S) used is not particularly limited and is appropriately set according to a coating film thickness, at a concentration at which the component (S) can be applied onto a substrate or the like, but generally, the component (S) is used such that a solid content concentration of the undercoat agent is in a range of 0.1% to 20% by mass, preferably in a range of 0.2% to 15% by mass.

### Method for Producing Structure Body

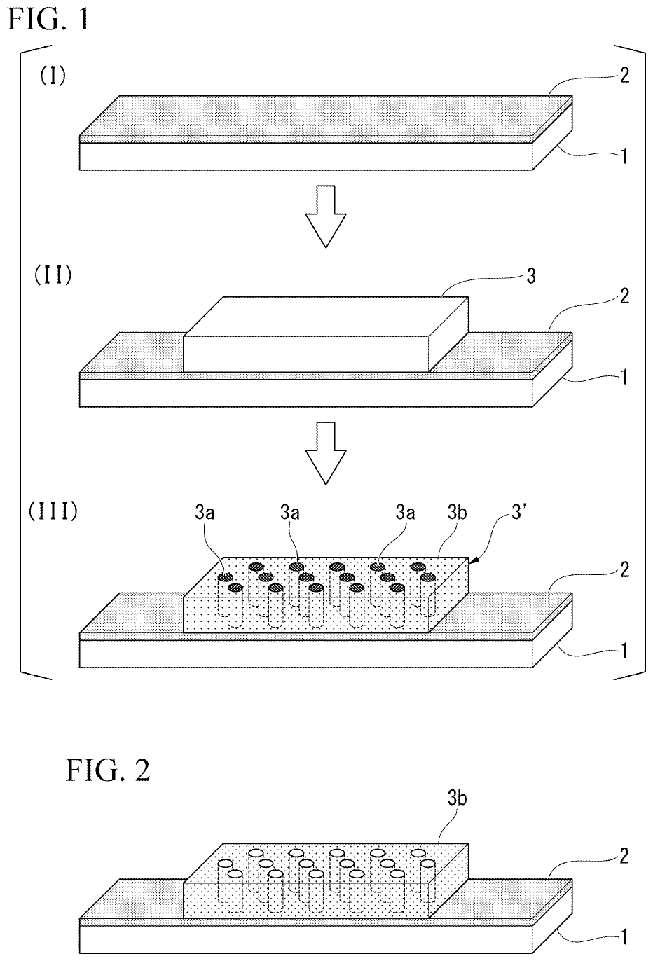

Hereinafter, the method for producing a structure body including a phase-separated structure will be specifically described with reference to FIG. 1. However, the present invention is not limited thereto.

FIG. 1 shows an exemplary embodiment of the method for producing a structure body including a phase-separated structure.

First, an undercoat agent layer 2 is formed by applying the above-described BCP composition onto a substrate 1 (FIG. 1(I); step (i)).

Next, a self-organization layer 3 is formed by applying the above-described BCP composition onto the undercoat agent layer 2 (FIG. 1(II); step (ii)).

Next, an annealing treatment is performed by heating to subject the self-organization layer 3 to phase separation into a phase 3a and a phase 3b (FIG. 1(III); step (iii)).

In the above-described production method according to the present embodiment, that is, in the production method including the steps (i) to (iii), a structure body 3′ including a phase-separated structure is produced on the substrate 1 on which the undercoat agent layer 2 has been formed.

### Step (i)

In the step (i), the undercoat agent layer 2 is formed by applying the above-described BCP composition onto the substrate 1.

In the step (i), the BCP composition is used as an undercoat agent for forming the undercoat agent layer 2. By providing the undercoat agent layer 2 on the substrate 1, adhesiveness between a surface of the substrate 1 and the self-organization layer is improved.

The type of the substrate 1 is not particularly limited as long as the resin composition for forming a phase-separated structure can be applied onto its surface. For example, a substrate made of an inorganic material such as a metal (silicon, copper, chromium, iron, and aluminum), glass, titanium oxide, silicon dioxide (SiO₂), silica, and mica; a substrate made of a nitride such as SiN; a substrate made of an oxynitride such as SiON; and a substrate made of an organic material such as acryl, polystyrene, cellulose, cellulose acetate, phenolic resin, and the like are exemplary examples. Among these, a substrate 1 made of metal is suitable, and for example, a structure body having a cylinder structure is likely to be formed in a silicon substrate (Si substrate) a silicon dioxide substrate (SiO₂ substrate), or a copper substrate (Cu substrate). Among these, an Si substrate or an SiO₂ substrate is particularly suitable.

The size and shape of the substrate 1 are not particularly limited. The substrate 1 is not necessarily required to have a smooth surface, and substrates of various shapes can be appropriately selected. For example, a substrate having a curved surface, a flat plate having a surface with an uneven shape, and a substrate with a flaky shape or the like are exemplary examples.

An inorganic and/or organic film may be provided on the surface of the substrate 1.

As the inorganic film, an inorganic antireflection film (inorganic BARC) is an exemplary example. As the organic film, an organic antireflection film (organic BARC) is an exemplary example.

The inorganic film can be formed, for example, by applying an inorganic antireflection film composition such as a silicon-based material onto the substrate and by sintering the film.

For example, the organic film can be formed by applying a material for forming an organic film, in which a resin component and the like constituting the film are dissolved in an organic solvent, onto a substrate using a spinner or the like, and baking the film under heating conditions at preferably 200° C. to 300° C. for preferably 30 to 300 seconds and more preferably 60 to 180 seconds. The material for forming an organic film does not necessarily need to have sensitivity to light or electron beams, which is essential for a resist film, and may or may not have sensitivity. Specifically, a resist or a resin generally used for the production of semiconductor elements or liquid crystal display elements can be used.

In addition, it is preferable that the material for forming an organic film be a material capable of forming an organic film which can be subjected to etching, particularly dry etching, so that the organic film can be etched by using a pattern formed from a block copolymer, which is formed by processing the layer 3, to transfer the pattern onto the organic film, and an organic film pattern can be formed. Above all, the material for forming an organic film is preferably a material capable of forming an organic film capable of being subjected to etching such as oxygen plasma etching. Such a material for forming an organic film may be a material conventionally used for forming an organic film such as organic BARC. For example, ARC series manufactured by Nissan Chemical Industries, Ltd., AR series manufactured by Rohm and Haas Company, SWK series manufactured by Tokyo Ohka Kogyo Co., Ltd., and the like are exemplary examples.

A method of forming the undercoat agent layer 2 by applying the BCP composition onto the substrate 1 is not particularly limited, and the undercoat agent layer 2 can be formed by a known method in the related art.

For example, the undercoat agent layer 2 can be formed by applying the BCP composition onto the substrate 1 by a known method in the related art, such as using spin coating or a spinner, to form a coating film, and drying the coating film.

As a method of drying the coating film, any method of drying the coating film may be used as long as the solvent contained in the BCP composition can be volatilized, and for example, a method of baking the coating film is an exemplary example. In this case, a baking temperature is preferably 80° C. to 300° C., more preferably 180° C. to 270° C., and still more preferably 220° C. to 250° C. The baking time is preferably 30 to 500 seconds and more preferably 60 to 400 seconds.

The thickness of the undercoat agent layer 2 after drying the coating film is preferably approximately 10 to 100 nm and more preferably approximately 30 to 90 nm.

The surface of the substrate 1 may be cleaned in advance before forming the undercoat agent layer 2 on the substrate 1. Coatability of the undercoat agent is improved by cleaning the surface of the substrate 1.

Regarding the cleaning treatment method, known methods in the related art can be utilized, and an oxygen plasma treatment, an ozone oxidation treatment, an acid alkali treatment, a chemical modification treatment, and the like are exemplary examples.

After the undercoat agent layer 2 is formed, the undercoat agent layer 2 may be rinsed as necessary using a rinse liquid such as a solvent. Since an uncrosslinked portion or the like in the undercoat agent layer 2 is removed by the rinsing, the affinity with the self-organization layer 3 is improved, and the phase-separated structure oriented in the direction perpendicular to the surface of the substrate 1 is likely to be formed.

The rinse liquid may be any one which can dissolve the uncrosslinked portions, and a solvent such as propylene glycol monomethyl ether acetate (PGMEA), propylene glycol monomethyl ether (PGME), or ethyl lactate (EL), or a commercially available thinner liquid can be used.

After the cleaning, post-baking may be performed in order to volatilize the rinse liquid. The temperature condition of the post-baking is preferably 80° C. to 300° C., more preferably 100° C. to 270° C., and still more preferably 120° C. to 250° C. The baking time is preferably 30 to 500 seconds and more preferably 60 to 240 seconds. The thickness of the undercoat agent layer 2 after the post-baking is preferably approximately 1 to 20 nm and more preferably approximately 2 to 10 nm.

### Step (ii)

In the step (ii), the self-organization layer 3 is formed by applying the above-described BCP composition onto the undercoat agent layer 2. As the BCP composition, the same BCP composition as that used in the step (i) is used.

The method of forming the self-organization layer 3 on the undercoat agent layer 2 is not particularly limited, and a method of applying the BCP composition onto the undercoat agent layer 2 by a known method in the related art, such as spin coating or using a spinner, to form a coating film, and drying the coating film is an exemplary example.

The thickness of the self-organization layer 3 may be a thickness sufficient to induce phase separation, and when considering the type of the substrate 1, or the structure period size, the uniformity of the nano-structure bodies, or the like of the phase-separated structure to be formed, the thickness thereof is preferably 10 to 100 nm and more preferably 20 to 80 nm.

For example, in a case where the substrate 1 is an Si substrate or an SiO₂ substrate, the thickness of the layer 3 is preferably 10 to 100 nm and more preferably 20 to 80 nm.

In a case where the substrate 1 is a Cu substrate, the thickness of the layer 3 is preferably 10 to 100 nm and more preferably 20 to 80 nm.

Step (iii)

In the step (iii), the self-organization layer 3 is subjected to phase separation.

By heating the substrate 1 after the step (ii) to perform an annealing treatment, a phase-separated structure is formed such that at least a portion of the surface of the substrate 1 is exposed by selective removal of the block copolymer. That is, the structure body 3′ including a phase-separated structure which is phase-separated into a phase 3a and a phase 3b is produced on the substrate 1.

Regarding the temperature conditions for the annealing treatment, it is preferable that the annealing treatment be performed at a temperature equal to or higher than a glass transition temperature of the block copolymer (P1) and lower than a thermal decomposition temperature. The temperature condition for the annealing treatment is preferably, for example, 180° C. to 270° C. The heating time is preferably 30 to 3600 seconds.

The annealing treatment is preferably performed in a gas having low reactivity, such as nitrogen.

### Optional Step

The method for producing a structure body including a phase-separated structure is not limited to the above-described embodiment, and may have a step (optional step) in addition to the steps (i) to (iii).

As the optional step, a step of selectively removing a phase formed of at least one kind of block among the plurality of kinds of blocks constituting the block copolymer from the layer including the block copolymer (hereinafter, referred to as “step (iv)”, a guide pattern-forming step, and the like are exemplary examples.

### Regarding Step (iv)

In the step (iv), a phase formed of at least one kind of block among the plurality of kinds of blocks constituting the above-described block copolymer is selectively removed from the layer containing the block copolymer, which is formed on the undercoat agent layer. As a result, a fine pattern (polymer nano-structure body) is formed.

As a method for selectively removing the phase formed of blocks, a method of performing an oxygen plasma treatment on the layer containing the block copolymer, a method of performing a hydrogen plasma treatment thereon, and the like are exemplary examples.

In the following description, among the blocks constituting the block copolymer, a block which is not selectively removed is referred to as a P_{A} block, and a block which is selectively removed is referred to as a P_{B} block. For example, after the layer containing the PS-PMMA block copolymer is subjected to phase separation, a phase formed of PMMA is selectively removed by performing, on the layer, an oxygen plasma treatment, a hydrogen plasma treatment, or the like. In this case, the PS portion is the P_{A} block and the PMMA portion is the P_{B} block.

FIG. 2 shows an exemplary embodiment of the step (iv).

In the embodiment shown in FIG. 2, in a case where the phase 3a is selectively removed and a pattern (polymer nano-structure body) from the separated phase 3b is formed by performing an oxygen plasma treatment on the structure body 3′ produced on the substrate 1 in the step (iii). In this case, the phase 3b is a phase formed of the P_{A} block, and the phase 3a is a phase formed of the P_{B} block.

The substrate 1 having the patterns formed by the phase separation of the self-organization layer 3 as described above can be used as it is, but the shape of the pattern (polymer nano-structure body) of the substrate 1 may be changed by further heating.

Regarding the temperature conditions for the heating, it is preferable that the annealing treatment be performed at a temperature equal to or higher than a glass transition temperature of the block copolymer used and lower than a thermal decomposition temperature. In addition, the heating is preferably performed in a gas having low reactivity, such as nitrogen.

### Regarding Guide Pattern-Forming Step

In the method for producing a structure body including a phase-separated structure, a step (guide pattern-forming step) of forming a guide pattern on the undercoat agent layer may be provided between the step (i) and the step (ii). As a result, it is possible to control an array structure of the phase-separated structure.

For example, in a case where the guide pattern is not provided, even for a block copolymer with which a random fingerprint-shaped phase-separated structure is formed, in a case where a groove structure of a resist film is provided on the surface of the undercoat agent layer, a phase-separated structure oriented along the grooves is obtained. According to such a principle, the guide pattern may be provided on the undercoat agent layer 2. In addition, in a case where a surface of the guide pattern has an affinity with any polymer constituting the block copolymer, a phase-separated structure having a cylinder structure oriented in the direction perpendicular to the surface of the substrate is likely to be formed.

The guide pattern can be formed, for example, using a resist composition.

As the resist composition for forming the guide pattern, among resist compositions and modified products thereof, which are generally used for formation of a resist pattern, any one having the affinity with any polymer constituting the block copolymer can be appropriately selected and used. The resist composition may be any of a positive-type resist composition for forming a positive-type pattern in which the exposed part of the resist film is dissolved and removed, or a negative-type resist composition for forming a negative-type pattern in which the unexposed part of the resist film is dissolved and removed; but the resist composition is preferably a negative-type resist composition. As the negative-type resist composition, for example, a resist composition containing an acid generator, and a base material component in which solubility in a liquid developer containing an organic solvent is decreased by the action of an acid, and in which the base material component contains a resin component having a constitutional unit which is decomposed by the action of an acid to have increased polarity, is preferable.

After the BCP composition is poured on the undercoat agent layer on which the guide pattern has been formed, an annealing treatment is performed to induce phase separation. Therefore, the resist composition for forming the guide pattern is preferably a composition capable of forming a resist film having excellent solvent resistance and heat resistance.

With the method for producing a structure body including a phase-separated structure according to the present embodiment described above, the undercoat agent layer and the self-organization layer are formed of the same BCP composition. Since it is not necessary to use different materials as compositions for forming the undercoat agent and the self-organization layer, effort required for production is simplified. In addition, it is easy to manage raw materials used for producing the structure body including a phase-separated structure.

### Composition Containing Block Copolymer

The composition according to the second aspect of the present invention is a composition used in the above-described method for producing a structure body including a phase-separated structure according to the first aspect.

The composition according to the present embodiment is the above-described composition containing the block copolymer (P1), and is the same as the above-described BCP composition.

### EXAMPLES

Hereinafter, the present invention will be described in more detail with reference to examples, but the present invention is not limited to these examples.

### Synthesis of Block Copolymer: P1-1

### Synthesis of Diphenylethylene Derivative: DPE1

Imidazole (7.05 g, 103 mmol) and 6-chloro-1-hexanol (7.10 g, 52.0 mmol) were added to a two-neck flask, and nitrogen substitution was performed. N,N-dimethylformamide (DMF) (160 mL) was added thereto under a nitrogen atmosphere, and tert-butyldimethylsilyl chloride (30.7 g, 203 mmol) was added thereto with cooling in an ice bath. Further, dehydrated DMF (160 mL) was added thereto, and the mixture was stirred in an ice bath for 1 hour and then at room temperature for 2 hours. Thereafter, water was added thereto to quench the reaction, and extraction with hexane and washing with water were repeated three times. The organic layer was dried with magnesium sulfate. Thereafter, the solvent was distilled off under reduced pressure, and the resultant was purified by column chromatography using hexane. The solvent was distilled off under reduced pressure to obtain an intermediate Int (1-1) (12.4 g, yield: 95%).

1H-NMR (CDCl3, 400 MHz):

δ (ppm)=0.02 (s, 6H, —Si(CH3)2), 0.89 (s, 9H, —SiC(CH3)3), 1.30 to 1.60 (m, 6H, -CH2CH2CH2-), 1.75 to 1.82 (m, 2H, -C1CH2CH2-), 3.54 (t, 2H, C1CH2-), 3.61 (t, 2H, —CH2O-)

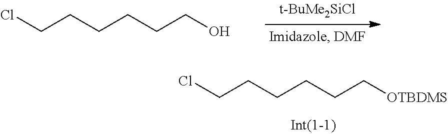 [SMILES: OCCCCCCCl ; CC(C)(C)[Si](C)(C)OCCCCCCCl]

Int (1-1) (11.7 g, 46.5 mmol) was added to a two-neck flask, 4,4′-dihydroxybenzophenone (1.69 g, 7.85 mmol), potassium carbonate (6.50 g, 47.1 mmol), potassium iodide (0.405 g, 2.45 mmol), and DMF (125 mL) were added thereto. After stirring at 60° C. for 48 hours, water was added thereto to quench the reaction, and extraction with hexane and washing with water were repeated three times. The organic layer was dried with magnesium sulfate. Thereafter, the solvent was distilled off under reduced pressure, and the resultant was purified by column chromatography using a mixed solvent of hexane:ethyl acetate=10:1. The solvent was distilled off under reduced pressure to obtain an intermediate Int (2-1) (3.75 g, yield: 75%).

1H-NMR (CDCl3, 400 MHz):

δ (ppm)=0.05 (s, 12H, —Si(CH3)2), 0.90 (s, 18H, —SiC(CH3)3), 1.38 to 1.61 (m, 12H, -CH2CH2CH2-), 1.79 to 1.86 (m, 4H, —CH2CH2OSi—), 3.62 (t, 4H, —CH2OSi—), 4.03 (t, 4H, —ArOCH2-), 6.94 (d, 4H, Ar), 7.77 (d, 4H, Ar)

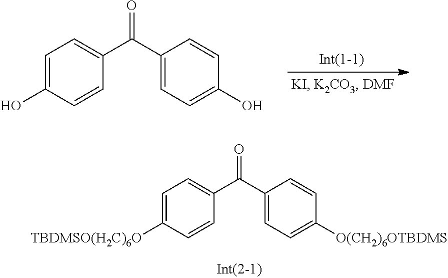

Int (2-1) (3.02 g, 4.70 mmol) was added to a two-neck flask, and the inside of the two-neck flask was heated with a dryer while being decompressed. While cooling with an ice bath, potassium tert-butoxide (1.07 g, 9.54 mmol) and methyltriphenylphosphonium bromide (5.04 g, 14.1 mmol) were added thereto, and nitrogen substitution was performed. Tetrahydrofuran (THF) (120 mL) was added thereto under a nitrogen atmosphere, and the mixture was stirred in an ice bath for 1 hour and then at room temperature for 16 hours. Thereafter, water was added thereto to quench the reaction, and extraction with diethyl ether and washing with water were repeated three times. The organic layer was dried with magnesium sulfate, hexane was added to the organic layer from which the solvent had been distilled off under reduced pressure, and the resulting white precipitate was removed by filtration while being washed with hexane. The solvent was distilled off again under reduced pressure, and the resultant was purified by column chromatography using a mixed solvent of hexane:ethyl acetate=20:1. The solvent was distilled off under reduced pressure to obtain DPE1 (2.98 g, yield: 99%).

1H-NMR (CDCl3, 400 MHz):

δ (ppm)=0.05 (s, 12H, —Si(CH3)2), 0.90 (s, 18H, —SiC(CH3)3), 1.36 to 1.61 (m, 12H, -CH2CH2CH2-), 1.76 to 1.83 (m, 4H, —CH2CH2OSi—), 3.62 (t, 4H, —CH2OSi—), 3.97 (t, 4H, —ArOCH2-), 5.28 (s, 2H, C═CH2), 6.84 (d, 4H, Ar), 7.26 (d, 4H, Ar)

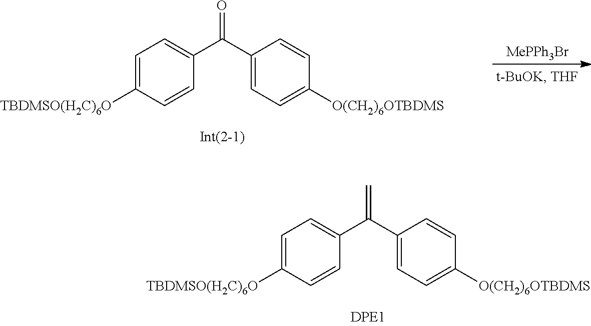

Synthesis of BCP precursor: Pre (1)

DPE1 (0.134 g, 0.209 mmol) was weighed in a Schlenk tube, and the inside of the Schlenk tube was heated with a heat gun while being depressurized. THF was added to another Schlenk tube in an argon (Ar) atmosphere, and sec-butyl lithium was added thereto while being cooled to −78° C. until the solution was colored yellow. The THF was subjected to a freeze degassing operation, and then the THF was transferred to the Schlenk tube in which DPE1 had been charged by trap-to-trap distillation, thereby preparing a THF solution of DPE1.

Lithium chloride (10.3 mg, 0.243 mmol) was weighed in a Schlenk tube, and the inside of the Schlenk tube was heated with a heat gun while being depressurized. After returning the Schlenk tube to room temperature, THF (20 mL) was added thereto, and the mixture was cooled to −78° C. Sec-butyl lithium (0.3 mL) was added thereto, and it was confirmed that the color of the solution changed from transparent to yellow. Thereafter, the mixture was stirred at room temperature until yellow color disappeared. The solution was cooled again to −78° C., sec-butyl lithium (32.5 μL, 0.0400 mmol) as an initiator amount was added thereto, and then styrene (1.03 mL, 8.99 mmol) was added thereto, followed by stirring for 30 minutes. Next, the entire amount of the prepared THF solution of DPE1 was added dropwise thereto, and the mixture was stirred for 30 minutes. Subsequently, methyl methacrylate (0.790 mL, 7.43 mmol) was added thereto, and the mixture was stirred for 30 minutes. Finally, an excess amount of methanol (3 mL) subjected to Ar bubbling was added to the reaction solution to quench the reaction. The THF solution in the Schlenk tube was added to methanol (400 mL) to perform precipitation purification. The solid recovered by filtration was dried under reduced pressure at 40° C., and then oligomer components generated during the polymerization were removed by Soxhlet extraction using cyclohexane. The solid in the cylindrical filter paper was dissolved in THF (20 mL), and the THF solution was added to methanol (400 mL) to perform precipitation purification. The solid recovered by filtration was dried under reduced pressure at 40° C. to obtain a precursor Pre (1) (1.18 g, yield: 70%). Mn and dispersity (PDI=Mw/Mn) of the Pre (1), measured by size exclusion chromatography (SEC), were 40.9 kg-mol¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

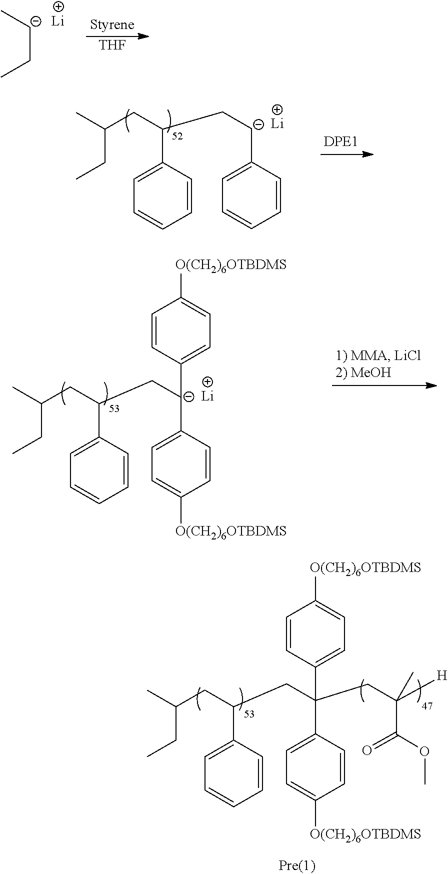

### Synthesis of BCP: P1-1

Pre (1) (202 mg, 5.05 μmol) was weighed in a two-neck flask, and Ar substitution was performed. After addition of THF (1.25 mL), tetra-n-butylammonium fluoride (0.75 mL, 150 μmol) was added thereto under an Ar atmosphere, and the mixture was stirred at room temperature for 24 hours. Methanol (40 mL) was added to the THF solution in the two-neck flask, and the solution was subjected to precipitation purification. The solid recovered by filtration was dried under reduced pressure at 40° C. to obtain P1-1 (197 mg, yield: 98%). Mn and dispersity (PDI=Mw/Mn) of the P1-1, measured by size exclusion chromatography (SEC), were 41.4 kg-mol⁻¹ and 1.03. The synthesis of P1-1 was confirmed by disappearance of the 1H-NMR peak derived from a tert-butyl dimethylsilyl group (TBDMS).

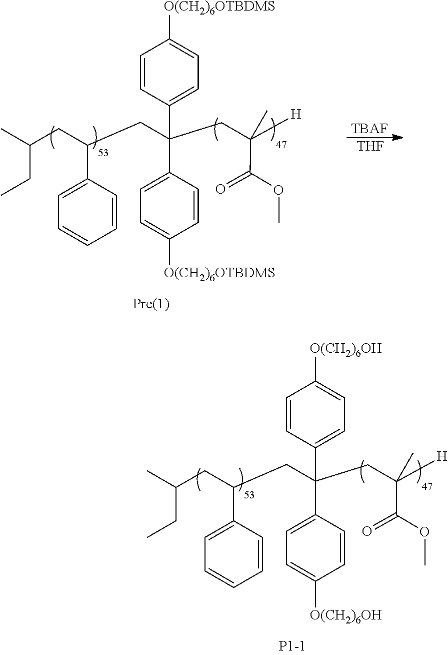

### Synthesis of block copolymer: P1-2

### Synthesis of BCP precursor: Pre (2)

A precursor Pre (2) (0.69 g, yield: 60%) was obtained by the same method as in Pre (1), except that the amount of styrene used was changed to (0.65 mL, 5.7 mmol) and the amount of methyl methacrylate used was changed to (0.59 mL, 5.5 mmol). Mn and dispersity (PDI=Mw/Mn) of the precursor 2, measured by size exclusion chromatography (SEC), were 28.2 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

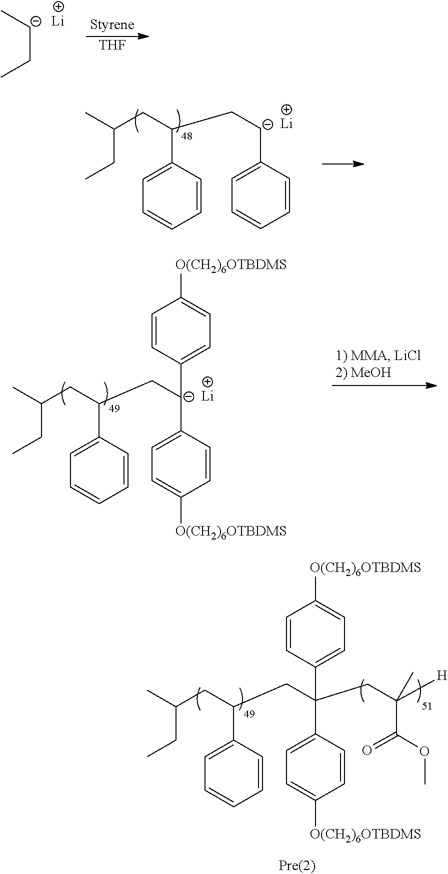

### Synthesis of BCP: P1-2

P1-2 was obtained by the same method as in P1-1, except that Pre (1) was changed to Pre (2). Mn and dispersity (PDI=Mw/Mn) of the P1-2, measured by size exclusion chromatography (SEC), were 28.5 kg-mol⁻¹ and 1.03. The synthesis of P1-2 was confirmed by disappearance of the 1H-NMR peak derived from TBDMS.

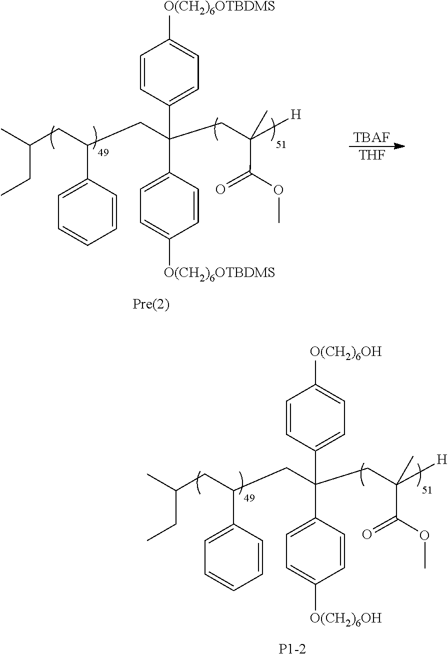

### Synthesis of block copolymer: P1-3

### Synthesis of BCP precursor: Pre (3-1)

A precursor Pre (3-1) (1.13 g, yield: 66%) was obtained by the same method as in Pre (1), except that the styrene was changed to a mixed monomer of styrene (0.83 mL, 7.2 mmol) and 4-trimethylsilylstyrene (0.19 mL, 0.94 mmol), and the methyl methacrylate was changed to a mixed monomer of methyl methacrylate (0.67 mL, 6.2 mmol) and glycidyl methacrylate (0.15 mL, 1.2 mmol). Mn and dispersity (PDI=Mw/Mn) of the Pre (3-1), measured by size exclusion chromatography (SEC), were 42.5 kg-mol⁻¹ and 1.05.

1H-NMR (CDCl3, 400 MHz):

δ (ppm)=0.06 to 0.07 (—Si(CH3)2), 0.20 to 0.30 (-PhSi(CH3)3, PTMSS), 0.85 (α-CH3, PMMA), 0.90 (—SiC(CH3)3), 1.02 (α-CH3, PMMA and PGMA), 1.23 to 1.69 (—CH2CH—, PS and PTMSS), 1.74 to 2.02 (—CH2CH—, PS and PTMSS, —CH2C(CH3)-, PMMA and PGMA),

2.63 (-CH2-CH(CH2)-O—, PGMA), 2.84 (—CH2CH(CH2)-O—, PGMA), 3.60 (—COOCH3, PMMA), 3.79 (—(C═O)O-CH2-, PGMA), 4.28 (—(C═O)O-CH2-, PGMA), 6.20 to 7.50 (Ar, PS and PTMSS)

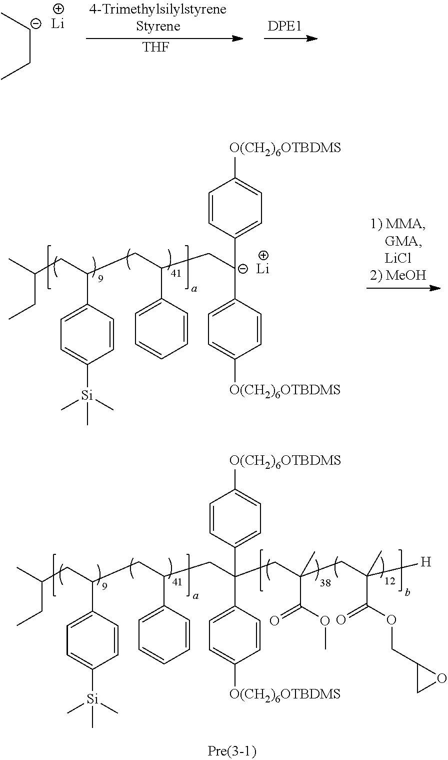

### Synthesis of BCP precursor: Pre (3-2)

Pre (3-1) (1.00 g, 23.5 μmol) and THF (5 mL) were added to a two-neck flask, and the mixture was cooled in an ice bath, and then a 1 wt % lithium hydroxide aqueous solution (equimolar to 0.05 mol/L of LiGH, GMA unit) and 2,2,2-trifluoroethanethiol (equimolar to 2 mol/L, GMA unit) were added thereto. The mixture was stirred at room temperature for 20 minutes and then at 40° C. for 3 hours. Methanol (50 mL) was added to the THF solution in the two-neck flask, and the solution was subjected to precipitation purification. The solid recovered by filtration was dried under reduced pressure at 40° C. to obtain a precursor Pre (3-2) (0.95 g, yield: 95%). Mn and dispersity (PDI=Mw/Mn) of the Pre (3-2), measured by size exclusion chromatography (SEC), were 45.0 kg-mol⁻¹ and 1.05.

1H-NMR (CDCl3, 400 MHz):

δ (ppm)=0.06 to 0.07 (—Si(CH3)2), 0.20 to 0.30 (-PhSi(CH3)3, PTMSS), 0.85 (α-CH3, PMMA), 0.90 (—SiC(CH3)3), 1.02 (α-CH3, PMMA and PHFMA), 1.23 to 1.69 (—CH2CH—, PS and PTMSS), 1.74 to 2.02 (—CH2CH—, PS and PTMSS, —CH2C(CH3)-, PMMA and PHFMA),

2.85 (—CH(OH)-CH2-S—, PHFMA), 3.20 to 3.45 (—S-CH2-CF3, PHFMA), 3.60 (—COOCH3, PMMA), 3.79 (—(C═O)O-CH2-, PHFMA), 3.95 to 4.20 (—CH(OH)—, PHFMA), 4.45 to 4.57 (—CH(OH)—, PHFMA), 6.20 to 7.50 (Ar, PS and PTMSS)

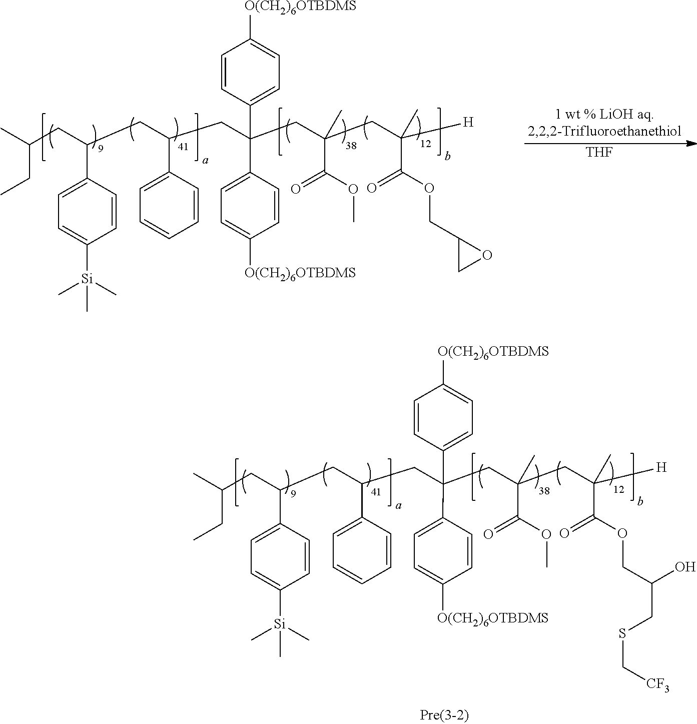

### Synthesis of BCP: P1-3

P1-3 was obtained by the same method as in P1-1, except that Pre (1) was changed to Pre (3-2). Mn and dispersity (PDI=Mw/Mn) of the P1-3, measured by size exclusion chromatography (SEC), were 45.6 kg-mol⁻¹ and 1.05. The synthesis of P1-3 was confirmed by disappearance of the 1H-NMR peak derived from TBDMS.

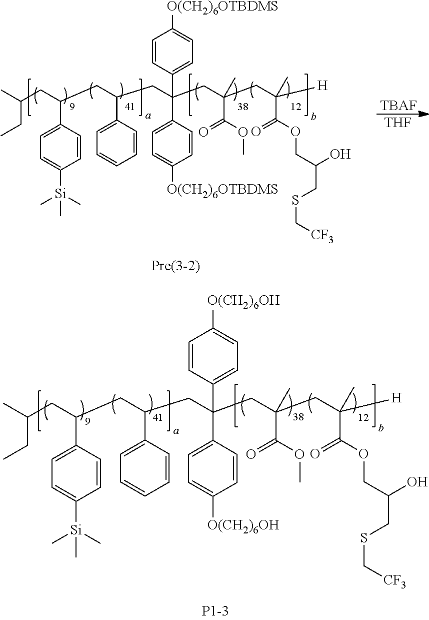

### Synthesis of block copolymer: P1-4

### Synthesis of diphenylethylene derivative: DPE2

An intermediate Int (2-2) (2.43 g, yield: 75%) was obtained by the same method as in Int (2-1), except that 4,4′-dihydroxybenzophenone (1.69 g, 7.85 mmol) was changed to 4-hydroxybenzophenone (1.56 g, 7.87 mmol). 1H-NMR (CDCl3, 400 MHz): δ (ppm)=0.05 (s, 6H, —Si(CH3)2), 0.90 (s, 9H, —SiC(CH3)3), 1.38 to 1.61 (m, 6H, -CH2CH2CH2-), 1.79 to 1.86 (m, 2H, —CH2CH2OSi—), 3.62 (t, 2H, —CH2OSi—), 4.03 (t, 2H, —ArOCH2-), 6.94 (d, 2H, Ar), 7.48 (t, 2H, Ar), 7.53 (m, 1H, Ar), 7.72 (d, 2H, Ar), 7.77 (d, 2H, Ar)

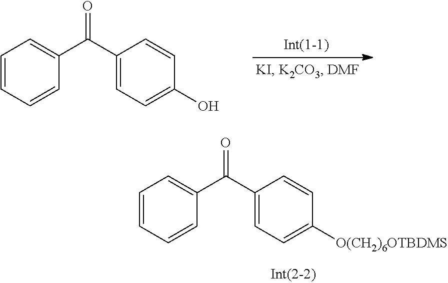

DPE2 (1.83 g, yield: 95%) was obtained by the same method as in DPE1, except that Int (2-1) (3.02 g, 4.70 mmol) was changed to Int (2-2) (1.94 g, 4.70 mmol).

1H-NMR (CDCl3, 400 MHz):

δ (ppm)=0.05 (s, 6H, —Si(CH3)2), 0.90 (s, 9H, —SiC(CH3)3), 1.36 to 1.61 (m, 6H, -CH2CH2CH2-), 1.76 to 1.83 (m, 2H, —CH2CH2OSi—), 3.62 (t, 2H, —CH2OSi—), 3.97 (t, 2H, —ArOCH2-), 5.32 (s, 2H, C═CH2), 6.83 (d, 2H, Ar), 7.26 (d, 4H, Ar), 7.30 to 7.34 (m, 3H, Ar)

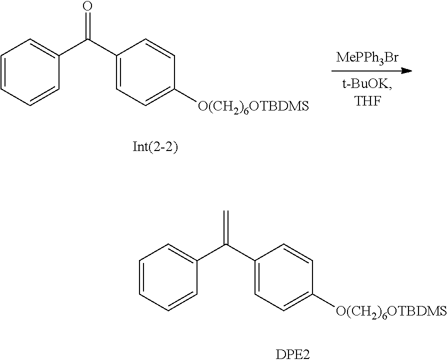

### Synthesis of BCP precursor: Pre (4)

A THF solution of DPE2 was prepared by the same method as that of the THF solution of DPE1, except that DPE1 (0.134 g, 0.209 mmol) was changed to DPE2 (0.086 g, 0.21 mmol).

A precursor Pre (4) (1.20 g, yield: 66%) was obtained by the same method as in Pre (1), except that the amount of styrene used was changed to (1.05 mL, 9.21 mmol), the THF solution of DPE1 was changed to the THF solution of DPE2, and the amount of methyl methacrylate used was changed to (0.91 mL, 8.6 mmol). Mn and dispersity (PDI=Mw/Mn) of the Pre (4), measured by size exclusion chromatography (SEC), were 44.0 kg-mol-1 and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

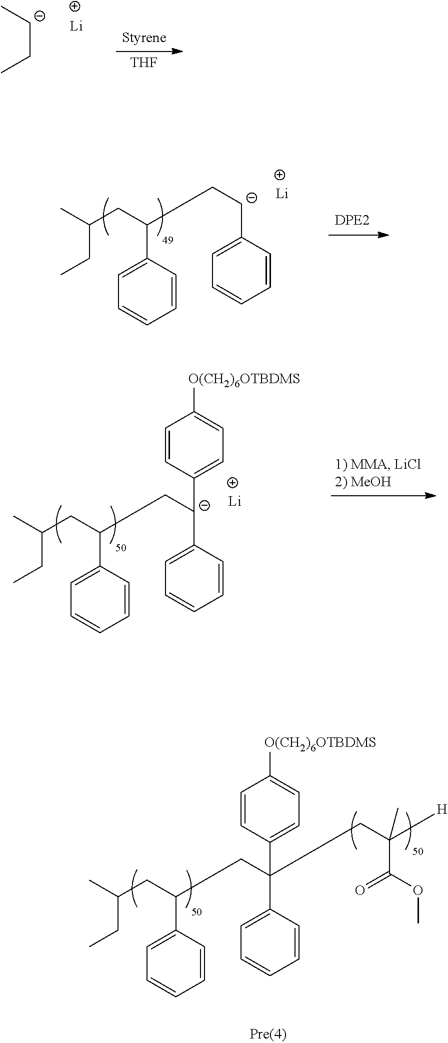

### Synthesis of BCP: P1-4

P1-4 was obtained by the same method as in P1-1, except that Pre (1) was changed to Pre (4). Mn and dispersity (PDI=Mw/Mn) of the P1-4, measured by size exclusion chromatography (SEC), were 44.6 kg-mol-1 and 1.03.

1H-NMR (CDCl3, 400 MHz):

δ (ppm)=0.85, 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

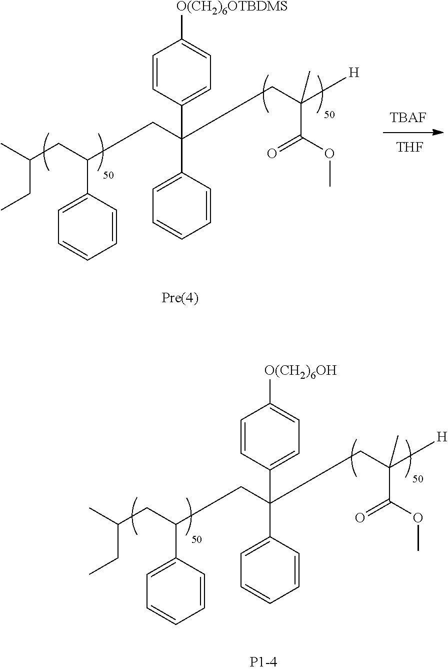

### Synthesis of block copolymer: P1-5

### Synthesis of diphenylethylene derivative: DPE3

An intermediate Int (1-2) (15.0 g, yield: 94%) was obtained by the same method as in Int (1-1), except that 6-chloro-1-hexanol (7.10 g, 52.0 mmol) was changed to 10-chloro-1-decanol (10.0 g, 51.9 mmol).

1H-NMR (CDCl3, 400 MHz):

δ (ppm)=0.02 (s, 6H, —Si(CH3)2), 0.89 (s, 9H, —SiC(CH3)3), 1.30 to 1.60 (m, 14H, —(CH2)7-), 1.75 to 1.82 (m, 2H, -C1CH2CH2-), 3.54 (t, 2H, C1CH2-), 3.61 (t, 2H, —CH2O-)

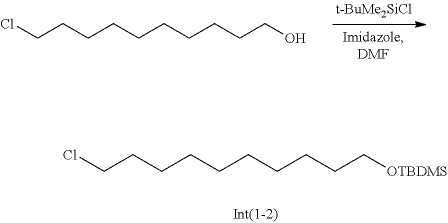 [SMILES: OCCCCCCCCCCCl ; CC(C)(C)[Si](C)(C)OCCCCCCCCCCCl]

An intermediate Int (2-3) (3.06 g, yield: 80%) was obtained by the same method as in Int (2-1), except that 4,4′-dihydroxybenzophenone (1.69 g, 7.85 mmol) was changed to 4-fluoro-4′-hydroxybenzophenone (1.70 g, 7.86 mmol), and Int (1-1) (11.7 g, 46.5 mmol) was changed to Int (1-2) (14.3 g, 46.5 mmol). 1H-NMR (CDCl3, 400 MHz): δ (ppm)=0.05 (s, 6H, —Si(CH3)2), 0.90 (s, 9H, —SiC(CH3)3), 1.38 to 1.61 (m, 14H, —(CH2)7-), 1.79 to 1.86 (m, 2H, —CH2CH2OSi—), 3.62 (t, 2H, —CH2OSi—), 4.03 (t, 2H, -ArOCH2-), 7.03 (d, 2H, Ar), 7.39 (d, 2H, Ar), 7.72 to 7.74 (m, 4H, Ar)

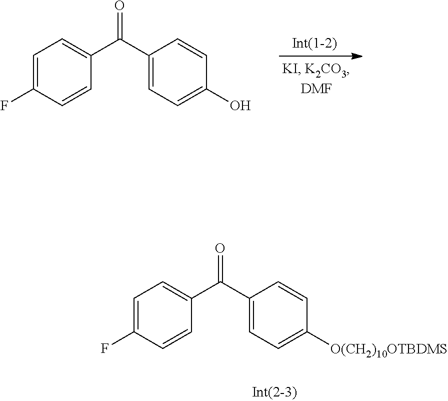

DPE3 (2.19 g, yield: 96%) was obtained by the same method as in DPE1, except that Int (2-1) (3.02 g, 4.70 mmol) was changed to Int (2-3) (2.28 g, 4.70 mmol). 1H-NMR (CDCl3, 400 MHz): δ (ppm)=0.05 (s, 6H, —Si(CH3)2), 0.90 (s, 9H, —SiC(CH3)3), 1.38 to 1.61 (m, 14H, —(CH2)7-), 1.79 to 1.86 (m, 2H, —CH2CH2OSi—), 3.62 (t, 2H, —CH2OSi—), 3.97 (t, 2H, -ArOCH2-), 5.34 (s, 2H, C═CH₂), 6.88 (d, 2H, Ar), 7.24 (d, 2H, Ar), 7.32 to 7.34 (m, 4H, Ar)

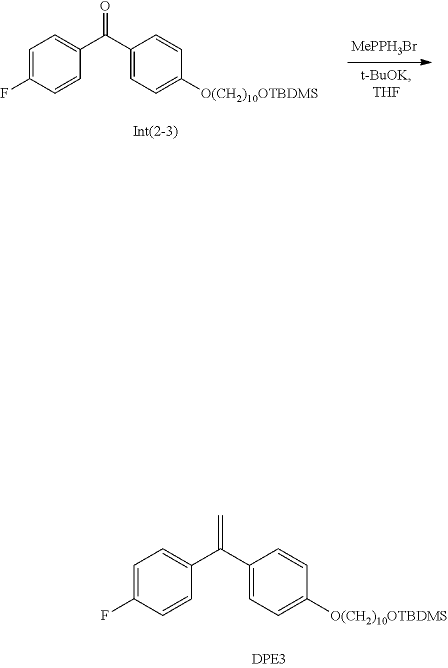

### Synthesis of BCP precursor: Pre (5)

A THF solution of DPE3 was prepared by the same method as that of the THF solution of DPE1, except that DPE1 (0.134 g, 0.209 mmol) was changed to DPE3 (0.101 g, 0.209 mmol).

A precursor Pre 5 (1.47 g, yield: 73%) was obtained by the same method as in Pre (1), except that the amount of styrene used was changed to (1.11 mL, 9.69 mmol), the THF solution of DPE1 was changed to the THF solution of DPE3, and the amount of methyl methacrylate used was changed to (1.13 mL, 10.6 mmol). Mn and dispersity (PDI=Mw/Mn) of the Pre (5), measured by size exclusion chromatography (SEC), were 50.4 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

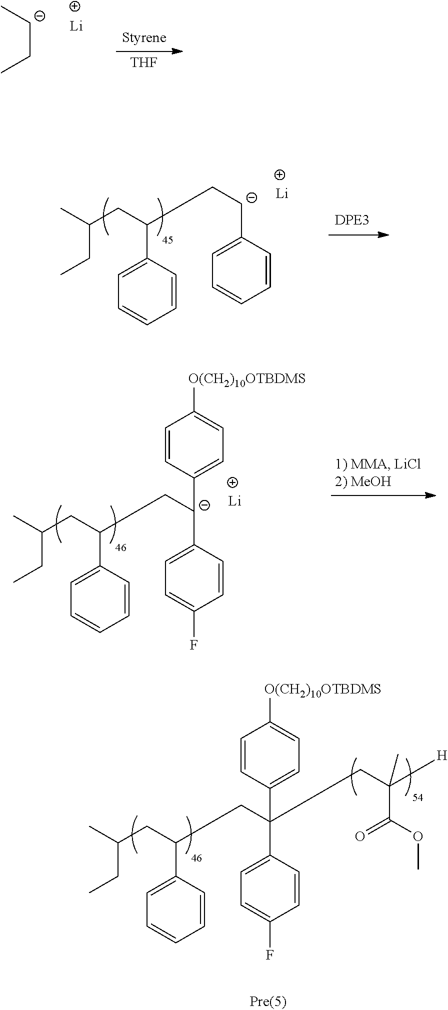

### Synthesis of BCP: P1-5

P1-5 was obtained by the same method as that of Pre (1), except that Pre (1) was changed to Pre (5). Mn and dispersity (PDI=Mw/Mn) of the P1-5, measured by size exclusion chromatography (SEC), were 51.0 kg-mol⁻¹ and 1.03. The synthesis of P1-5 was confirmed by disappearance of the 1H-NMR peak derived from TBDMS.

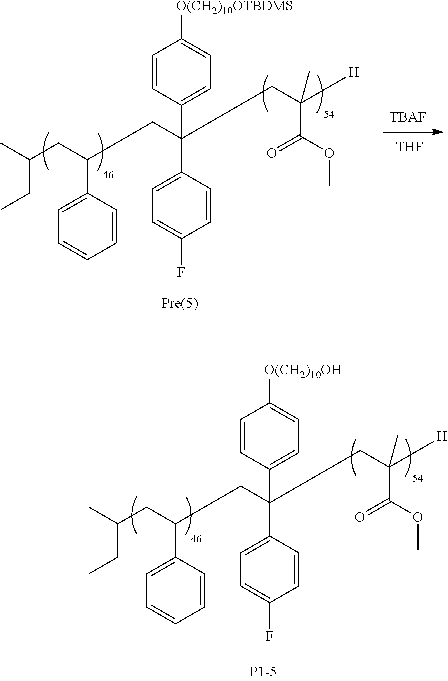

### Synthesis of block copolymer: P1-6

### Synthesis of diphenylethylene derivative: DPE4

An intermediate Int (1-3) (13.5 g, yield: 92%) was obtained by the same method as in Int (1-1), except that 6-chloro-1-hexanol (7.10 g, 52.0 mmol) was changed to 2-[2-(2-chloroethoxy)ethoxy]ethanol (8.77 g, 52.0 mmol). 1H-NMR (CDCl3, 400 MHz): δ (ppm)=0.02 (s, 6H, —Si(CH3)2), 0.89 (s, 9H, —SiC(CH3)3), 3.52 to 3.65 (m, 8H, -CH2OCH2CH2OCH2-), 3.83 (t, 2H, C1CH2-), 3.96 (t, 2H, —CH2OSi—)

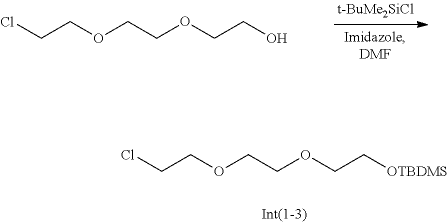 [SMILES: OCCOCCOCCCl ; CC(C)(C)[Si](C)(C)OCCOCCOCCCl]

An intermediate Int (2-4) (2.69 g, 6.06 mmol) was obtained by the same method as in Int (2-2), except that Int (1-1) (11.7 g, 46.5 mmol) was changed to Int (1-3) (13.2 g, 46.5 mmol). 1H-NMR (CDCl3, 400 MHz): δ (ppm)=0.05 (s, 6H, —Si(CH3)2), 0.90 (s, 9H, —SiC(CH3)3), 3.52 to 3.59 (m, 6H, -CH2OCH2CH2OCH2-), 3.77 (t, 2H, -ArOCH2CH2-), 3.96 (t, 2H, —CH2OSi—), 4.31 (t, 2H, —ArOCH2-), 6.95 (d, 2H, Ar), 7.50 to 7.53 (m, 3H, Ar), 7.73 (d, 2H, Ar), 7.81 (d, 2H, Ar)

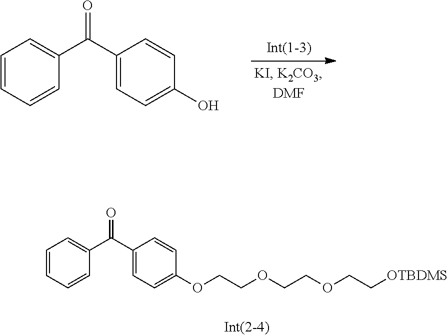 [SMILES: O=C(c1ccccc1)c1ccc(O)cc1 ; CC(C)(C)[Si](C)(C)OCCOCCOCCOc1ccc(C(=O)c2ccccc2)cc1]

DPE4 (1.96 g, 4.42 mmol) was obtained by the same method as in DPE1, except that Int (2-1) (3.02 g, 4.70 mmol) was changed to Int (2-4) (2.09 g, 4.70 mmol).

1H-NMR (CDCl3, 400 MHz):

δ (ppm)=0.05 (s, 6H, —Si(CH3)2), 0.90 (s, 9H, —SiC(CH3)3), 3.52 to 3.59 (m, 6H, -CH2OCH2CH2OCH2-), 3.77 (t, 2H, -ArOCH2CH2-), 3.96 (t, 2H, —CH2OSi—), 4.31 (t, 2H, —ArOCH2-), 5.32 (s, 2H, C═CH2), 6.88 (d, 2H, Ar), 7.33 to 7.38 (m, 7H, Ar)

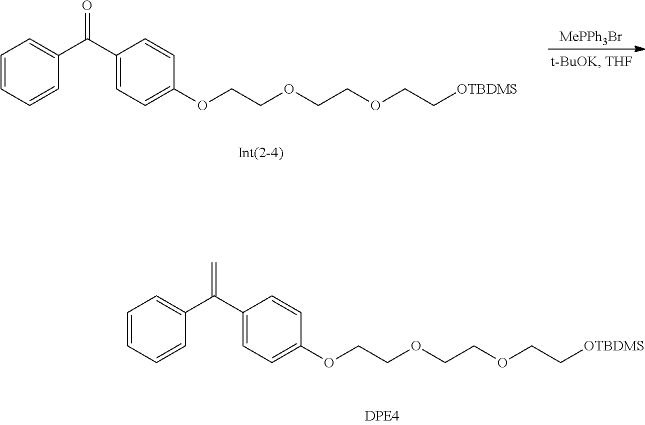 [SMILES: CC(C)(C)[Si](C)(C)OCCOCCOCCOc1ccc(C(=O)c2ccccc2)cc1 ; "MePPh3Br" ; C=C(c1ccccc1)c1ccc(OCCOCCOCCO[Si](C)(C)C(C)(C)C)cc1]

### Synthesis of BCP precursor: Pre (6)

A THF solution of DPE4 was prepared by the same method as that of the THF solution of DPE1, except that DPE1 (0.134 g, 0.209 mmol) was changed to DPE4 (0.925 g, 0.209 mmol).

A precursor Pre (6) (1.10 g, yield: 68%) was obtained by the same method as in Pre (1), except that the amount of styrene used was changed to (0.83 mL, 7.3 mmol), the THF solution of DPE1 was changed to the THF solution of DPE4, and the amount of methyl methacrylate used was changed to (0.92 mL, 8.6 mmol). Mn and dispersity (PDI=Mw/Mn) of the Pre (6), measured by size exclusion chromatography (SEC), were 39.5 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

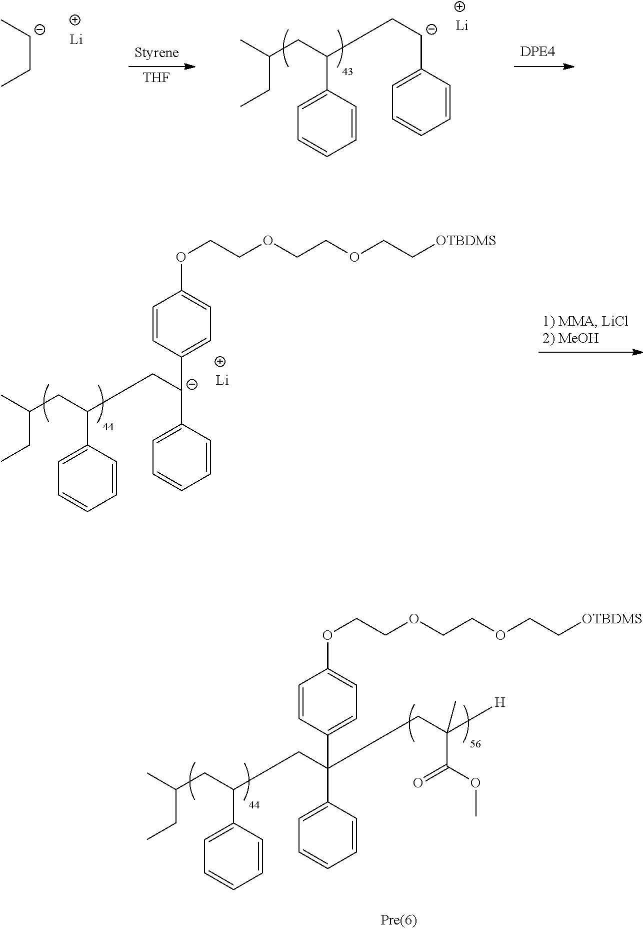

### Synthesis of BCP: P1-6

P1-6 was obtained by the same method as in P1-1, except that Pre (1) was changed to Pre (6). Mn and dispersity (PDI=Mw/Mn) of the P1-6, measured by size exclusion chromatography (SEC), were 40.0 kg-mol⁻¹ and 1.03. The synthesis of P1-6 was confirmed by disappearance of the 1H-NMR peak derived from TBDMS.

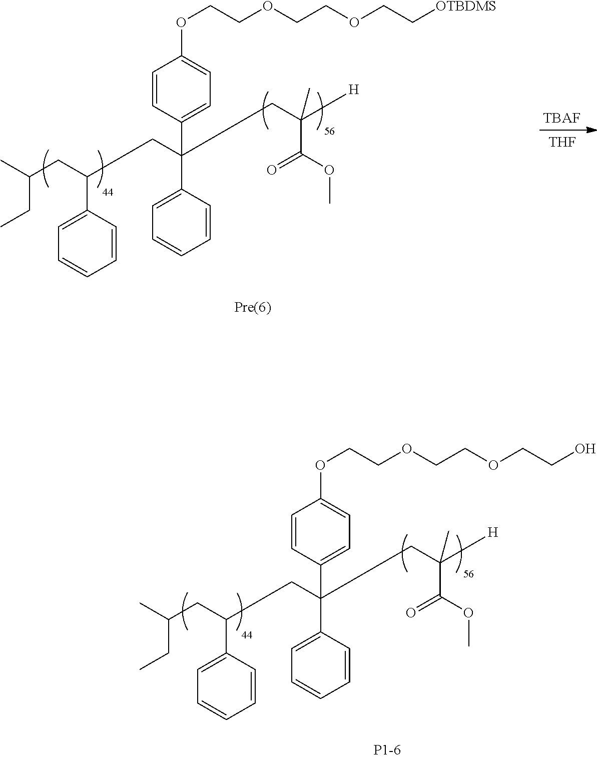

### Synthesis of block copolymer: P1-7

### Synthesis of diphenylethylene derivative: DPE5

An intermediate Int (2-5) (3.1 g, yield: 75%) was obtained by the same method as in Int (2-1), except that Int (1-1) (11.7 g, 46.5 mmol) was changed to 4-(4-chlorobutyl)-2,2-dimethyl-1,3-dioxolane (8.96 g, 46.5 mmol).

1H-NMR (CDCl3, 400 MHz):

δ (ppm)=1.21 (s, 12H, >C(CH3)2), 1.25 to 1.38 (m, 8H, —CH2CH3CH<), 1.69 (q, 4H, -OCH2CH2CH2-), 3.62 (d, 2H, >CHCH2O-), 3.82 to 3.87 (m, 4H, >CHCH2-), 4.06 (t, 4H, —ArOCH2-), 7.03 (d, 4H, Ar), 7.73 (d, 4H, Ar)

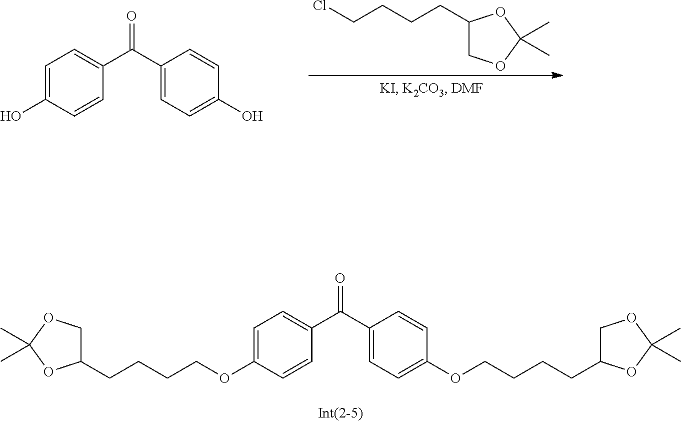

DPE5 (2.24 g, yield: 91%) was obtained by the same method as in DPE1, except that Int (2-1) (3.02 g, 4.70 mmol) was changed to Int (2-5) (2.48 g, 4.70 mmol).

1H-NMR (CDCl3, 400 MHz):

δ (ppm)=1.21 (s, 12H, >C(CH3)2), 1.25 to 1.38 (m, 8H, —CH2CH3CH<), 1.69 (q, 4H, -OCH2CH2CH2-), 3.62 (d, 2H, >CHCH2O-), 3.82 to 3.87 (m, 4H, >CHCH2-), 4.06 (t, 4H, —ArOCH2-), 5.32 (s, 2H, C═CH₂), 6.88 (d, 4H, Ar), 7.34 (d, 4H, Ar)

13C-NMR (CDCl3, 100 MHz):

δ (ppm)=22.61, 26.20, 29.97, 31.99, 68.70, 69.20, 77.82, 114.20 to 114.31, 119.25, 129.00, 133.24, 150.20, 158.68

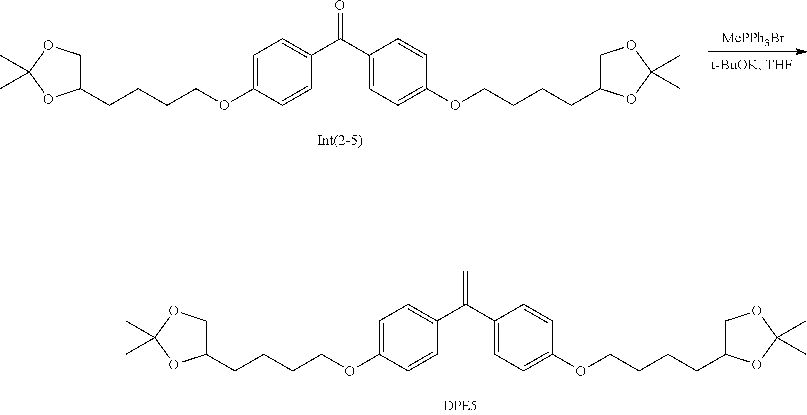

### Synthesis of BCP precursor: Pre (7)

A THF solution of DPE5 was prepared by the same method as that of the THF solution of DPE1, except that DPE1 (0.134 g, 0.209 mmol) was changed to DPE5 (0.110 g, 0.210 mmol).

A precursor Pre (7) (1.17 g, yield: 66%) was obtained by the same method as in Pre (1), except that the amount of styrene used was changed to (1.09 mL, 9.49 mmol), the THF solution of DPE1 was changed to the THF solution of DPE5, and the amount of methyl methacrylate used was changed to (0.84 mL, 7.8 mmol). Mn and dispersity (PDI=Mw/Mn) of the Pre (7), measured by size exclusion chromatography (SEC), were 43.0 kg-mol-1 and 1.03.

1H-NMR (CDCl3, 400 MHz):

δ (ppm)=0.85 (α-CH3, PMMA), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

13C-NMR (CDCl3, 100 MHz):

δ (ppm)=16.37 to 16.47, 18.56, 22.60, 25.90, 26.20, 29.90, 40.20 to 40.42, 44.43, 44.75, 51.73, 52.36, 54.04 to 54.31, 69.20, 77.80, 119.20, 125.37 to 125.52, 127.18 to 128.14, 145.15 to 145.54, 176.88, 177.70, 178.00

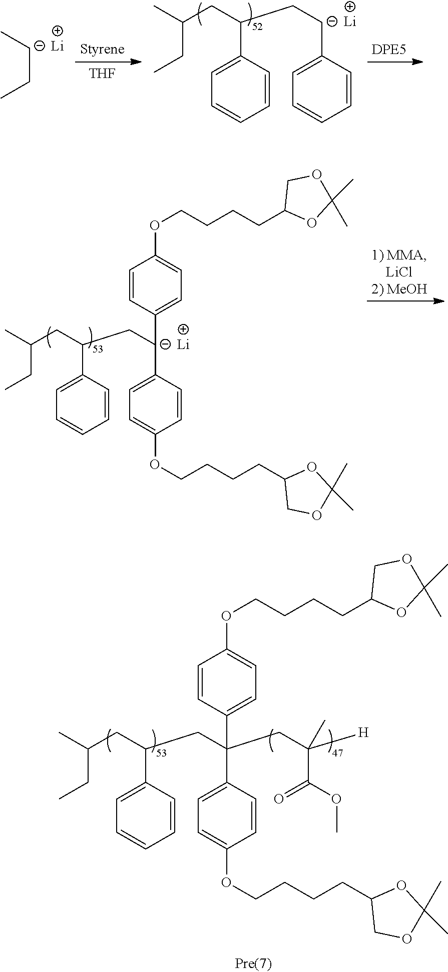

### Synthesis of BCP: P1-7

The precursor 7 (1.00 g, 24.4 μmol) was weighed in a two-neck flask, THF (5.0 mL) was added thereto, 1N hydrochloric acid (0.10 mL) was added thereto, and the mixture was stirred at 50° C. for 2 hours. After the reaction solution was returned to room temperature, sodium hydrogen carbonate (0.09 g) was added thereto, and the mixture was stirred for 10 minutes, and then the solid content was removed by filtration. The filtrate was added to methanol (150 mL) and subjected to sedimentation purification. The solid recovered by filtration was dried under reduced pressure at 40° C. to obtain P1-7 (0.90 g, yield: 90%). Mn and dispersity (PDI=Mw/Mn) of the P1-7, measured by size exclusion chromatography (SEC), were 43.5 kg-mol⁻¹ and 1.03. The synthesis of P1-7 was confirmed by disappearance of the 13C-NMR peak derived from 2,2-dimethyl-1,3-dioxolane.

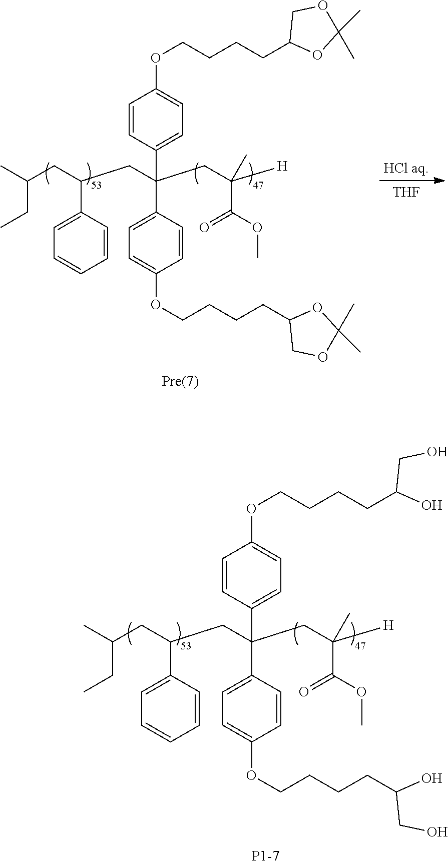

### Synthesis of block copolymer: P1-8

### Synthesis of BCP precursor: Pre (8)

A THF solution of 1,1-bis[4-[(tert-butyl)dimethylsiloxy]phenyl]ethylene was prepared by the same method as that of the THF solution of DPE1, except that DPE1 (0.134 g, 0.209 mmol) was changed to 1,1-bis[4-[(tert-butyl)dimethylsiloxy]phenyl]ethylene (0.092 g, 0.21 mmol) (R. P. Quirk, Y. Wang, Polym. Int. 1993, 31, 51).

A precursor Pre (8) (1.32 g, yield: 68%) was obtained by the same method as in Pre (1), except that the amount of styrene used was changed to (1.10 mL, 9.61 mmol), the THF solution of DPE1 was changed to the THF solution of 1,1-bis[4-[(tert-butyl)dimethylsiloxy]phenyl]ethylene, and the amount of methyl methacrylate used was changed to (0.99 mL, 9.3 mmol). Mn and dispersity (PDI=Mw/Mn) of the Pre (8), measured by size exclusion chromatography (SEC), were 46.9 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

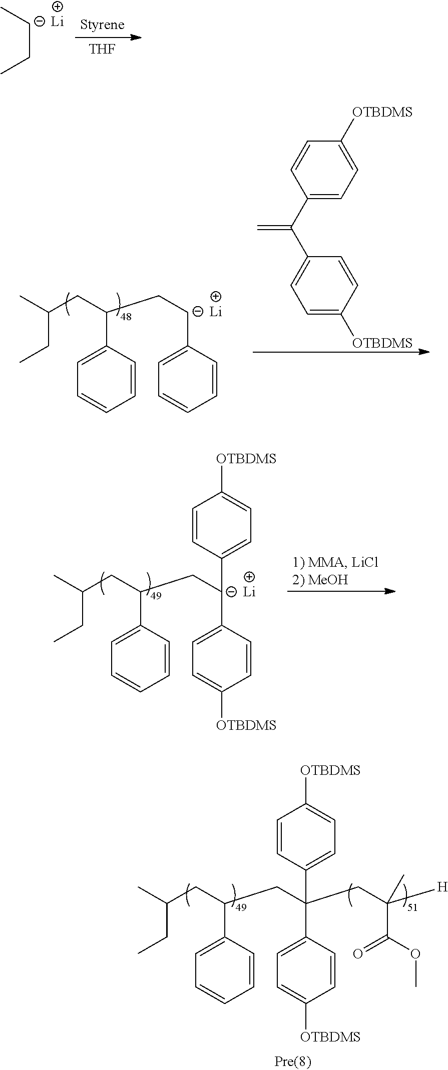

### Synthesis of BCP: P1-8

P1-8 was obtained by the same method as in P1-1, except that Pre (1) was changed to Pre (8). Mn and dispersity (PDI=Mw/Mn) of the P1-8, measured by size exclusion chromatography (SEC), were 47.5 kg-mol⁻¹ and 1.03. The synthesis of P1-8 was confirmed by disappearance of the 1H-NMR peak derived from TBDMS.

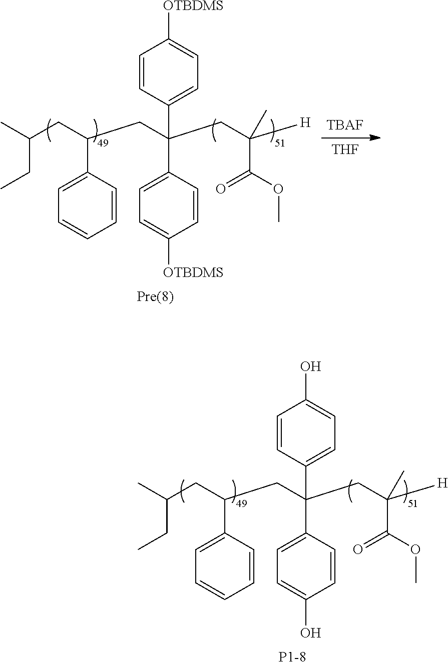

### Synthesis of block copolymer: P1-9

### Synthesis of diphenylethylene derivative: DPE6

An intermediate Int (2-6) (3.41 g, yield: 74%) was obtained by the same method as in Int (2-1), except that 4,4′-dihydroxybenzophenone (1.69 g, 7.85 mmol) was changed to bis[3-(bromomethyl)phenyl]methanone (2.89 g, 7.85 mmol), and Int (1-1) (11.7 g, 46.5 mmol) was changed to 3-[[tert-butyl(dimethyl)silyl]oxy]-1-propanol (8.85 g, 46.5 mmol). 1H-NMR (CDCl3, 400 MHz): δ (ppm)=0.05 (s, 12H, —Si(CH3)2), 0.90 (s, 18H, —SiC(CH3)3), 1.82 (q, 4H, —OCH2CH2CH2O-), 3.35 (t, 4H, -ArCH2OCH2-), 3.77 (t, 4H, —CH2OSi—), 4.80 (m, 4H, —ArCH2-), 7.37 (m, 2H, Ar), 7.66 to 7.71 (m, 6H, Ar)

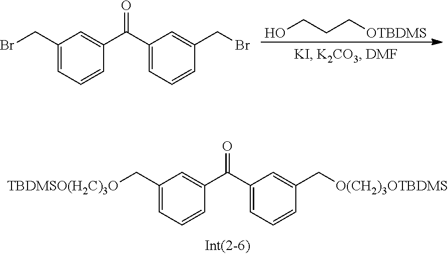

DPE6 (2.42 g, yield: 88%) was obtained by the same method as in DPE1, except that Int (2-1) (3.02 g, 4.70 mmol) was changed to Int (2-6) (2.76 g, 4.70 mmol).

1H-NMR (CDCl3, 400 MHz):

δ (ppm)=0.05 (s, 12H, —Si(CH3)2), 0.90 (s, 18H, —SiC(CH3)3), 1.82 (q, 4H, —OCH2CH2CH2O-), 3.35 (t, 4H, -ArCH2OCH2-), 3.77 (t, 4H, —CH2OSi—), 4.80 (m, 4H, —ArCH2-), 5.32 (s, 2H, C═CH2), 7.22 (m, 2H, Ar), 7.28 to 7.35 (m, 6H, Ar)

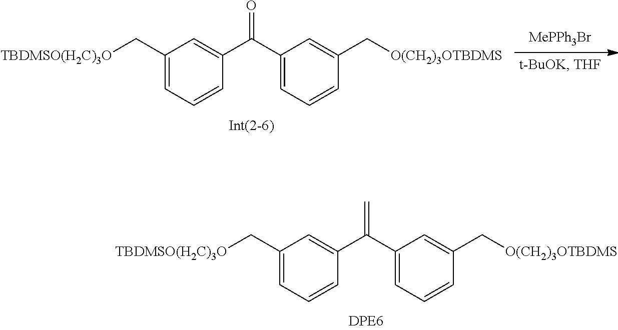

### Synthesis of BCP precursor: Pre (9)

A THF solution of DPE6 was prepared by the same method as that of the THF solution of DPE1, except that DPE1 (0.134 g, 0.209 mmol) was changed to DPE6 (0.122 g, 0.209 mmol).

A precursor Pre (9) (1.06 g, yield: 62%) was obtained by the same method as in Pre (1), except that the amount of styrene used was changed to (1.03 mL, 8.98 mmol), the THF solution of DPE1 was changed to the THF solution of DPE6, and the amount of methyl methacrylate used was changed to (0.82 mL, 7.7 mmol). Mn and dispersity (PDI=Mw/Mn) of the Pre (9), measured by size exclusion chromatography (SEC), were 41.5 kg-mol-1 and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

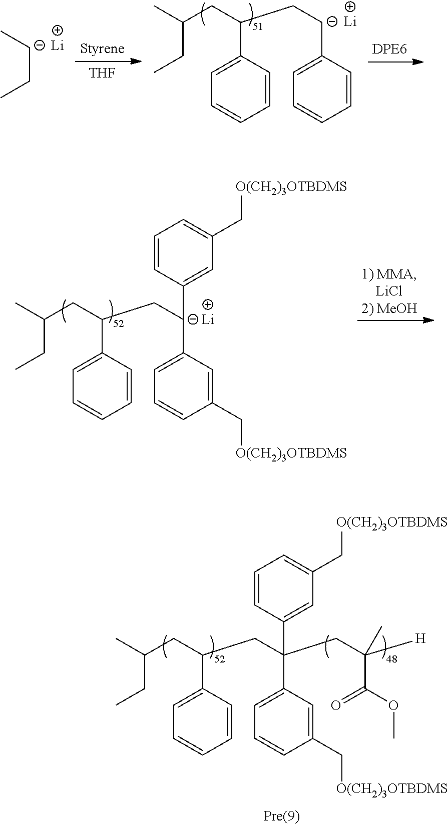

### Synthesis of BCP: P1-9

P1-9 was obtained by the same method as in P1-1, except that Pre (1) was changed to Pre (9). Mn and dispersity (PDI=Mw/Mn) of the P1-9, measured by size exclusion chromatography (SEC), were 42.0 kg-mol⁻¹ and 1.03. The synthesis of P1-9 was confirmed by disappearance of the 1H-NMR peak derived from TBDMS.

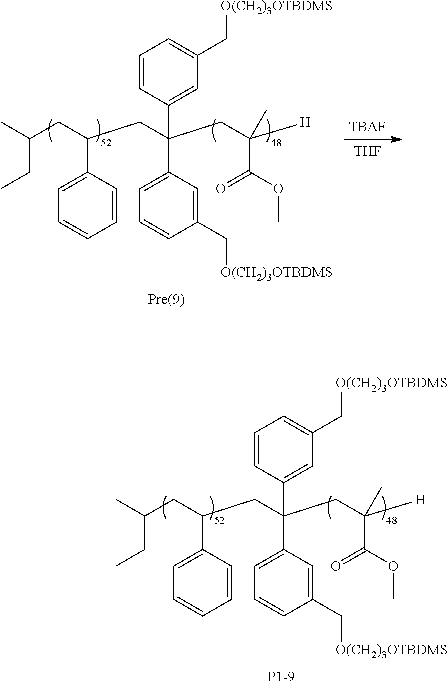

### Synthesis of block copolymer: P1-10

### Synthesis of diphenylethylene derivative: DPE7

An intermediate Int (2-7) (2.48 g, yield: 74%) was obtained by the same method as in Int (2-1), except that 4,4′-dihydroxybenzophenone (1.69 g, 7.85 mmol) was changed to 3-benzoylbenzyl bromide (2.16 g, 7.85 mmol), and Int (1-1) (11.7 g, 46.5 mmol) was changed to 6-[[tert-butyl(dimethyl)silyl]oxy]-1-propanol (10.8 g, 46.5 mmol). 1H-NMR (CDCl3, 400 MHz): δ (ppm)=0.05 (s, 6H, —Si(CH3)2), 0.90 (s, 9H, —SiC(CH3)3), 1.38 to 1.61 (m, 6H, -CH2CH2CH2-), 1.79 to 1.86 (m, 2H, —CH2CH2OSi—), 3.35 (t, 2H, ArCH2OCH2-), 3.62 (t, 2H, —CH2OSi—), 4.80 (m, 2H, —ArCH2-), 7.37 (m, 1H, Ar), 7.51 (m, 2H, Ar), 7.61 to 7.68 (m, 4H, Ar), 7.81 (d, 2H, Ar)

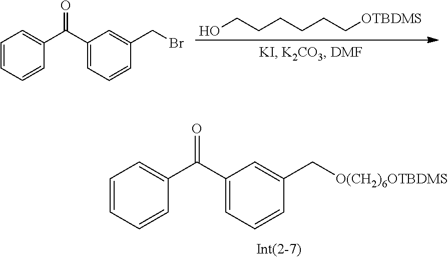

DPE7 (1.74 g, yield: 87%) was obtained by the same method as in DPE1, except that Int (2-1) (3.02 g, 4.70 mmol) was changed to Int (2-7) (2.01 g, 4.70 mmol).

1H-NMR (CDCl3, 400 MHz):

δ (ppm)=0.05 (s, 6H, —Si(CH3)2), 0.90 (s, 9H, —SiC(CH3)3), 1.38 to 1.61 (m, 6H, -CH2CH2CH2-), 1.79 to 1.86 (m, 2H, —CH2CH2OSi—), 3.35 (t, 2H, ArCH2OCH2-), 3.62 (t, 2H, —CH2OSi—), 4.80 (m, 2H, -ArCH2-), 5.32 (s, 2H, C═CH2), 7.22 (m, 1H, Ar), 7.28 to 7.37 (m, 8H, Ar)

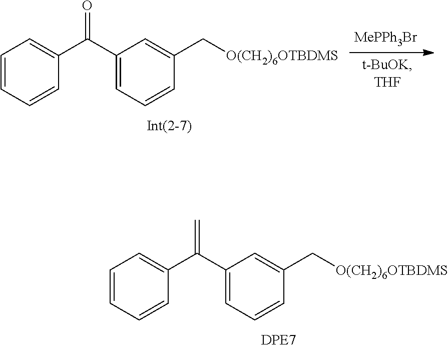

### Synthesis of BCP precursor: Pre (10)

A THF solution of DPE7 was prepared by the same method as that of the THF solution of DPE1, except that DPE1 (0.134 g, 0.209 mmol) was changed to DPE7 (0.089 g, 0.21 mmol).

A precursor Pre (10) (1.02 g, yield: 60%) was obtained by the same method as in Pre (1), except that the amount of styrene used was changed to (1.04 mL, 9.12 mmol), the THF solution of DPE1 was changed to the THF solution of DPE7, and the amount of methyl methacrylate used was changed to (0.80 mL, 7.5 mmol). Mn and dispersity (PDI=Mw/Mn) of the Pre (10), measured by size exclusion chromatography (SEC), were 41.2 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

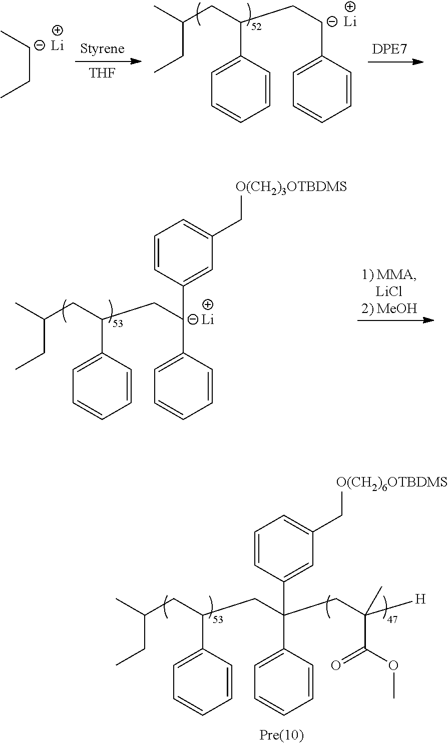

### Synthesis of BCP: P1-10

P1-10 was obtained by the same method as in P1-1, except that Pre (1) was changed to Pre (10). Mn and dispersity (PDI=Mw/Mn) of the P1-10, measured by size exclusion chromatography (SEC), were 41.7 kg-mol⁻¹ and 1.03. The synthesis of P1-10 was confirmed by disappearance of the 1H-NMR peak derived from TBDMS.

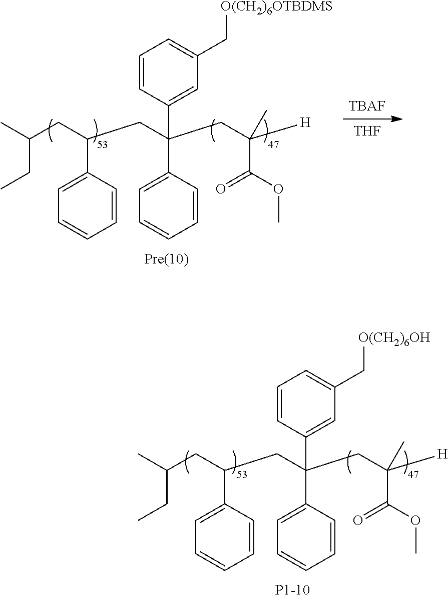

### Synthesis of block copolymer: P1-11

### Synthesis of diphenylethylene derivative: DPE8

An intermediate Int (2-8) (2.70 g, yield: 75%) was obtained by the same method as in Int (2-7), except that 6-[[tert-butyl(dimethyl)silyl]oxy]-1-propanol (10.8 g, 46.5 mmol) was changed to Int (1-3) (13.2 g, 46.5 mmol). 1H-NMR (CDCl3, 400 MHz): δ (ppm)=0.05 (s, 6H, —Si(CH3)2), 0.90 (s, 9H, —SiC(CH3)3), 3.52 to 3.59 (m, I0H, -OCH2CH2OCH2CH2OCH2-), 3.96 (t, 2H, —CH2OSi—), 4.80 (t, 2H, ArCH2-), 7.37 (m, 1H, Ar), 7.51 to 7.81 (m, 8H, Ar)

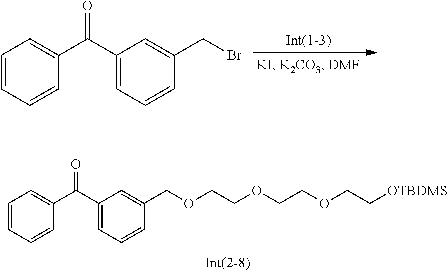 [SMILES: O=C(c1ccccc1)c1cccc(CBr)c1 ; CC(C)(C)[Si](C)(C)OCCOCCOCCOCc1cccc(C(=O)c2ccccc2)c1]

DPE8 (1.87 g, yield: 87%) was obtained by the same method as in DPE1, except that Int (2-1) (3.02 g, 4.70 mmol) was changed to Int (2-8) (2.16 g, 4.70 mmol).

1H-NMR (CDCl3, 400 MHz):

δ (ppm)=0.05 (s, 6H, —Si(CH3)2), 0.90 (s, 9H, —SiC(CH3)3), 3.52 to 3.59 (m, I0H, -OCH2CH2OCH2CH2OCH2-), 3.96 (t, 2H, —CH2OSi—), 4.80 (t, 2H, ArCH2-), 5.32 (s, 2H, C═CH2), 7.22 to 7.37 (m, 9H, Ar)

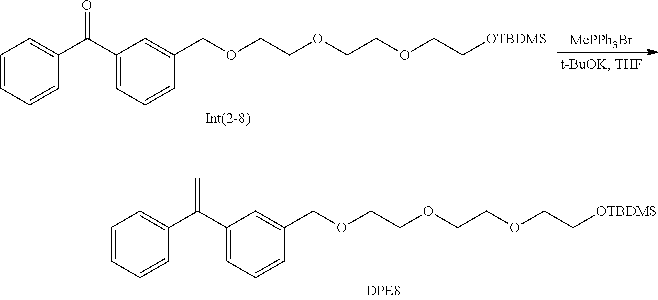

### Synthesis of BCP precursor: Pre (11)

A THF solution of DPE8 was prepared by the same method as that of the THF solution of DPE1, except that DPE1 (0.134 g, 0.209 mmol) was changed to DPE8 (0.096 g, 0.21 mmol).

A precursor Pre (11) (1.19 g, yield: 68%) was obtained by the same method as in Pre (1), except that the amount of styrene used was changed to (1.01 mL, 8.87 mmol), the THF solution of DPE1 was changed to the THF solution of DPE8, and the amount of methyl methacrylate used was changed to (0.88 mL, 8.3 mmol). Mn and dispersity (PDI=Mw/Mn) of the Pre (11), measured by size exclusion chromatography (SEC), were 42.5 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

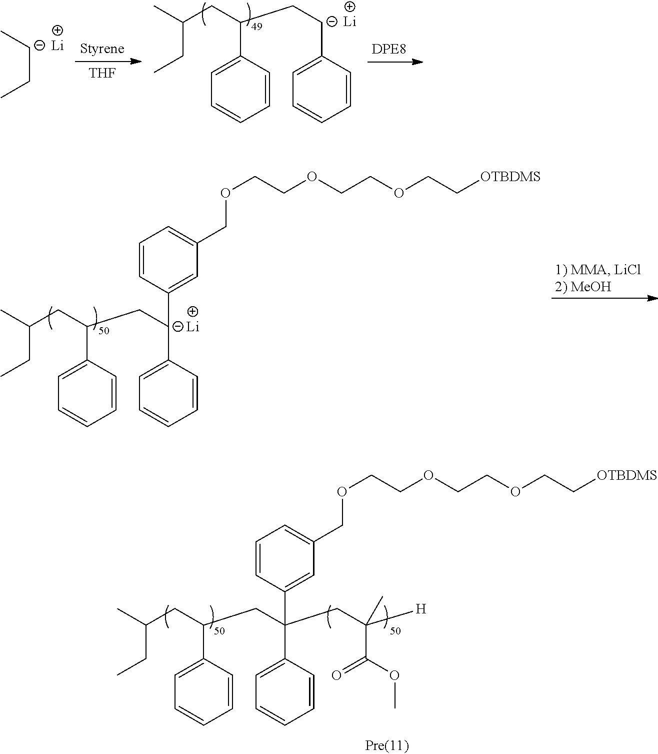

### Synthesis of BCP: P1-11

P1-11 was obtained by the same method as in P1-1, except that Pre (1) was changed to Pre (11). Mn and dispersity (PDI=Mw/Mn) of the P1-11, measured by size exclusion chromatography (SEC), were 43.0 kg-mol¹ and 1.03. The synthesis of P1-11 was confirmed by disappearance of the 1H-NMR peak derived from TBDMS.

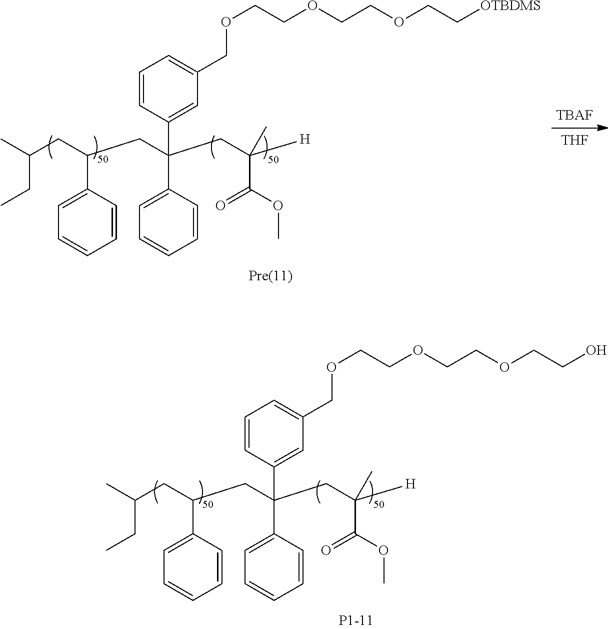

### Synthesis of block copolymer: P1-12

### Synthesis of BCP precursor: Pre (12)

A THF solution of 1,1-bis[3-(tert-butyl dimethylsilyloxymethyl)phenyl]ethene was prepared by the same method as that of the THF solution of DPE1, except that DPE1 (0.134 g, 0.209 mmol) was changed to 1,1-bis[3-(tert-butyl dimethylsilyloxymethyl)phenyl]ethene (0.098 g, 0.21 mmol) (Synthesis of Chain-End-Functionalized Poly(methyl methacrylate)s with a Definite Number of Benzyl Bromide Moieties and Their Application to Star-Branched Polymers |Macromolecules (acs.org)).

A precursor Pre (12) (1.10 g, yield: 64%) was obtained by the same method as in Pre (1), except that the amount of styrene used was changed to (1.05 mL, 9.17 mmol), the THF solution of DPE1 was changed to the THF solution of 1,1-bis[3-(tert-butyl dimethylsilyloxymethyl)phenyl]ethene, and the amount of methyl methacrylate used was changed to (0.81 mL, 7.6 mmol). Mn and dispersity (PDI=Mw/Mn) of the Pre (12), measured by size exclusion chromatography (SEC), were 41.5 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

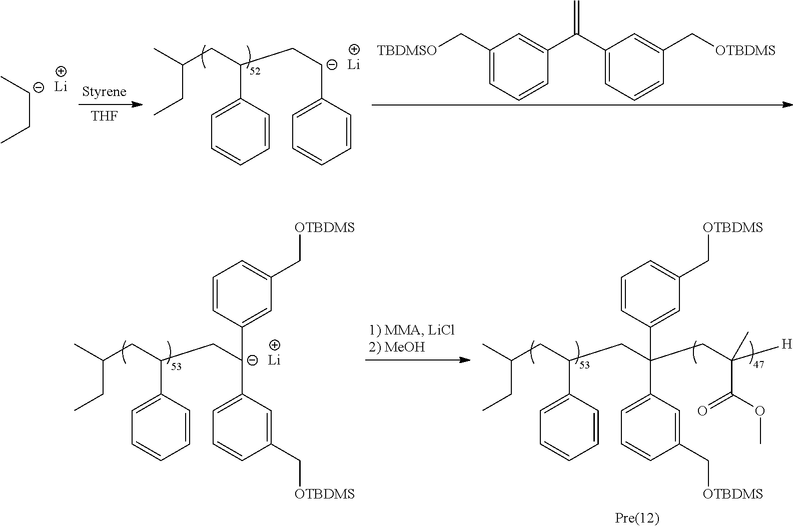

### Synthesis of BCP: P1-12

P1-12 was obtained by the same method as in P1-1, except that Pre (1) was changed to Pre (12). Mn and dispersity (PDI=Mw/Mn) of the P1-12, measured by size exclusion chromatography (SEC), were 42.0 kg-mol⁻¹ and 1.03. The synthesis of P1-12 was confirmed by disappearance of the 1H-NMR peak derived from TBDMS.

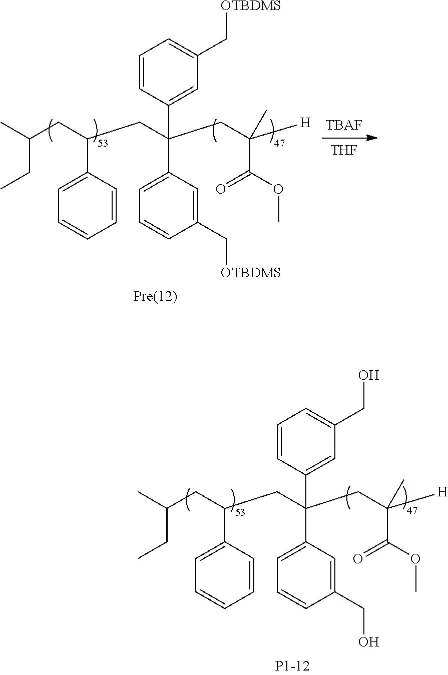

### Synthesis of block copolymer: P1-13

### Synthesis of diphenylethylene derivative: DPE9

An intermediate Int (2-9) (2.14 g, yield: 74%) was obtained by the same method as in Int (2-7), except that 6-[[tert-butyl(dimethyl)silyl]oxy]-1-propanol (10.8 g, 46.5 mmol) was changed to 4-(4-hydroxybutyl)-2,2-dimethyl-1,3-dioxolane (8.10 g, 46.5 mmol).

1H-NMR (CDCl3, 400 MHz):

δ (ppm)=1.21 (s, 6H, >C(CH3)2), 1.25 to 1.44 (m, 6H, —CH2CH2CH2CH<), 3.35 (t, 2H, -OCH2CH2CH2-), 3.62 (d, 1H, >CHCH2O-), 3.82 to 3.87 (m, 2H, >CHCH2-), 4.80 (m, 2H, ArCH2-), 7.37 (m, 1H, Ar), 7.51 to 7.81 (m, 8H, Ar)

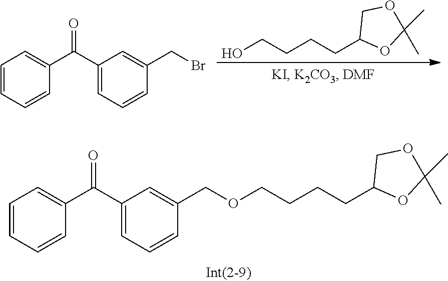 [SMILES: O=C(c1ccccc1)c1cccc(CBr)c1 ; CC1(C)OCC(CCCCO)O1 ; CC1(C)OCC(CCCCOCc2cccc(C(=O)c3ccccc3)c2)O1]

DPE9 (1.48 g, yield: 86%) was obtained by the same method as in DPE1, except that Int (2-1) (3.02 g, 4.70 mmol) was changed to Int (2-9) (1.73 g, 4.70 mmol).

1H-NMR (CDCl3, 400 MHz):

δ (ppm)=1.21 (s, 6H, >C(CH3)2), 1.25 to 1.44 (m, 6H, —CH2CH2CH2CH<), 3.35 (t, 2H, -OCH2CH2CH2-), 3.62 (d, 1H, >CHCH2O-), 3.82 to 3.87 (m, 2H, >CHCH2-), 4.80 (m, 2H, ArCH2-), 5.32 (s, 2H, C═CH₂), 7.22 to 7.37 (m, 9H, Ar)

13C-NMR (CDCl3, 100 MHz):

δ (ppm)=22.61, 26.20, 30.33, 31.99, 69.20, 70.04, 73.41, 77.82, 114.20, 119.25, 125.00, 127.46 to 128.60, 137.44, 139.97, 141.66, 150.20.

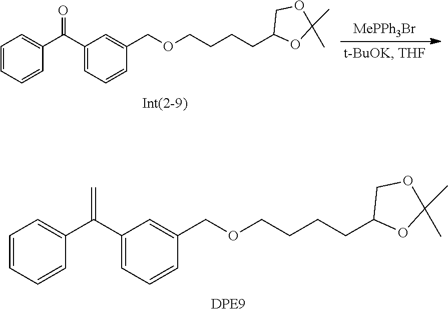

### Synthesis of BCP precursor: Pre (13)

A THF solution of DPE9 was prepared by the same method as that of the THF solution of DPE1, except that DPE1 (0.134 g, 0.209 mmol) was changed to DPE9 (0.077 g, 0.21 mmol).

A precursor Pre (13) (1.15 g, yield: 69%) was obtained by the same method as in Pre (1), except that the amount of styrene used was changed to (1.06 mL, 9.25 mmol), the THF solution of DPE1 was changed to the THF solution of DPE9, and the amount of methyl methacrylate used was changed to (0.75 mL, 7.0 mmol). Mn and dispersity (PDI=Mw/Mn) of the Pre (13), measured by size exclusion chromatography (SEC), were 40.2 kg-mol⁻¹ and 1.03.

1H-NMR (CDCl3, 400 MHz):

δ (ppm)=0.85 (α-CH3, PMMA), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

13C-NMR (CDCl3, 100 MHz):

δ (ppm)=16.37 to 16.47, 18.56, 22.61, 25.90, 26.20, 29.90, 30.35, 40.20 to 40.42, 44.43, 44.75, 51.73, 52.36, 54.04 to 54.31, 69.20, 70.04, 77.80, 119.25, 125.37 to 125.52, 127.18 to 128.14, 145.15 to 145.54, 176.88, 177.70, 178.00

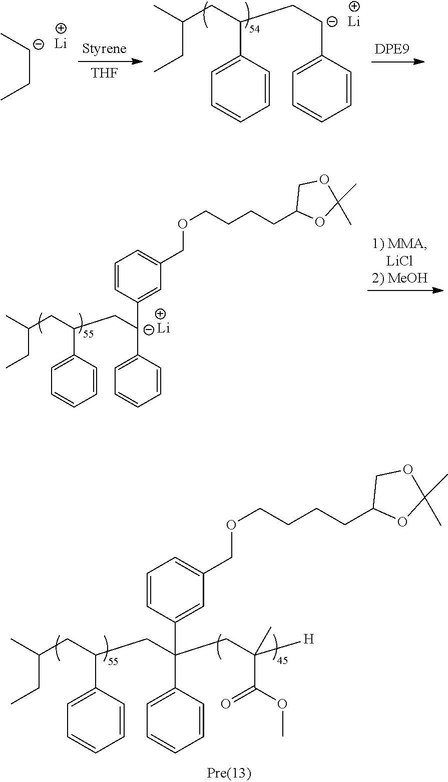

### Synthesis of BCP: P1-13

P1-13 was obtained by the same method as in P1-7, except that Pre (7) was changed to Pre (13). Mn and dispersity (PDI=Mw/Mn) of the P1-13, measured by size exclusion chromatography (SEC), were 40.7 kg-mol⁻¹ and 1.03. The synthesis of P1-13 was confirmed by disappearance of the 13C-NMR peak derived from 2,2-dimethyl-1,3-dioxolane.

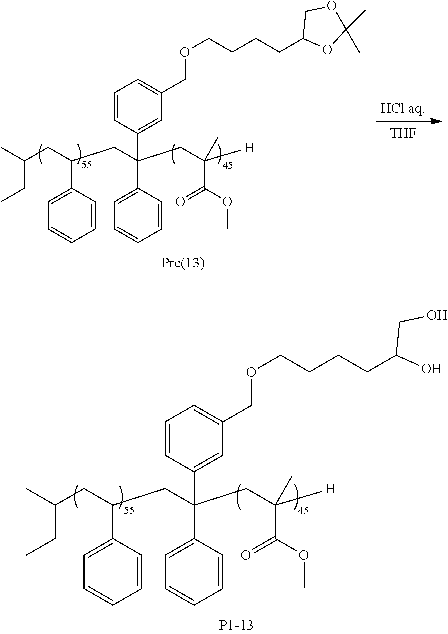

### Synthesis of block copolymer: P1-14

### Synthesis of diphenylethylene derivative: DPE10

An intermediate Int (2-10) (12.9 g, yield: 70%) was obtained by the same method as in Int (1-1), except that 6-chloro-1-hexanol (7.10 g, 52.0 mmol) was changed to [4-(3-hydroxypropyl)phenyl]phenylmethanone (12.5 g, 52.0 mmol).

1H-NMR (CDCl3, 400 MHz):

δ (ppm)=0.05 (s, 6H, —Si(CH3)2), 0.90 (s, 9H, —SiC(CH3)3), 1.87 (q, 2H, ArCH2CH2CH2-), 2.77 (m, 2H, ArCH2-), 3.77 (t, 2H, —CH2O-), 6.92 (d, 2H, Ar), 7.51 (m, 2H, Ar), 7.61 to 7.72 (m, 3H, Ar), 7.81 (d, 2H, Ar)

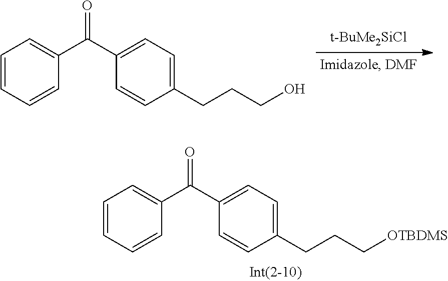 [SMILES: O=C(c1ccccc1)c1ccc(CCCO)cc1 ; CC(C)(C)[Si](C)(C)OCCCc1ccc(C(=O)c2ccccc2)cc1]

DPE10 (1.38 g, yield: 83%) was obtained by the same method as in DPE1, except that Int (2-1) (3.02 g, 4.70 mmol) was changed to Int (2-10) (1.67 g, 4.70 mmol).

1H-NMR (CDCl3, 400 MHz):

δ (ppm)=0.05 (s, 6H, —Si(CH3)2), 0.90 (s, 9H, —SiC(CH3)3), 1.87 (q, 2H, ArCH2CH2CH2-), 2.77 (m, 2H, ArCH2-), 3.77 (t, 2H, —CH2O-), 5.32 (s, 2H, C═CH2), 6.77 (d, 2H, Ar), 7.34 to 7.37 (m, 7H, Ar)

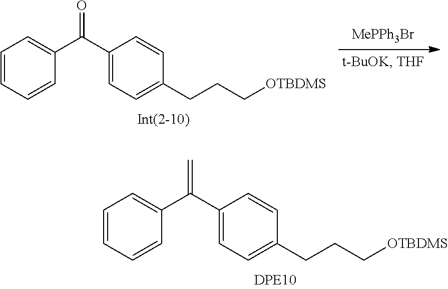

### Synthesis of BCP precursor: Pre (14)

A THF solution of DPE10 was prepared by the same method as that of the THF solution of DPE1, except that DPE1 (0.134 g, 0.209 mmol) was changed to DPE10 (0.074 g, 0.21 mmol).

A precursor Pre (14) (1.02 g, yield: 61%) was obtained by the same method as in Pre (1), except that the amount of styrene used was changed to (0.91 mL, 8.0 mmol), the THF solution of DPE1 was changed to the THF solution of DPE10, and the amount of methyl methacrylate used was changed to (0.89 mL, 8.4 mmol). Mn and dispersity (PDI=Mw/Mn) of the Pre (14), measured by size exclusion chromatography (SEC), were 40.6 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

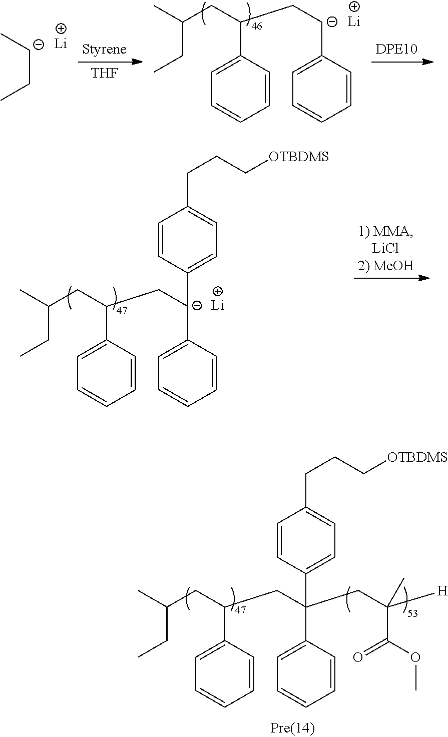

### Synthesis of BCP: P1-14

P1-14 was obtained by the same method as in P1-1, except that Pre (1) was changed to Pre (14). Mn and dispersity (PDI=Mw/Mn) of the P1-14, measured by size exclusion chromatography (SEC), were 41.1 kg-mol⁻¹ and 1.03. The synthesis of P1-14 was confirmed by disappearance of the 1H-NMR peak derived from TBDMS.

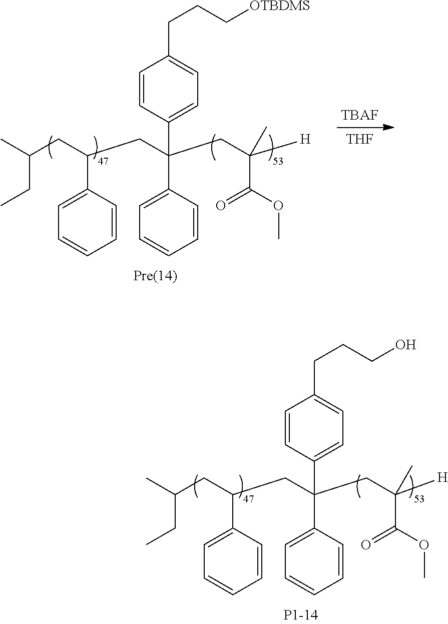

### Synthesis of block copolymer: P1-15

### Synthesis of diphenylethylene derivative: DPE11

An intermediate Int (2-11) (2.32 g, yield: 74%) was obtained by the same method as in Int (2-1), except that 4,4′-dihydroxybenzophenone (1.69 g, 7.85 mmol) was changed to [4-(3-bromopropyl)phenyl]phenylmethanone] (1.38 g, 7.85 mmol) (Journal of Physical Chemistry A (2008), 112(7), 1403-1407.), and Int (1-1) (11.7 g, 46.5 mmol) was changed to 2-[[tert-butyl(dimethyl)silyl]oxy]ethanol (8.20 g, 46.5 mmol). 1H-NMR (CDCl3, 400 MHz): δ (ppm)=0.05 (s, 6H, —Si(CH3)2), 0.90 (s, 9H, —SiC(CH3)3), 1.80 (q, 2H, ArCH2CH2CH2-), 2.77 (m, 2H, ArCH2-), 3.35 (t, 2H, ArCH2CH2CH2O-), 3.59 (t, 2H, —OCH2CH2O-), 3.96 (t, 2H, —OCH2CH2O-), 6.92 (d, 2H, Ar), 7.51 (m, 2H, Ar), 7.61 to 7.72 (m, 3H, Ar), 7.81 (d, 2H, Ar)

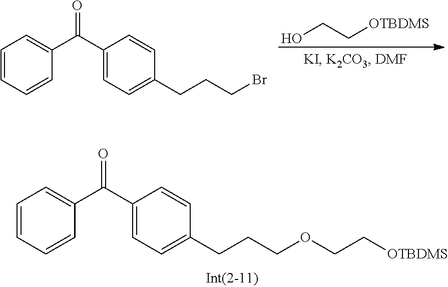 [SMILES: O=C(c1ccccc1)c1ccc(CCCBr)cc1 ; CC(C)(C)[Si](C)(C)OCCO ; CC(C)(C)[Si](C)(C)OCCOCCCc1ccc(C(=O)c2ccccc2)cc1]

DPE11 (1.60 g, yield: 86%) was obtained by the same method as in DPE1, except that Int (2-1) (3.02 g, 4.70 mmol) was changed to Int (2-11) (1.87 g, 4.70 mmol).

1H-NMR (CDCl3, 400 MHz):

δ (ppm)=0.05 (s, 6H, —Si(CH3)2), 0.90 (s, 9H, —SiC(CH3)3), 1.80 (q, 2H, ArCH2CH2CH2-), 2.77 (m, 2H, ArCH2-), 3.35 (t, 2H, ArCH2CH2CH2O-), 3.59, 3.96 (t, 2H, —OCH2CH2O-), 5.32 (s, 2H, C═CH2), 6.77 (d, 2H, Ar), 7.34 to 7.37 (m, 7H, Ar)

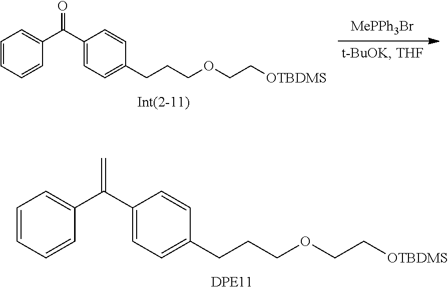 [SMILES: CC(C)(C)[Si](C)(C)OCCOCCCc1ccc(C(=O)c2ccccc2)cc1 ; "MePPh3Br" ; C=C(c1ccccc1)c1ccc(CCCOCCO[Si](C)(C)C(C)(C)C)cc1]

### Synthesis of BCP precursor: Pre (15)

A THF solution of DPE11 was prepared by the same method as that of the THF solution of DPE1, except that DPE1 (0.134 g, 0.209 mmol) was changed to DPE11(0.083 g, 0.21 mmol).

A precursor Pre (15) (1.26 g, yield: 65%) was obtained by the same method as in Pre (1), except that the amount of styrene used was changed to (1.08 mL, 9.44 mmol), the THF solution of DPE1 was changed to the THF solution of DPE11, and the amount of methyl methacrylate used was changed to (1.02 mL, 9.53 mmol). Mn and dispersity (PDI=Mw/Mn) of the Pre (15), measured by size exclusion chromatography (SEC), were 47.0 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

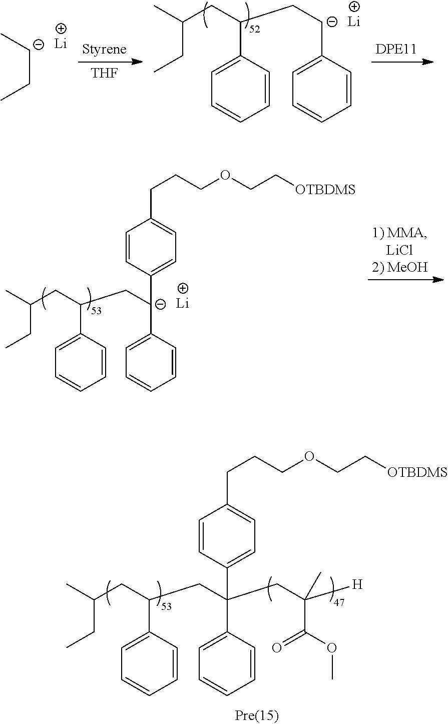

### Synthesis of BCP: P1-15

P1-15 was obtained by the same method as in P1-1, except that Pre (1) was changed to Pre (15). Mn and dispersity (PDI=Mw/Mn) of the P1-15, measured by size exclusion chromatography (SEC), were 47.6 kg-mol⁻¹ and 1.03. The synthesis of P1-15 was confirmed by disappearance of the 1H-NMR peak derived from TBDMS.

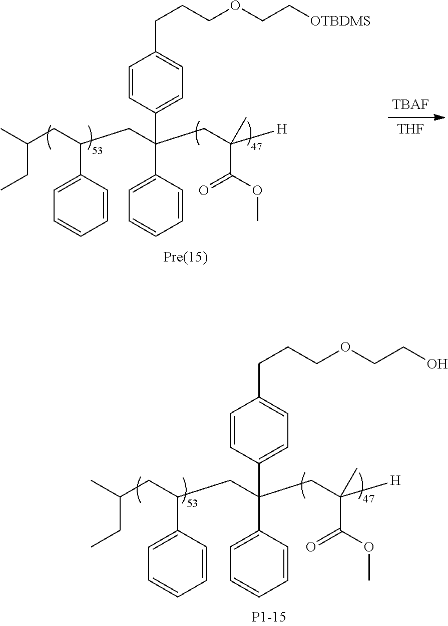

### Synthesis of block copolymer: P1-16

### Synthesis of diphenylethylene derivative: DPE12

An intermediate Int (2-12) (2.11 g, yield: 73%) was obtained by the same method as in Int (2-11), except that 2-[[tert-butyl(dimethyl)silyl]oxy]ethanol (8.20 g, 46.5 mmol) was changed to 4-(2-hydroxyethyl)-2,2-dimethyl-1,3-dioxolane (6.80 g, 46.5 mmol).

1H-NMR (CDCl3, 400 MHz):

δ (ppm)=1.21 (s, 6H, >C(CH3)2), 1.64 (m, 2H, —CH2CH<), 1.80 (q, 2H, ArCH2CH2CH2-), 2.77 (m, 2H, ArCH2-), 3.35 (t, 4H, -CH2OCH2-), 3.62 (d, 1H, >CHCH2O-), 3.82 to 3.87 (m, 2H, >CHCH2-), 6.92 (d, 2H, Ar), 7.51 (m, 2H, Ar), 7.61 to 7.72 (m, 3H, Ar), 7.81 (d, 2H, Ar)

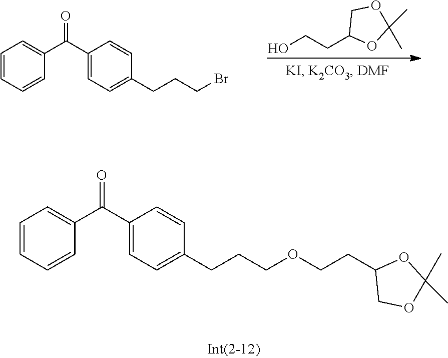

DPE12 (1.43 g, yield: 83%) was obtained by the same method as in DPE1, except that Int (2-1) (3.02 g, 4.70 mmol) was changed to Int (2-12) (1.73 g, 4.70 mmol).

1H-NMR (CDCl3, 400 MHz):

δ (ppm)=1.21 (s, 6H, >C(CH3)2), 1.64 (m, 2H, —CH2CH<), 1.80 (q, 2H, ArCH2CH2CH2-), 2.77 (m, 2H, ArCH2-), 3.35 (t, 4H, -CH2OCH2-), 3.62 (d, 1H, >CHCH2O-), 3.82 to 3.87 (m, 2H, >CHCH2-), 5.32 (s, 2H, C═CH2), 6.77 (d, 2H, Ar), 7.34 to 7.37 (m, 7H, Ar)

13C-NMR (CDCl3, 100 MHz):

δ (ppm)=22.61, 26.20, 31.30, 32.00, 32.99, 69.20-69.30, 72.00, 75.41, 114.20, 119.25, 125.00, 127.46 to 128.60, 134.74, 138.95, 141.66, 150.20

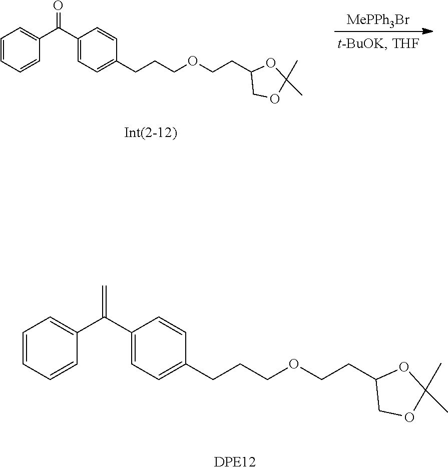 [SMILES: CC1(C)OCC(CCOCCCc2ccc(C(=O)c3ccccc3)cc2)O1 ; "MePPh3Br" ; C=C(c1ccccc1)c1ccc(CCCOCCC2COC(C)(C)O2)cc1]

### Synthesis of BCP precursor: Pre (16)

A THF solution of DPE12 was prepared by the same method as that of the THF solution of DPE1, except that DPE1 (0.134 g, 0.209 mmol) was changed to DPE12 (0.077 g, 0.21 mmol).

A precursor Pre (16) (1.35 g, yield: 68%) was obtained by the same method as in Pre (1), except that the amount of styrene used was changed to (1.17 mL, 10.3 mmol), the THF solution of DPE1 was changed to the THF solution of DPE12, and the amount of methyl methacrylate used was changed to (0.98 mL, 9.2 mmol). Mn and dispersity (PDI=Mw/Mn) of the Pre (16), measured by size exclusion chromatography (SEC), were 48.0 kg-mol⁻¹ and 1.03.

1H-NMR (CDCl3, 400 MHz):

δ (ppm)=0.85 (α-CH3, PMMA), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.42 (Ar, PS)

13C-NMR (CDCl3, 100 MHz):

δ (ppm)=16.37 to 16.47, 18.56, 22.61, 25.90, 26.20, 31.30, 32.00, 32.99, 40.20 to 40.42, 44.43, 44.75, 51.73, 52.36, 54.04 to 54.31, 69.20, 72.00, 75.80, 119.25, 125.37 to 125.52, 127.18 to 128.60, 134.74, 138.95, 141.66, 145.15 to 145.54, 176.88, 177.70, 178.00

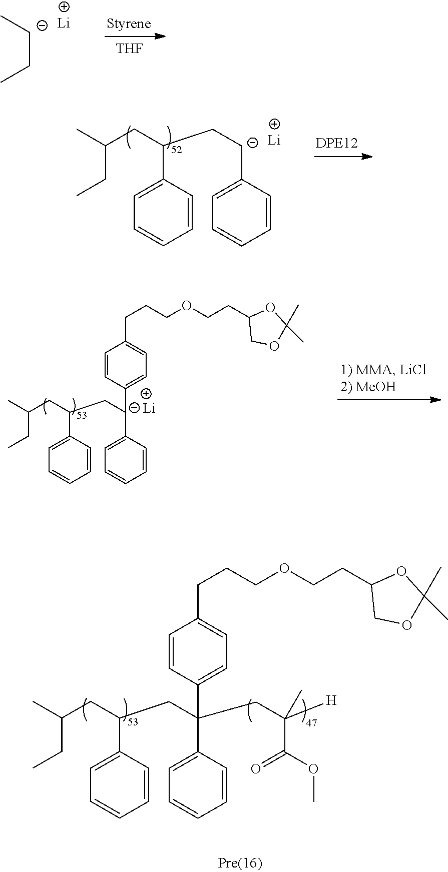

### Synthesis of BCP: P1-16

P1-16 was obtained by the same method as in P1-7, except that Pre (7) was changed to Pre (16). Mn and dispersity (PDI=Mw/Mn) of the P1-16, measured by size exclusion chromatography (SEC), were 48.6 kg-mol⁻¹ and 1.03. The synthesis of P1-16 was confirmed by disappearance of the 13C-NMR peak derived from 2,2-dimethyl-1,3-dioxolane.

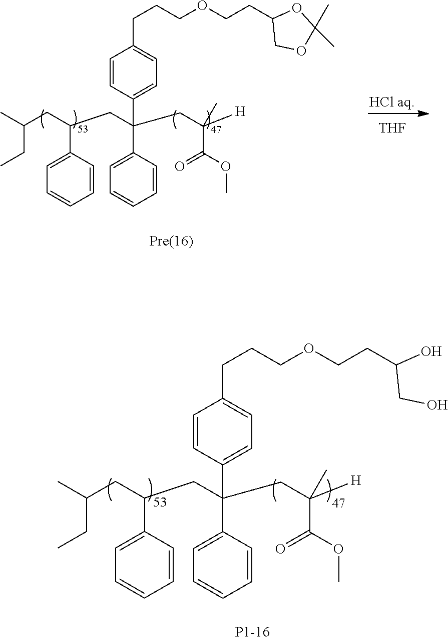

### Synthesis of block copolymer: P1-17

### Synthesis of BCP precursor: Pre (17)

A THF solution of 4,5-dihydro-4,4-dimethyl-2-[4-(1-phenylethenyl)phenyl]-oxazole was prepared by the same method as that of the THF solution of DPE1, except that DPE1 (0.134 g, 0.209 mmol) was changed to 4,5-dihydro-4,4-dimethyl-2-[4-(1-phenylethenyl)phenyl]-oxazole (0.058 g, 0.21 mmol) (Gabriel J. Summers & Roderic P. Quirk Polymer International 1996, 40, 79.).

A precursor Pre (17) (1.20 g, yield: 70%) was obtained by the same method as in Pre (1), except that the amount of styrene used was changed to (0.99 mL, 8.7 mmol), the THF solution of DPE1 was changed to the THF solution of 4,5-dihydro-4,4-dimethyl-2-[4-(1-phenylethenyl)phenyl]-oxazole, and the amount of methyl methacrylate used was changed to (0.86 mL, 8.1 mmol). Mn and dispersity (PDI=Mw/Mn) of the Pre (17), measured by size exclusion chromatography (SEC), were 41.4 kg-mol⁻¹ and 1.03.

1H-NMR (CDCl3, 400 MHz):

δ (ppm)=0.85 (α-CH3, PMMA), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 4.08 (—OCH2C(CH3)₂—, oxazoline), 6.39 to 6.85, 6.91 to 7.42 (Ar, PS)

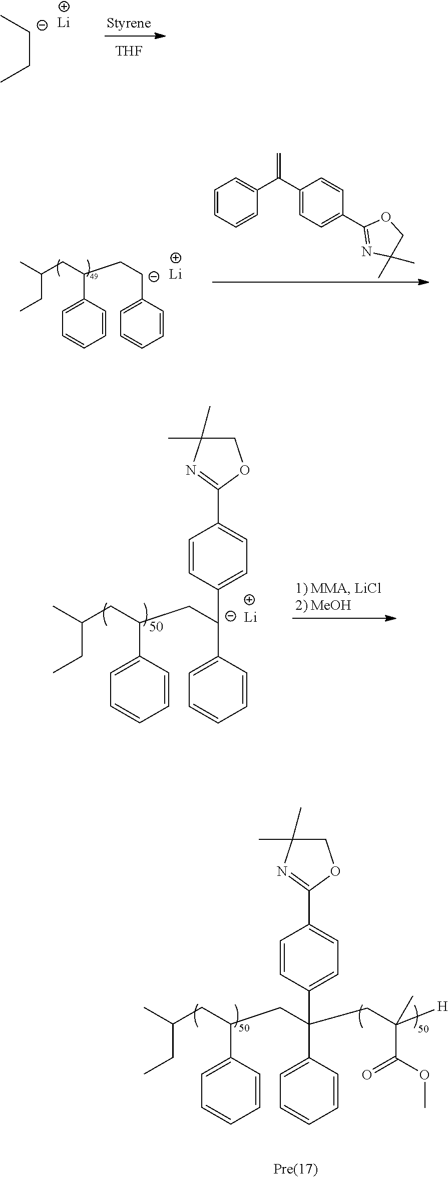

### Synthesis of BCP: P1-17

Pre (17) (1.00 g, 24.2 μmol) was weighed in a two-neck flask, THF (10.0 mL) was added thereto, 6N hydrochloric acid (1.0 mL) was added thereto, and the mixture was stirred at 50° C. for 5 hours. After the reaction solution was returned to room temperature, the solid content was removed by filtration. The filtrate was added to methanol (300 mL) and subjected to sedimentation purification. The solid recovered by filtration was dried under reduced pressure at 40° C. to obtain P1-17 (0.70 g, yield: 70%). Mn and dispersity (PDI=Mw/Mn) of the P1-17, measured by size exclusion chromatography (SEC), were 41.9 kg-mol⁻¹ and 1.03. The synthesis of P1-17 was confirmed by disappearance of the 1H-NMR peak derived from an oxazoline ring.

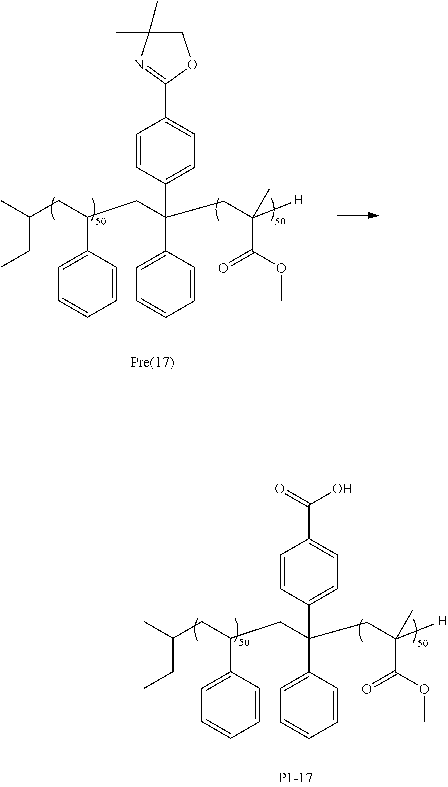

### Synthesis of block copolymer: P1-18

### Synthesis of diphenylethylene derivative: DPE13

2-[[tert-butyl(dimethyl)silyl]oxy]ethanol (1.76 g, 10.0 mmol), dichloromethane (50 mL), pyridine (8.0 mL), and 4-dimethylaminopyridine (3.05 g, 25.0 mmol) were added to a two-neck flask, and stirred at room temperature until they were completely dissolved. After the solution was cooled in an ice bath, 4-benzoylbenzoyl chloride (12.2 g, 50.0 mmol) (Gabriel J. Summers & Roderic P. Quirk Polymer International 1996, 40, 79.) was gently added dropwise thereto, and then the mixture was returned to room temperature and stirred for 2 hours. The reaction solution was washed four times with 1N hydrochloric acid (30 mL), and the combined water layer was extracted with dichloromethane (50 mL). The organic layer was dried with magnesium sulfate, the solvent was distilled off under reduced pressure, and the resultant was purified by column chromatography using hexane. The solvent was distilled off under reduced pressure to obtain an intermediate Int (2-13) (2.70 g, yield: 70%).

1H-NMR (CDCl3, 400 MHz):

δ (ppm)=0.05 (s, 6H, —Si(CH3)2), 0.90 (s, 9H, —SiC(CH3)3), 4.25, 4.44 (t, 2H, —COOCH2CH2O-), 7.51 (m, 2H, Ar), 7.61 (m, 1H, Ar), 7.80 to 7.82 (m, 6H, Ar)

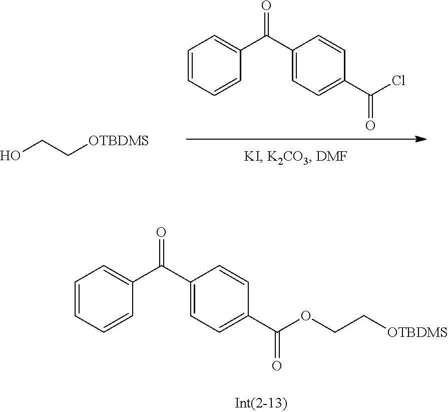 [SMILES: O=C(Cl)c1ccc(C(=O)c2ccccc2)cc1 ; CC(C)(C)[Si](C)(C)OCCO ; CC(C)(C)[Si](C)(C)OCCOC(=O)c1ccc(C(=O)c2ccccc2)cc1]

DPE13 (1.49 g, yield: 83%) was obtained by the same method as in DPE1, except that Int (2-1) (3.02 g, 4.70 mmol) was changed to Int (2-13) (1.81 g, 4.70 mmol).

1H-NMR (CDCl3, 400 MHz):

δ (ppm)=0.05 (s, 6H, —Si(CH3)2), 0.90 (s, 9H, —SiC(CH3)3), 4.25, 4.44 (t, 2H, —COOCH2CH2O-), 5.32 (s, 2H, C═CH2), 7.33 to 7.37 (m, 5H, Ar), 7.45 (d, 2H, Ar), 7.67 (d, 2H, Ar)

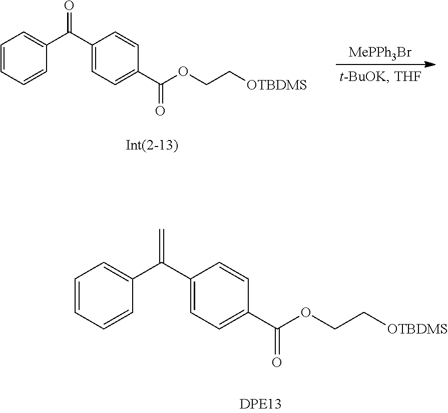 [SMILES: CC(C)(C)[Si](C)(C)OCCOC(=O)c1ccc(C(=O)c2ccccc2)cc1 ; "MePPh3Br" ; C=C(c1ccccc1)c1ccc(C(=O)OCCO[Si](C)(C)C(C)(C)C)cc1]

### Synthesis of BCP precursor: Pre (18)

A THF solution of DPE13 was prepared by the same method as that of the THF solution of DPE1, except that DPE1 (0.134 g, 0.209 mmol) was changed to DPE13 (0.080 g, 0.21 mmol).

A precursor Pre (18) (1.16 g, yield: 68%) was obtained by the same method as in Pre (1), except that the amount of styrene used was changed to (1.12 mL, 9.77 mmol), the THF solution of DPE1 was changed to the THF solution of DPE13, and the amount of methyl methacrylate used was changed to (0.73 mL, 6.9 mmol). Mn and dispersity (PDI=Mw/Mn) of the Pre (18), measured by size exclusion chromatography (SEC), were 41.0 kg-mol⁻¹ and 1.03.

1H-NMR (CDCl3, 400 MHz):

δ (ppm)=0.06 to 0.07 (—Si(CH3)2), 0.85 (α-CH3, PMMA), 0.90 (—SiC(CH3)3), 1.02 (α-CH3, PMMA), 1.23 to 1.69 (—CH2CH—, PS), 1.74 to 2.02 (—CH2CH—, PS, —CH2C(CH3)-, PMMA), 3.60 (—COOCH3, PMMA), 6.39 to 6.85, 6.91 to 7.67 (Ar, PS)

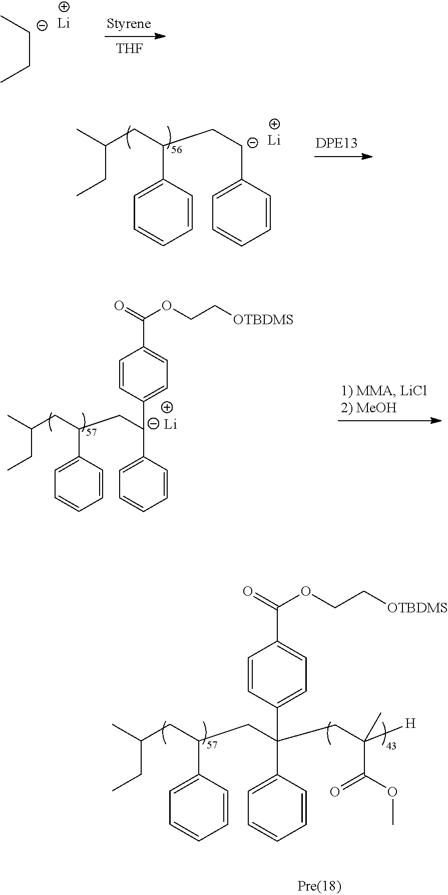

### Synthesis of BCP: P1-18

P1-18 was obtained by the same method as in P1-1, except that Pre (1) was changed to Pre (18). Mn and dispersity (PDI=Mw/Mn) of the P1-18, measured by size exclusion chromatography (SEC), were 41.5 kg-mol⁻¹ and 1.03. The synthesis of P1-18 was confirmed by disappearance of the 1H-NMR peak derived from TBDMS.

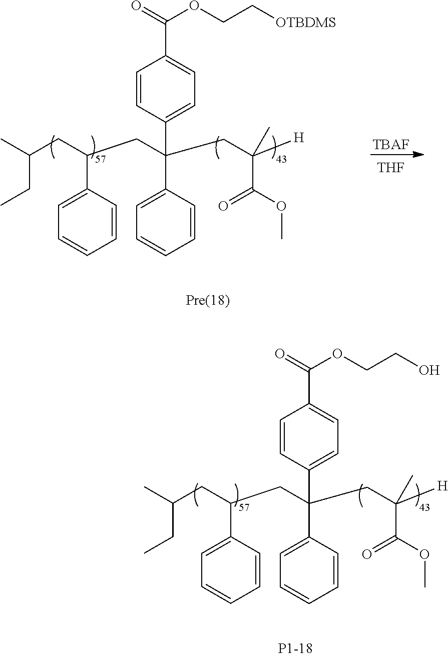

### Synthesis of block copolymer: P1-19

### Synthesis of diphenylethylene derivative: DPE14

An intermediate Int (2-14) (2.34 g, yield: 66%) was obtained by the same method as in Int (2-13), except that 2-[[tert-butyl(dimethyl)silyl]oxy]ethanol (1.76 g, 10.0 mmol) was changed to 4-(2-hydroxyethyl)-2,2-dimethyl-1,3-dioxolane (1.46 g, 10.0 mmol). 1H-NMR (CDCl3, 400 MHz): δ (ppm)=1.21 (s, 6H, >C(CH3)2), 1.93 (m, 2H, —CH2CH<), 3.62 (d, 1H, >CHCH2O-), 3.82 to 3.87 (m, 2H, >CHCH2-), 4.23 (t, 2H, -COOCH2-), 7.51 (m, 2H, Ar), 7.61 (m, 1H, Ar), 7.80 to 7.82 (m, 6H, Ar)

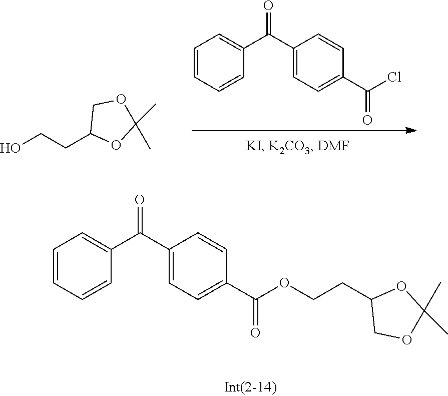

DPE14 (1.42 g, yield: 86%) was obtained by the same method as in DPE1, except that Int (2-1) (3.02 g, 4.70 mmol) was changed to Int (2-14) (1.67 g, 4.70 mmol).

1H-NMR (CDCl3, 400 MHz):

δ (ppm)=1.21 (s, 6H, >C(CH3)2), 1.93 (m, 2H, —CH2CH<), 3.62 (d, 1H, >CHCH2O-), 3.82 to 3.87 (m, 2H, >CHCH2-), 4.23 (t, 2H, -COOCH2-), 5.32 (s, 2H, C═CH2), 7.33 to 7.37 (m, 5H, Ar), 7.45 (d, 2H, Ar), 7.67 (d, 2H, Ar)

13C-NMR (CDCl3, 100 MHz):

δ (ppm)=26.20, 30.70, 58.93, 68.90, 75.31, 114.20, 119.25, 125.00, 127.46 to 128.60, 141.66, 145.93, 150.20, 165.98

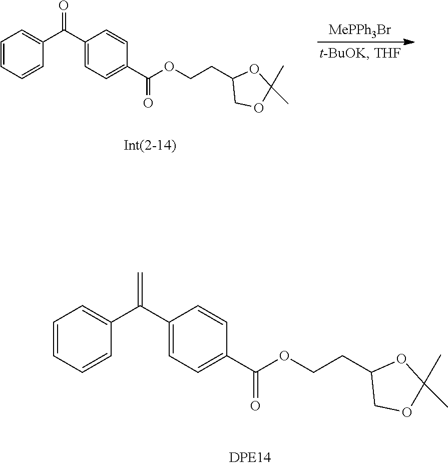 [SMILES: CC1(C)OCC(CCOC(=O)c2ccc(C(=O)c3ccccc3)cc2)O1 ; "MePPh3Br" ; C=C(c1ccccc1)c1ccc(C(=O)OCCC2COC(C)(C)O2)cc1]

### Synthesis of BCP precursor: Pre (19)

A THF solution of DPE14 was prepared by the same method as that of the THF solution of DPE1, except that DPE1 (0.134 g, 0.209 mmol) was changed to DPE14 (0.074 g, 0.21 mmol).

A precursor Pre (19) (1.19 g, yield: 64%) was obtained by the same method as in Pre (1), except that the amount of styrene used was changed to (1.14 mL, 9.98 mmol), the THF solution of DPE1 was changed to the THF solution of DPE14, and the amount of methyl methacrylate used was changed to (0.88 mL, 8.2 mmol). Mn and dispersity (PDI=Mw/Mn) of the Pre (19), measured by size exclusion chromatography (SEC), were 45.0 kg-mol⁻¹ and 1.03.

13C-NMR (CDCl3, 100 MHz):

δ (ppm)=16.37 to 16.47, 18.56, 25.90, 26.20, 30.70, 40.20 to 40.42, 44.43, 44.75, 51.73, 52.36, 54.04 to 54.31, 58.93, 68.90, 75.31, 114.20, 119.25, 125.00 to 125.52, 127.18 to 128.60, 141.66, 145.15 to 145.93, 150.20, 165.98, 176.88, 177.70, 178.00

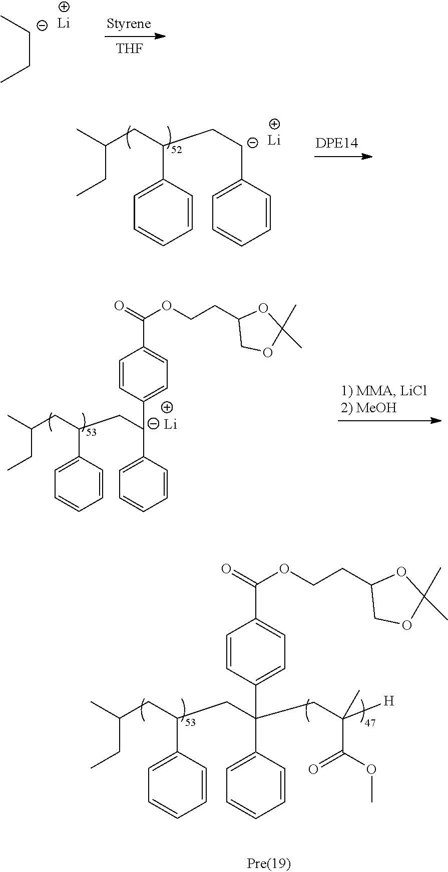

### Synthesis of BCP: P1-19

P1-19 was obtained by the same method as in P1-7, except that Pre (7) was changed to Pre (19). Mn and dispersity (PDI=Mw/Mn) of the P1-19, measured by size exclusion chromatography (SEC), were 45.5 kg-mol⁻¹ and 1.03. The synthesis of P1-19 was confirmed by disappearance of the 13C-NMR peak derived from 2,2-dimethyl-1,3-dioxolane.

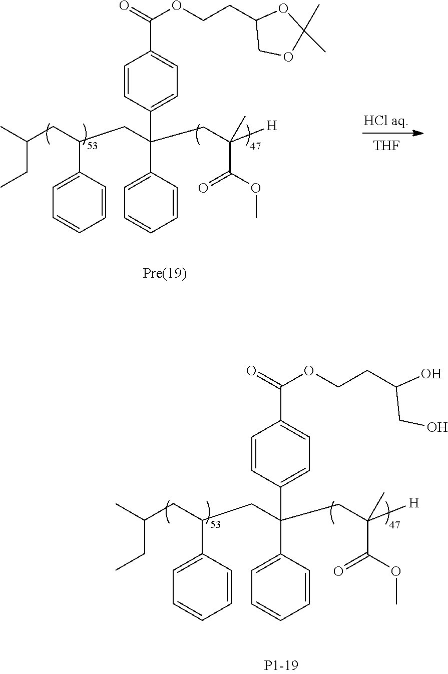

### Preparation of BCP Composition

Each component shown in Table 1 was mixed and dissolved, and each BCP composition (solid content concentration: 1% by mass) in each of Examples was prepared.

TABLE 1

| | | Organic |
|---|---|---|
| BCP | BCP | solvent |
| composition | component | component |
| BCP1-1 | P1-1 | (S)-1 |
| | [100] | [9900] |
| BCP2-1 | P2-1 | (S)-1 |
| | [100] | [9900] |
| BCP2-2 | P2-2 | (S)-1 |
| | [100] | [9900] |

In Table 1, each abbreviation has the following meaning. The numerical value in the brackets is a blending amount (part by mass). The number-average molecular weight (Mn) of each polymer was determined by size exclusion chromatography (SEC). The copolymerization compositional ratio (proportion (molar ratio) of each constitutional unit in a structural formula) of each polymer was determined by ¹³C-NMR.

P1-1: BCP of P1-1 described above

P2-1: BCP represented by Chemical Formula (P2-1); Mn=45.0 (kg-mol⁻¹)

P2-2: BCP represented by Chemical Formula (P2-2); Mn=42.1 (kg-mol⁻¹)

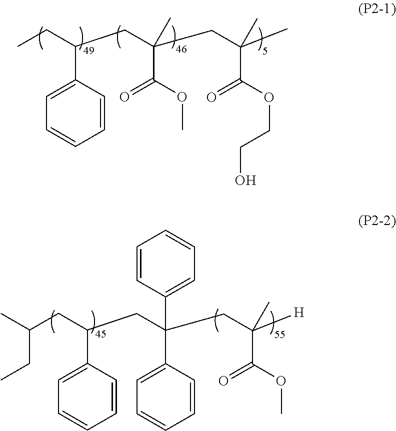

(S)-1: propylene glycol monomethyl ether acetate (PGMEA)

### Production of Structure Body Including Phase-Separated Structure

After a guide pattern was formed with a resist composition, a structure body including a phase-separated structure was obtained by the following steps using the above-described resin composition for forming a phase-separated structure of each of Examples.

### Step (i):

An organic anti-reflective film composition “ARC-29A” (trade name, manufactured by Brewer Science, Inc.) was applied to a 12-inch silicon wafer using a spinner, and the composition was then baked and dried on a hotplate at 205° C. for 60 seconds, thereby forming an organic anti-reflective film with a film thickness of 89 nm. The BCP composition shown in Table 3 was spin-coated on the organic anti-reflective film and heated at 250° C. for 30 minutes. As a result, an undercoat agent layer with a film thickness of 10 nm, made of the above-described crosslinked neutral film composition, was formed on the surface of the substrate.

### Formation of Guide Pattern:

A resist film for forming a guide pattern was applied onto the undercoat agent layer using a spinner, subjected to pre-bake treatment (PAB) on a hotplate, and dried to form a resist film for forming a guide pattern with a film thickness of 90 nm. Selective irradiation was performed using ArF excimer laser (193 nm) by an ArF exposure apparatus XT-1900Gi (manufactured by ASML) through a mask pattern. The resist film was subjected to post-exposure bake (PEB) treatment, further developed with butyl acetate, and shaken off to dry. Next, post-bake treatment was performed under conditions of 100° C. for 1 minute and then 230° C. for 10 minutes to form a guide pattern matching the space dimension four times a d value of the block copolymer used.

### Step (ii):

On the substrate on which the guide pattern had been formed, the BCP composition shown in Table 3 was spin-coated to have a film thickness of 24 nm, thereby forming a self-organization layer.

Step (iii):

The self-organization layer formed on the substrate was pre-baked at 90° C. for 60 seconds under a nitrogen atmosphere, and then annealed at 200° C. for 30 minutes under a nitrogen atmosphere to form a phase-separated structure.

### Step (iv):

Oxygen plasma treatment (200 mL/min, 40 Pa, 40° C., 200 W, 20 seconds) was performed on the substrate on which the phase-separated structure had been formed using TCA-3822 (manufactured by TOKYO OHKA KOGYO CO., LTD.), and thus a PMMA phase was selectively removed.

Measurement of period of structure body including phase-separated structure

Measurement was performed by a small-angle X-ray scattering (SAXS) method, and a period (nm) of the structure body was determined at the first scattering peak of the SAXS pattern curve. The results are shown in Table 3 as “Period”.

### Observation of Morphology

The surface (in the phase-separated state) of the obtained substrate was observed with a length-measuring SEM (scanning electron microscope, trade name: CG6300, manufactured by Hitachi High-Tech Corporation) to confirm the morphology of the phase-separated structure. The evaluation was performed based on the following evaluation standard, and the results are shown in Table 3 as “Morphology”.

### Evaluation Standard

A: vertical orientation was observed.

B: vertical orientation was not observed.

### Evaluation of Pattern Defects

The pattern after the step (ii) in Production of structure body including phase-separated structure was observed from above 10 sheets at a magnification of 100,000 times by a length-measuring SEM (scanning electron microscope, trade name: CG6300, manufactured by Hitachi High-Technologies Corporation), and the number of defects was counted.

As a result of such counting, the pattern defects were evaluated based on the following evaluation standard. The results are shown in Table 3 as “Defect”.

### Evaluation Standard

A: total number of defects was less than 5.

B: total number of defects was 5 or more.

TABLE 2

| | Undercoat | Self- | | | |
|---|---|---|---|---|---|
| | agent | organization | Period | Morph- | |
| | layer | layer | (nm) | ology | Defect |
| Example 1 | BCP1-1 | BCP1-1 | 22.5 | A | A |
| Comparative | BCP2-1 | BCP1-1 | 22.8 | A | B |
| Example 1 | | | | | |
| Comparative | BCP2-2 | BCP2-2 | Un- | B | Un- |
| Example 2 | | | evaluable | | evaluable |

From the results shown in Table 3, in Example 1, a phase-separated structure could be formed in which the morphology was favorable and the number of defects was reduced. On the other hand, in Comparative Example 1, the morphology was favorable, but the number of defects was not sufficiently reduced. In Comparative Example 2, the phase-separated structure could not be formed.

From the above results, by using the block copolymer (P1), it was confirmed that, even in a case where the undercoat agent layer and the self-organization layer were formed of the same BCP composition, a phase-separated structure could be formed with few defects and favorable phase separation performance.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

1: Substrate
2: Undercoat agent layer
3: Self-organization layer
3′: Structure body
3a: Phase
3b: Phase

What is claimed is:

1. A method for producing a structure body including a phase-separated structure, the method comprising:
(i) applying a composition containing a block copolymer represented by General Formula (n1) onto a substrate to form an undercoat agent layer;
(ii) applying the composition containing the block copolymer onto the undercoat agent layer to form a self-organization layer; and
(iii) subjecting the self-organization layer to phase separation, 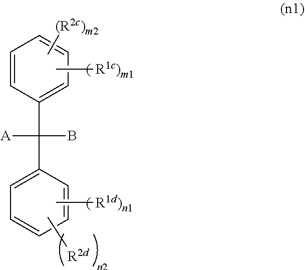
wherein A represents a first polymer block; B represents a second polymer block; R^{1c} and R^{1d} each independently represents a substrate adsorptive group-containing group; R^{2c} and R^{2d} each independently represents a substituent other than the substrate adsorptive group-containing group; m1 and n1 each independently represents an integer of 0 to 5; m2 and n2 each independently represents an integer of 0 to 5; m1+n1;>1; m1+m2<5; and n1+n2<5; provided that, when m1 is an integer of 2 or more, a plurality of R^{1c}'s may be the same as or different from each other, when m2 is an integer of 2 or more, a plurality of R^{2c}'s may be the same as or different from each other, when n1 is an integer of 2 or more, a plurality of Rid's may be the same as or different from each other, and when n2 is an integer of 2 or more, a plurality of R^{2d}'s may be the same as or different from each other.

2. The method for producing a structure body including a phase-separated structure according to claim 1, wherein the first polymer block and the second polymer block have no constitutional unit (u0) represented by any one of General Formulae (u0-1) to (u0-4), 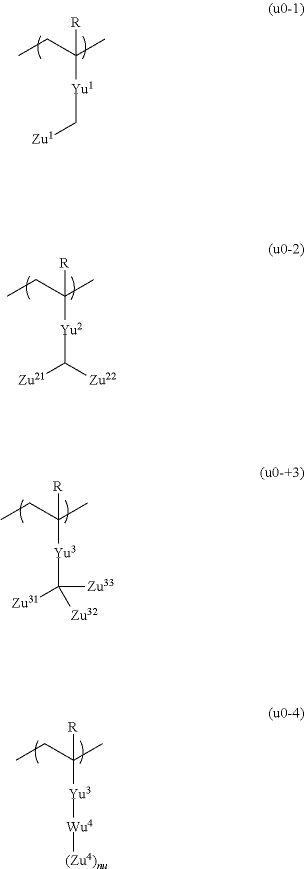
wherein R represents a hydrogen atom, an alkyl group having 1 to 5 carbon atoms, or a fluorinated alkyl group having 1 to 5 carbon atoms; Yu¹, Yu², Yu³, and Yu⁴ each independently represents a divalent linking group; Zu¹, Zu²¹, Zu²², Zu³¹, Zu³², Zu³³, and Zu⁴ each independently represents a substrate adsorptive group; Wu⁴ represents a cyclic group; and nu represents an integer of 1 or more within a limit of valence.

3. The method for producing a structure body including a phase-separated structure according to claim 1, wherein R^{1c} and R^{1d} are each a group represented by General Formula (r1), 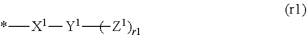
wherein X¹ represents a single bond, a methylene group, —COO—, or —O—; Y¹ represents a single bond or a divalent linking group; Z¹ represents the substrate adsorptive group-containing group; r1 represents an integer of 1 or more within a limit of valence; provided that, when X¹ is —COO— or —O—, Y¹ is not a single bond and * represents a bonding site bonded with a benzene ring in General Formula (n1).

4. The method for producing a structure body including a phase-separated structure according to claim 1, wherein the substrate adsorptive group is a hydroxy group, a carboxy group, a thiol group, a vinyl group, a halogen atom, an amino group, an azide group, a formyl group, an epoxy group, or a cyano group.

5. The method for producing a structure body including a phase-separated structure according to claim 1, wherein the first polymer block has a hydrophobic constitutional unit (Na), and the second polymer block has a hydrophilic constitutional unit (Nb).

6. A composition used in the method for producing a structure body including a phase-separated structure according to claim 1, the composition comprising the block copolymer represented by General Formula (n1).
